(19) United States
(12) Patent Application Publication
(10) Pub. No.: US 2024/0121976 A1
(43) Pub. Date: Apr. 11, 2024

(54) OPTICAL DEVICE, DISPLAY APPARATUS, AND ELECTRONIC DEVICE

(71) Applicant: SEMICONDUCTOR ENERGY LABORATORY CO., LTD., Atsugi-shi, Kanagawa-ken (JP)

(72) Inventors: Taisuke KAMADA, Niiza, Saitama (JP); Anna TADA, Isehara, Kanagawa (JP); Sachiko KAWAKAMI, Atsugi, Kanagawa (JP); Daisuke KUBOTA, Atsugi, Kanagawa (JP)

(21) Appl. No.: 18/269,004

(22) PCT Filed: Dec. 17, 2021
(86) PCT No.: PCT/IB2021/061896

§ 371 Date: Jun. 22, 2023

(30) Foreign Application Priority Data
Dec. 29, 2020 (JP) 2020-219883

(51) Int. Cl. H10K 50/16; H10K 50/15; H10K 85/20; H10K 85/30; H10K 85/60

(52) U.S. Cl. CPC H10K 50/167; H10K 50/157; H10K 85/20; H10K 85/331; H10K 85/371; H10K 85/381; H10K 85/623; H10K 85/6572; H10K 85/6576; H10K 2102/351

(57) ABSTRACT

An optical device with favorable characteristics is provided. An optical device with low driving voltage is provided. An optical device with low power consumption is provided. The optical device includes a first electrode, a second electrode, an active layer, and a carrier-transport layer. The active layer is positioned between the first electrode and the second electrode. The active layer contains a first organic compound and a second organic compound, the first organic compound is represented by General Formula (G1), and the second organic compound is represented by General Formula (G2-1). The carrier-transport layer is positioned between the second electrode and the active layer and the thickness of the carrier-transport layer is greater than or equal to 10 nm and less than or equal to 300 nm.

### TECHNICAL FIELD

One embodiment of the present invention relates to an optical device. One embodiment of the present invention relates to a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

In recent years, display apparatuses are used in various devices such as information terminal devices such as smartphones, tablet terminals, and laptop PCs, television devices, and monitor devices. Furthermore, display apparatuses have been required to have a variety of functions such as a touch panel function and a function of capturing images of fingerprints for authentication, in addition to a function of displaying images.

For example, light-emitting apparatuses including light-emitting devices have been developed as display apparatuses. Light-emitting devices (also referred to as EL devices or EL elements) utilizing electroluminescence (EL) have features such as ease of reduction in thickness and weight, high-speed response to input signals, and driving with a constant DC voltage power source, and have been used in display apparatuses. For example, Patent Document 1 discloses a flexible light-emitting apparatus using an organic EL device (also referred to as organic EL element).

### REFERENCE

### Patent Document

[Patent Document 1] Japanese Published Patent Application No. 2014-197522

### SUMMARY OF THE INVENTION

### Problems to be Solved by the Invention

An object of one embodiment of the present invention is to provide an optical device with favorable characteristics. Another object is to provide an optical device with low driving voltage. Another object is to provide an optical device with low power consumption. Another object is to provide an optical device with high productivity. Another object is to provide a highly convenient optical device. Another object is to provide a multifunctional optical device. Another object is to provide a novel optical device. Another object is to provide a novel display apparatus. Another object is to provide a novel electronic device.

The description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is an optical device including a first electrode, a second electrode, an active layer, and a carrier-transport layer. The active layer is positioned between the first electrode and the second electrode. The active layer contains a first organic compound and a second organic compound, the first organic compound is represented by General Formula (G1), and the second organic compound is represented by General Formula (G2-1). The carrier-transport layer is positioned between the second electrode and the active layer, and the thickness of the carrier-transport layer is greater than or equal to 10 nm and less than or equal to 300 nm.

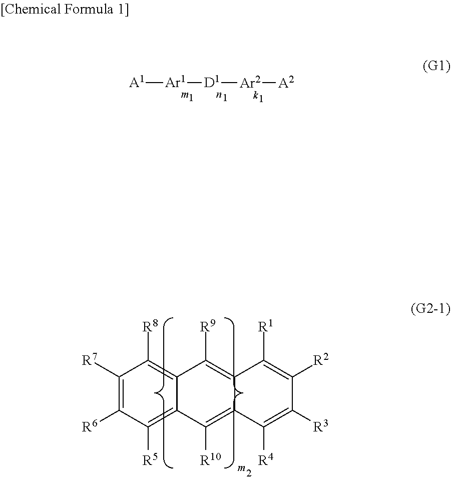

In General Formula (G1) above, D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms; A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3.

In General Formula (G2-1) above, R¹ to R¹⁰ each independently represents hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms; and m₂ represents an integer of 1 to 5.

In the above optical device, m₂ is 2 or more, and a plurality of R⁹ may be different from each other.

In the above optical device, m₂ is 2 or more, and a plurality of R¹⁰ may be different from each other.

In the above optical device, at least one pair of adjacent groups of R¹ to R⁴ and R⁵ to R⁶ may be bonded to each other to form a ring.

In the above optical device, the second organic compound is represented by Structural Formula (201) or (202).

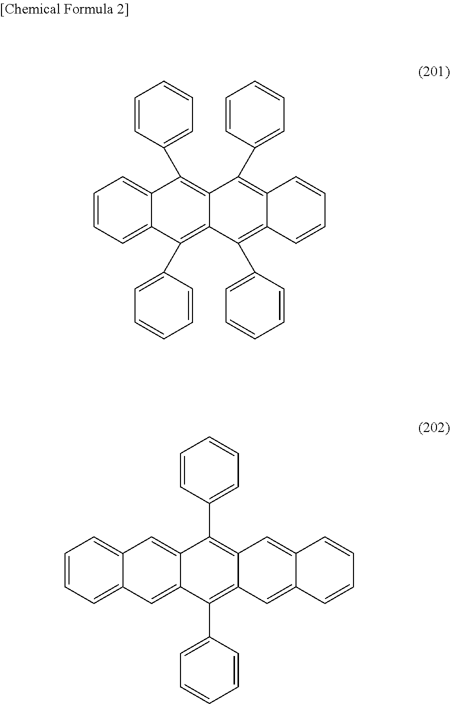

One embodiment of the present invention is an optical device including a first electrode, a second electrode, an active layer, and a carrier-transport layer. The active layer is positioned between the first electrode and the second electrode. The active layer contains a first organic compound and a second organic compound, the first organic compound is represented by General Formula (G1), and the second organic compound is represented by General Formula (G2-2) or Structural Formula (310). The carrier-transport layer is positioned between the second electrode and the active layer, and the thickness of the carrier-transport layer is greater than or equal to 10 nm and less than or equal to 300 nm.

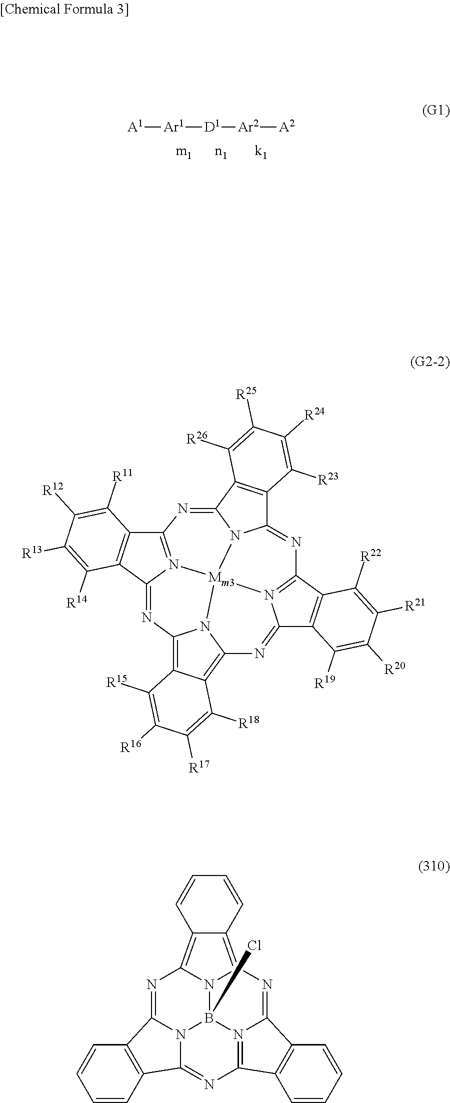

In General Formula (G1) above, D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms, A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3.

In General Formula (G2-2) above, M represents a metal, a metal oxide, or a metal halide; m₃ is 1 or 2; R¹¹ to R²⁶ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

In the optical device, the second organic compound is represented by any one of Structural Formula (301) to Structural Formula (305).

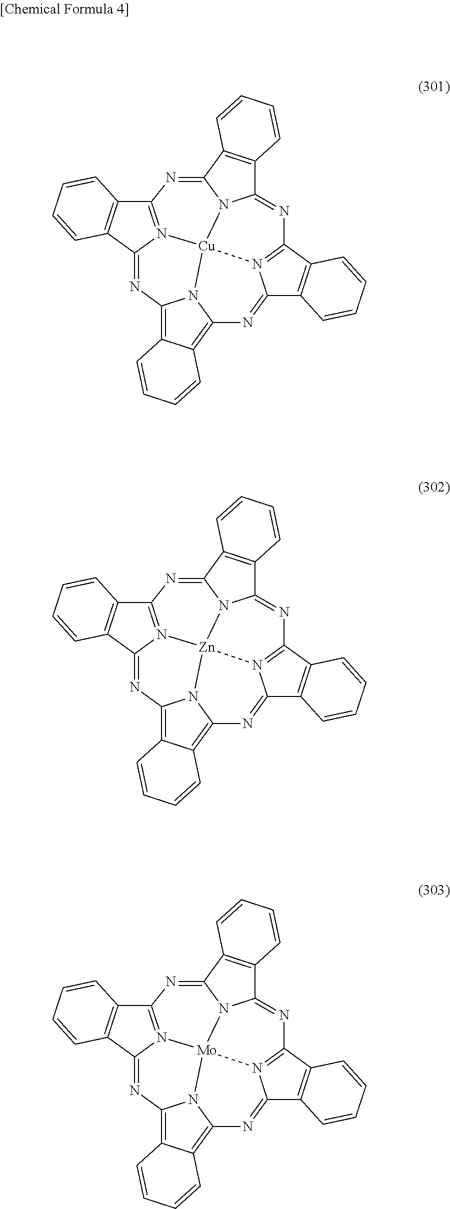

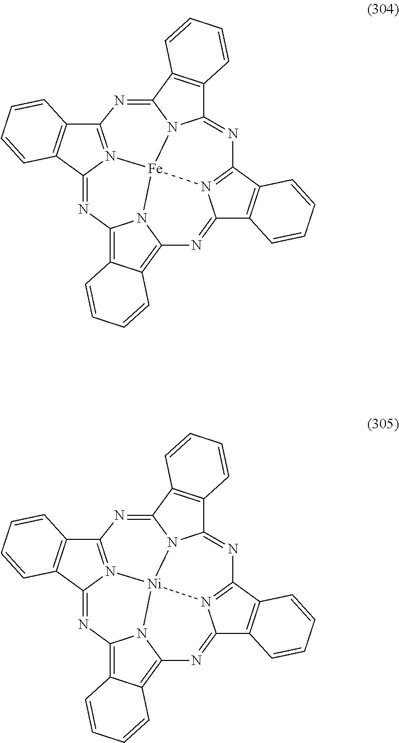

One embodiment of the present invention is an optical device including a first electrode, a second electrode, an active layer, and a carrier-transport layer. The active layer is positioned between the first electrode and the second electrode. The active layer contains a first organic compound and a second organic compound, the first organic compound is represented by General Formula (G1), and the second organic compound is represented by General Formula (G2-3). The carrier-transport layer is positioned between the second electrode and the active layer, and the thickness of the carrier-transport layer is greater than or equal to 10 nm and less than or equal to 300 nm.

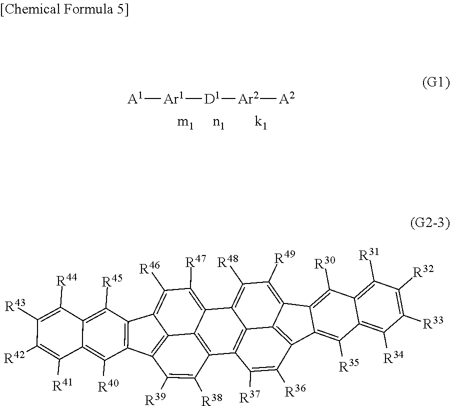

In General Formula (G1) above, D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms; A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3.

In General Formula (G2-3) above, R³⁰ to R⁴⁹ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

In the above optical device, the second organic compound is represented by Structural Formula (401)

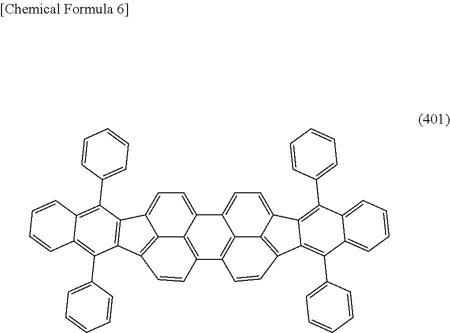 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]

In the above optical device, D¹ is represented by any one of General Formula (g1-1-1) to General Formula (g1-1-4). Each of Ar¹ and Ar² independently represents a substituted or unsubstituted thiophene-diyl group, a substituted or unsubstituted furan-diyl group, a substituted or unsubstituted phenylene group, or a substituted or unsubstituted naphthalene-diyl group. Each of A¹ and A² are independently represented by General Formula (g1-2).

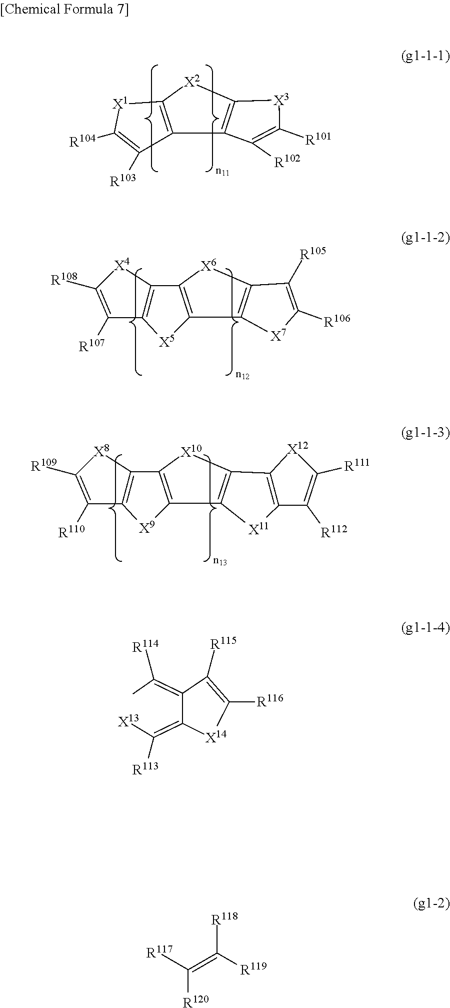

In General Formula (g1-1-1) to General Formula (g1-1-4) and General Formula (g1-2) above, one of R¹⁰¹ and R¹⁰² is bonded to one of Ar¹ and Ar²; one of R¹⁰³ and R¹⁰⁴ is bonded to the other of Ar¹ and Ar²; one of R¹⁰⁵ and R¹⁰⁶ is bonded to one of Ar¹ and Ar²; one of R¹⁰⁷ and R¹⁰⁸ is bonded to the other of Ar¹ and Ar²; one of R¹⁰⁹ and R¹¹⁰ is bonded to one of Ar¹ and Ar²; one of R¹¹¹ and R¹¹² is bonded to the other of Ar¹ and Ar²; one of any two of R¹¹³ to R¹¹⁶ is bonded to Ar¹ and the other is bonded to Ar²; the rest of R¹⁰¹ to R¹¹⁶ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹¹⁷ to R¹¹⁹ each independently represent hydrogen, deuterium, a cyano group, fluorine, chlorine, a nitro group, a substituted or unsubstituted alkyl halide group having 1 to 6 carbon atoms, or a substituted or unsubstituted alkoxy group having 1 to 6 carbon atoms; at least one of R¹¹⁷ to R¹¹⁹ represents a cyano group, fluorine, chlorine, a nitro group, a substituted or unsubstituted alkyl halide group having 1 to 6 carbon atoms, or a substituted or unsubstituted alkoxy group having 1 to 6 carbon atoms; R¹²⁰ is bonded to one or both of Ar¹ and Ar²; X¹ to X¹⁴ each independently represent oxygen or sulfur; n₁₁ represents an integer of 0 to 10; and n₁₂ and n₁₃ each independently represent an integer of 0 to 4.

In the above optical device, the first organic compound is represented by any one of General Formula (G1-1) to General Formula (G1-3).

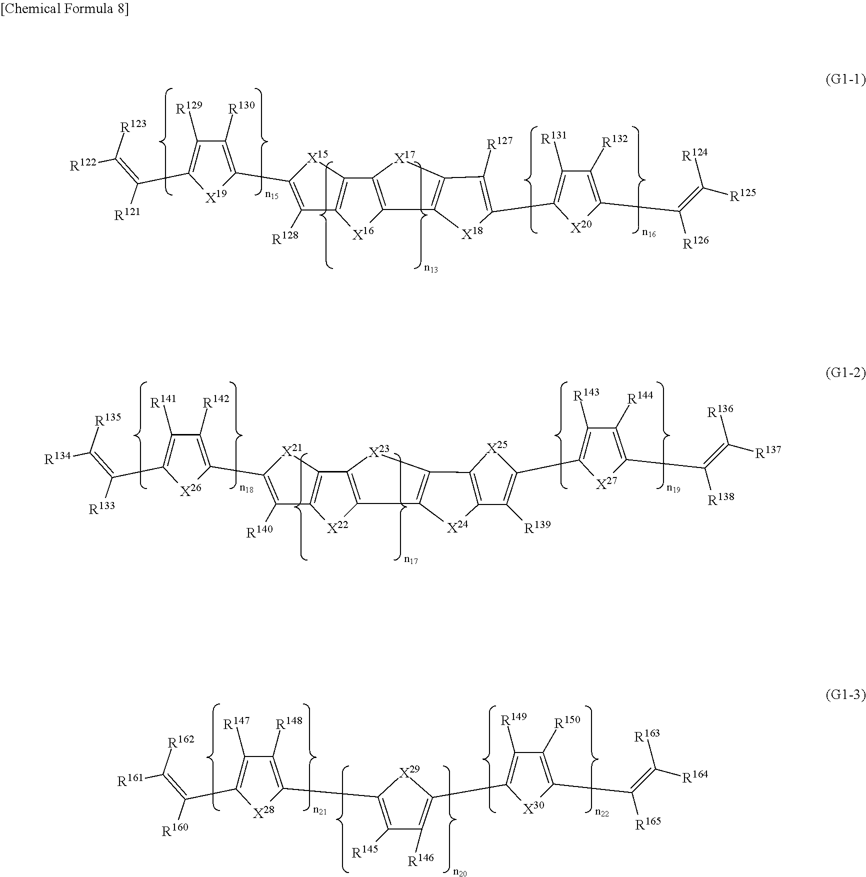

In General Formula (G1-1) to General Formula (G1-3) above, X¹⁵ to X³⁰ each independently represent oxygen or sulfur; n₁₄ and n₁₇ each independently represent an integer of 0 to 4; n₁₅, n₁₆, n₁₈, and n₁₉ to n₂₂ each independently represent an integer of 0 to 3; at least one of n₂₀ to n₂₂ represents an integer of 1 to 3; R¹²⁷ to R¹³² and R¹³⁹ to R¹⁵⁰ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹²¹ to R¹²⁶, R¹³³ to R¹³⁸, and R¹⁶⁰ to R¹⁶⁵ each independently represent hydrogen, deuterium, a cyano group, fluorine, chlorine, a substituted or unsubstituted alkyl halide group having 1 to 6 carbon atoms, or a substituted or unsubstituted alkoxy group having 1 to 6 carbon atoms; at least one of R¹²¹ to R¹²⁶, at least one of R¹³³ to R¹³⁸, and at least one of R¹⁶⁰ to R¹⁶⁵ each represent a cyano group, fluorine, chlorine, a nitro group, a substituted or unsubstituted alkyl halide group having 1 to 6 carbon atoms, or a substituted or unsubstituted alkoxy group having 1 to 6 carbon atoms.

In the above optical device, the first organic compound is represented by any one of Structural Formulae (101) and (102).

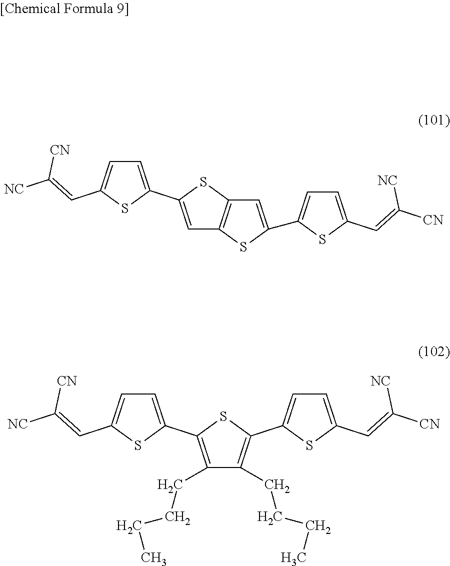 [SMILES: N#CC(C#N)=Cc1ccc(-c2cc3sc(-c4ccc(C=C(C#N)C#N)s4)cc3s2)s1 ; CCCCc1c(-c2ccc(C=C(C#N)C#N)s2)sc(-c2ccc(C=C(C#N)C#N)s2)c1CCCC]

In the above optical device, the carrier-transport layer contains an electron-transport material.

The above optical device may include a hole-transport layer. The hole-transport layer is positioned between the first electrode and the active layer, and the hole-transport layer contains a hole-transport material. The thickness of the hole-transport layer is greater than or equal to 10 nm and less than or equal to 300 nm.

In the above optical device, the carrier-transport layer contains a hole-transport material.

The above optical device may include an electron-transport layer. The electron-transport layer is positioned between the first electrode and the active layer and the electron-transport layer contains an electron-transport material. The thickness of the electron-transport layer is greater than or equal to 10 nm and less than or equal to 300 nm.

In the above optical device, the active layer may include a first layer and a second layer. The first layer includes a region in contact with the second layer, the first layer contains the first organic compound, and the second layer contains the second organic compound.

The above optical device may include a first light-emitting layer. The first light-emitting layer is positioned between the first pixel electrode and the active layer.

The above optical device may include a first light-emitting layer. The first light-emitting layer is positioned between the carrier-transport layer and the active layer.

One embodiment of the present invention is a display apparatus including the above optical device and a light-emitting device. The light-emitting device includes a third electrode, a second light-emitting layer, and the second electrode. The second light-emitting layer is positioned between the third electrode and the second electrode, and the second light-emitting layer contains a third organic compound different from the first organic compound.

The above display apparatus may further include at least one of a transistor and a substrate.

One embodiment of the present invention is an electronic device including the above display apparatus and at least one of a microphone, a camera, an operation button, a connection terminal, and a speaker.

### Effect of the Invention

One embodiment of the present invention can provide an optical device with favorable characteristics. An optical device with low driving voltage can be provided. An optical device with low power consumption can be provided. An optical device with high productivity can be provided. A highly convenient optical device can be provided. A multifunctional optical device can be provided. A novel optical device can be provided. A novel display apparatus can be provided. A novel electronic device can be provided.

The description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

FIG. 1A to FIG. 1E are cross-sectional views illustrating examples of a light-receiving device.

FIG. 2A to FIG. 2D are cross-sectional views illustrating examples of a light-emitting and light-receiving device.

FIG. 3A and FIG. 3B are cross-sectional views illustrating examples of display apparatuses.

FIG. 4A and FIG. 4B are cross-sectional views illustrating examples of display apparatuses.

FIG. 5A and FIG. 5B are cross-sectional views illustrating examples of a display apparatus.

FIG. 6A to FIG. 6D are cross-sectional views illustrating examples of display apparatuses.

FIG. 7A to FIG. 7D and FIG. 7F are cross-sectional views illustrating examples of display apparatuses. FIG. 7E and FIG. 7G are diagrams illustrating examples of images captured by display apparatuses. FIG. 7H to FIG. 7K are top views illustrating examples of a pixel.

FIG. 8A to FIG. 8G are top views illustrating examples of a pixel.

FIG. 9A to FIG. 9C are cross-sectional views illustrating examples of display apparatuses.

FIG. 10A is a cross-sectional view illustrating an example of a display apparatus. FIG. 10B and FIG. 10C are diagrams illustrating examples of a top surface layout of a resin layer.

FIG. 11 is a perspective view illustrating an example of a display apparatus.

FIG. 12 is a cross-sectional view illustrating an example of display apparatus.

FIG. 13 is a cross-sectional view illustrating an example of a display apparatus.

FIG. 14A is a cross-sectional view illustrating an example of a display apparatus. FIG. 14B is a cross-sectional view illustrating an example of a transistor.

FIG. 15A and FIG. 15B are circuit diagrams illustrating examples of pixel circuits.

FIG. 16A and FIG. 16B are diagrams illustrating an example of an electronic device.

FIG. 17A to FIG. 17D are diagrams illustrating examples of electronic devices.

FIG. 18A to FIG. 18F are diagrams illustrating examples of electronic devices.

FIG. 19A is a diagram showing the current-voltage characteristics of light-receiving devices.

FIG. 19B is a diagram showing external quantum efficiency.

FIG. 20A and FIG. 20B are diagrams showing the characteristics of light-receiving devices.

FIG. 21A and FIG. 21B are diagrams showing the current density-voltage characteristics of light-receiving devices.

FIG. 22A and FIG. 22B are diagrams showing the current density-voltage characteristics of light-receiving devices.

FIG. 23A and FIG. 23B are diagrams showing the current density-voltage characteristics of light-receiving devices.

FIG. 24A and FIG. 24B are diagrams showing the current density-voltage characteristics of light-receiving devices.

FIG. 25A and FIG. 25B are diagrams showing the external quantum efficiency of light-receiving devices.

FIG. 26A and FIG. 26B are diagrams showing the external quantum efficiency of light-receiving devices.

FIG. 27A and FIG. 27B are diagrams showing the current density-voltage characteristics of light-receiving devices.

FIG. 28A and FIG. 28B are diagrams showing the current density-voltage characteristics of light-receiving devices.

FIG. 29A and FIG. 29B are diagrams showing the current density-voltage characteristics of light-receiving devices.

FIG. 30A and FIG. 30B are diagrams showing the current density-voltage characteristics of light-receiving devices.

FIG. 31A and FIG. 31B are diagrams showing the external quantum efficiency of light-receiving devices.

FIG. 32A and FIG. 32B are diagrams showing the external quantum efficiency of light-receiving devices.

FIG. 33 is a diagram showing the reliability of light-receiving devices.

### MODE FOR CARRYING OUT THE INVENTION

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”.

### EMBODIMENT 1

In this embodiment, an optical device of one embodiment of the present invention will be described. Here, a light-receiving device (also referred to as a light-receiving element) and a light-emitting and light-receiving device (also referred to as a light-emitting and light-receiving element) are described as an example of an optical device.

### <Light-Receiving Device>

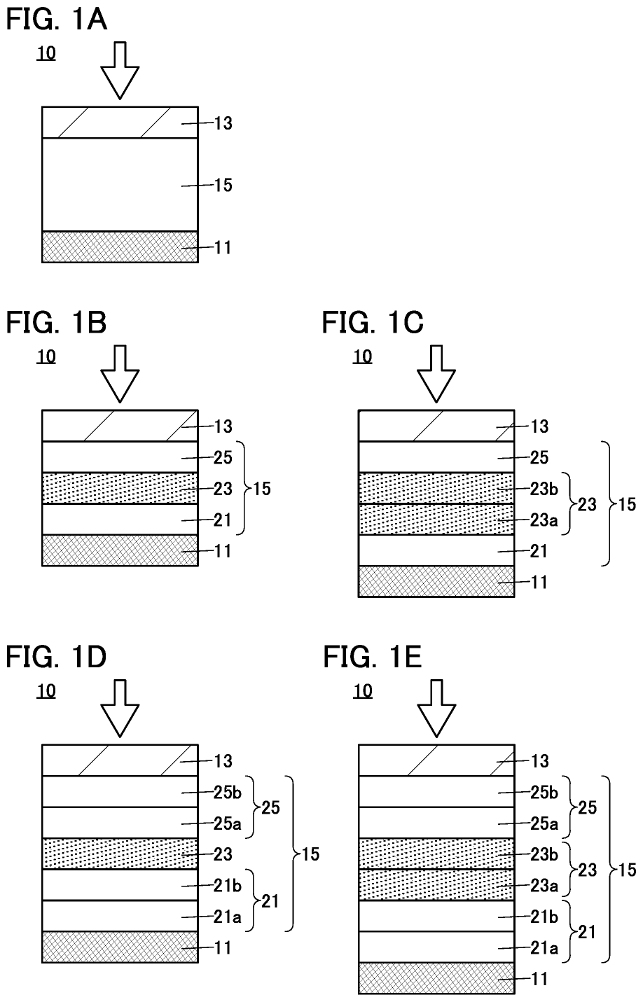

A structure example of a light-receiving device of one embodiment of the present invention is illustrated in FIG. 1A. FIG. 1A is a cross-sectional view illustrating a structure of a light-receiving device 10. The light-receiving device 10 includes a first electrode 11, a second electrode 13, and a layer 15 positioned between the first electrode 11 and the second electrode 13. The layer 15 includes at least an active layer. In the light-receiving device 10, electric charge that are generated in the active layer by incident light can be extracted as current. At this time, voltage may be applied between the first electrode 11 and the second electrode 13. The light-receiving device 10 has a function of detecting visible light or near-infrared light.

A pn or pin photodiode structure can be applied to the light-receiving device 10, for example. The light-receiving device 10 functions as a photoelectric conversion element (also referred to as a photoelectric conversion device) that detects light entering the light-receiving device 10 and generates electric charge. The amount of electric charge generated from the light-receiving device 10 depends on the amount of light entering the light-receiving device 10.

### [Active Layer]

As illustrated in FIG. 1B, the light-receiving device 10 can have a structure in which the layer 15 includes an active layer 23. The active layer 23 includes a semiconductor. Examples of the semiconductor include an inorganic semiconductor such as silicon and an organic semiconductor including an organic compound. As the semiconductor included in the active layer 23, an organic semiconductor can be suitably used. For the light-receiving device 10, an organic photodiode including a layer that contains an organic semiconductor can be suitably used. An organic photodiode is easily made thin, lightweight, and large in area and has a high degree of freedom for shape and design, and thus the light-receiving device 10 including the organic photodiode can be used in a variety of devices.

The active layer 23 contains an n-type semiconductor material and a p-type semiconductor material. The active layer 23 can have a structure including a mixed layer of an n-type semiconductor material and a p-type semiconductor material (such a structure is referred to as a bulk heterojunction structure). For example, the active layer 23 can be formed by depositing an n-type semiconductor material and a p-type semiconductor material by co-evaporation. With a bulk heterojunction structure, an optical device with high photoelectric conversion efficiency can be achieved.

As an n-type semiconductor material contained in the active layer 23, an electron-accepting organic semiconductor material can be used. An organic compound represented by General Formula (G1) can be used as the n-type semiconductor material.

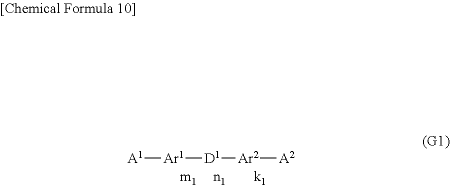

In General Formula (G1), D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms; A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3.

Note that when the expression “substituted or unsubstituted Z group” is used in this specification and the like, the Z group may be substituted with any one or more of deuterium, a substituted or unsubstituted alkyl group having 1 to 6 carbon atoms, a substituted or unsubstituted cycloalkyl group having 3 to 10 carbon atoms, a substituted or unsubstituted alkoxy group having 1 to 6 carbon atoms, a substituted or unsubstituted aryl group having 6 to 30 carbon atoms, a substituted or unsubstituted heteroaryl group having 2 to 30 carbon atoms, a substituted or unsubstituted alkyl halide group having 1 to 6 carbon atoms, and halogen. The aryl group or the heteroaryl group may be substituted with any one or more of deuterium, a substituted or unsubstituted alkyl group having 1 to 6 carbon atoms, a substituted or unsubstituted cycloalkyl group having 3 to 10 carbon atoms, a substituted or unsubstituted alkoxy group having 1 to 6 carbon atoms, a substituted or unsubstituted alkyl halide group having 1 to 6 carbon atoms, and halogen.

In the case where m₁ is 2 or 3, a plurality of Ar¹ may be the same, partly different, or completely different. Similarly, in the case where n₁ is 2 or 3, a plurality of D¹ may be the same, partly different, or completely different. Furthermore, in the case where n₁ is 2 or 3, a plurality of Ar² may be the same, partly different, or completely different.

The organic compound represented by General Formula (G1) has a relatively low boiling point, and thus the evaporation temperature can be low. Here, high evaporation temperature changes the quality of a film formed before the active layer 23, and the characteristics of the light-receiving device 10 deteriorates in some cases. Furthermore, high evaporation temperature decreases productivity in some cases. In one embodiment of the present invention, with the use of the organic compound represented by General Formula (G1) in the active layer 23, quality change of another film can be inhibited, and an optical device with favorable characteristics can be obtained. In addition, the productivity of the light-receiving device 10 can be increased.

In General Formula (G1) above, for example, a group represented by any of General Formula (g1-1-1) to General Formula (g1-1-4) below can be used as D¹. Furthermore, for example, a group represented by General Formula (g1-2) can be used as each of A¹ and A². Note that groups that can be used as D¹, A¹, and A² are not limited to these groups.

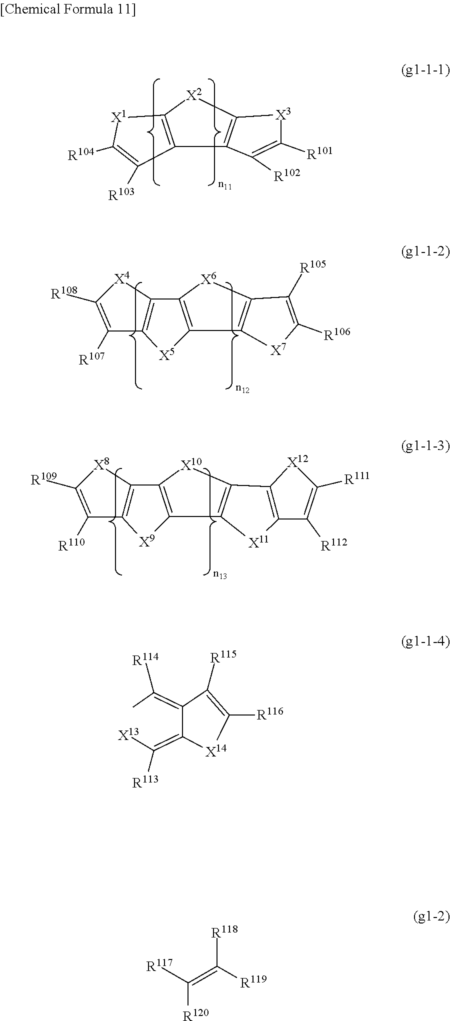

In General Formula (g1-1-1) to General Formula (g1-1-4) and General Formula (g1-2), one of R¹⁰¹ and R¹⁰² is bonded to one of Ar¹ and Ar²; one of R¹⁰³ and R¹⁰⁴ is bonded to the other of Ar¹ and Ar²; one of R¹⁰⁵ and R¹⁰⁶ is bonded to one of Ar¹ and Ar²; one of R¹⁰⁷ and R¹⁰⁸ is bonded to the other of Ar¹ and Ar²; one of R¹⁰⁹ and R¹¹⁰ is bonded to one of Ar¹ and Ar²; one of R¹¹¹ and R¹¹² is bonded to the other of Ar¹ and Ar²; one of any two of R¹¹³ to R¹¹⁶ is bonded to Ar¹ and the other is bonded to Ar²; the rest of R¹⁰¹ to R¹¹⁶ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹¹⁷ to R¹¹⁹ each independently represent hydrogen, deuterium, a cyano group, fluorine, chlorine, a nitro group, a substituted or unsubstituted alkyl halide group having 1 to 6 carbon atoms, or a substituted or unsubstituted alkoxy group having 1 to 6 carbon atoms; at least one of R¹¹⁷ to R¹¹⁹ represents a cyano group, fluorine, chlorine, a nitro group, a substituted or unsubstituted alkyl halide group having 1 to 6 carbon atoms, or a substituted or unsubstituted alkoxy group having 1 to 6 carbon atoms; R¹²⁰ is bonded to one or both of Ar¹ and Ar²; X¹ to X¹⁴ each independently represent oxygen or sulfur; n₁₁ represents an integer of 0 to 10; and n₁₂ and n₁₃ each independently represent an integer of 0 to 4.

In the case where n₁₁ is 2 or more, a plurality of X² each independently represent oxygen or sulfur. Similarly, in the case where n₁₂ is 2 or more, a plurality of X⁵ and a plurality of X⁶ each independently represent oxygen or sulfur. Furthermore, in the case where n₁₃ is 2 or more, a plurality of X⁹ and a plurality of X¹⁰ each independently represent oxygen or sulfur.

In General Formula (G1) above, a group represented by any of Structural Formula (D-1) to Structural Formula (D-21) below, Structural Formula (D-23) to Structural Formula (D-25) below, and Structural Formula (D-27) to Structural Formula (D-51) below can be used as D¹, for example. Note that a group that can be used as D¹ is not limited thereto.

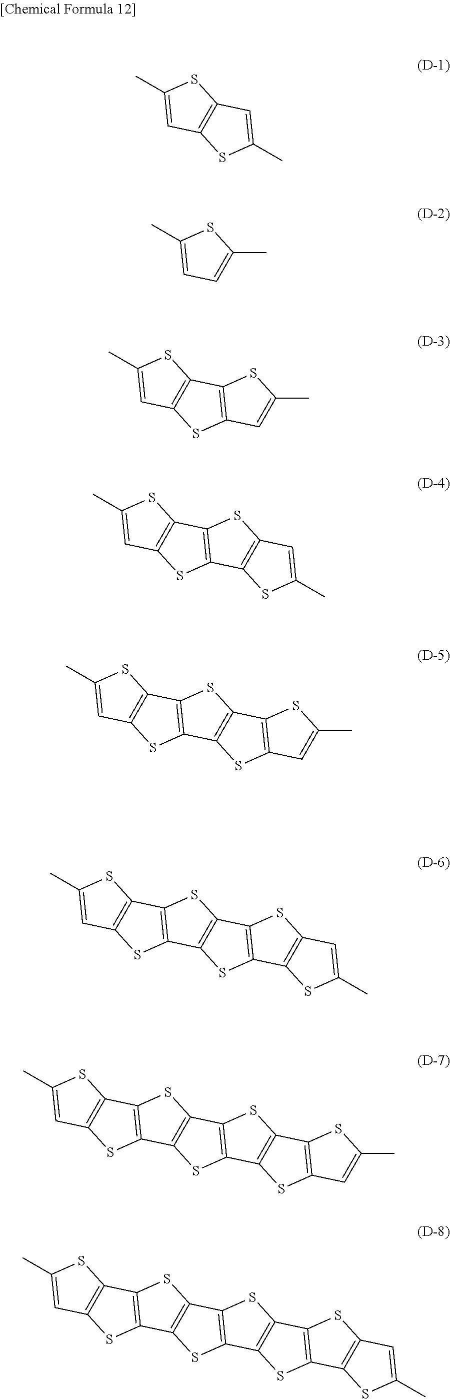

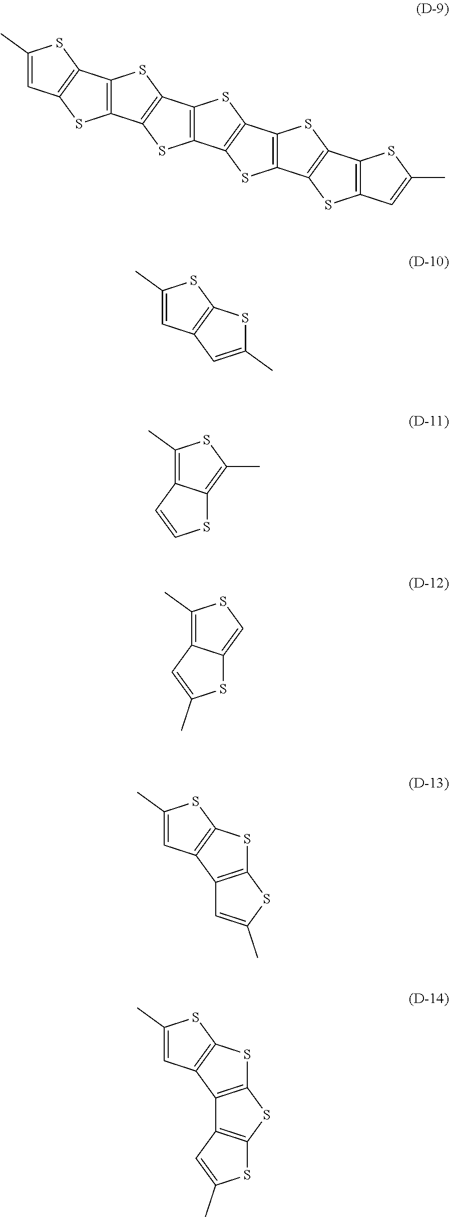

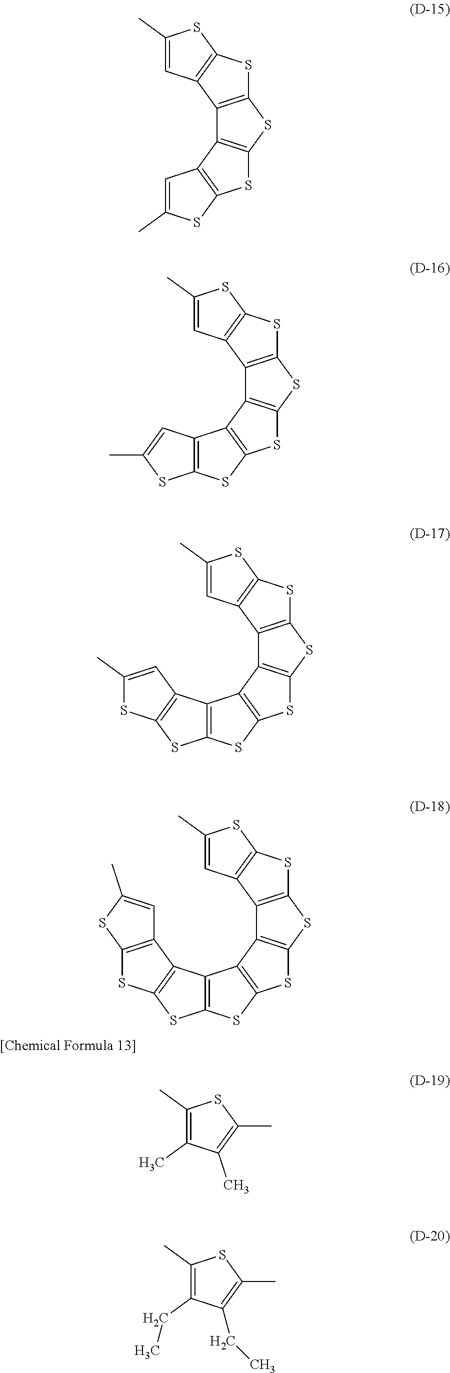

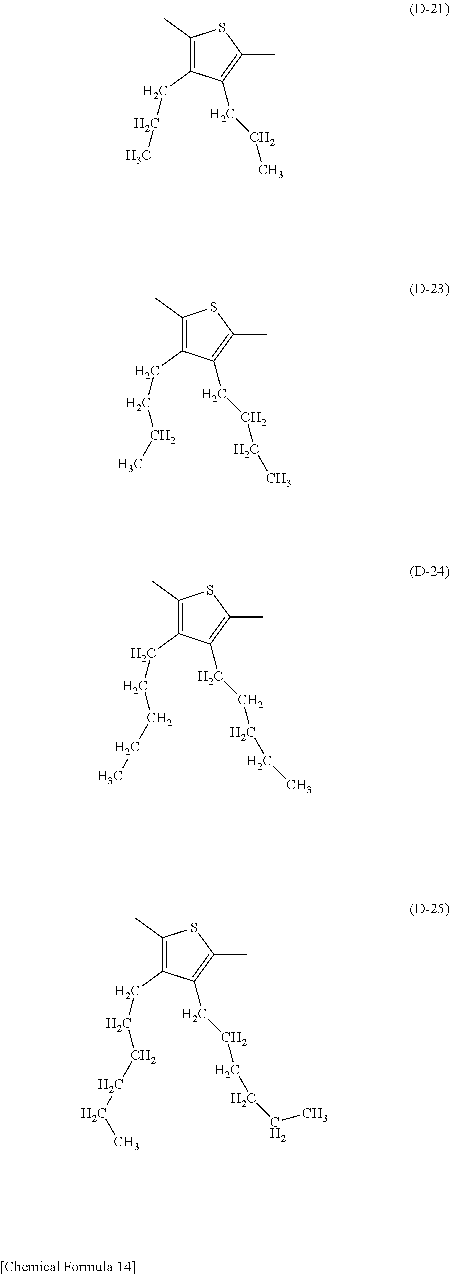

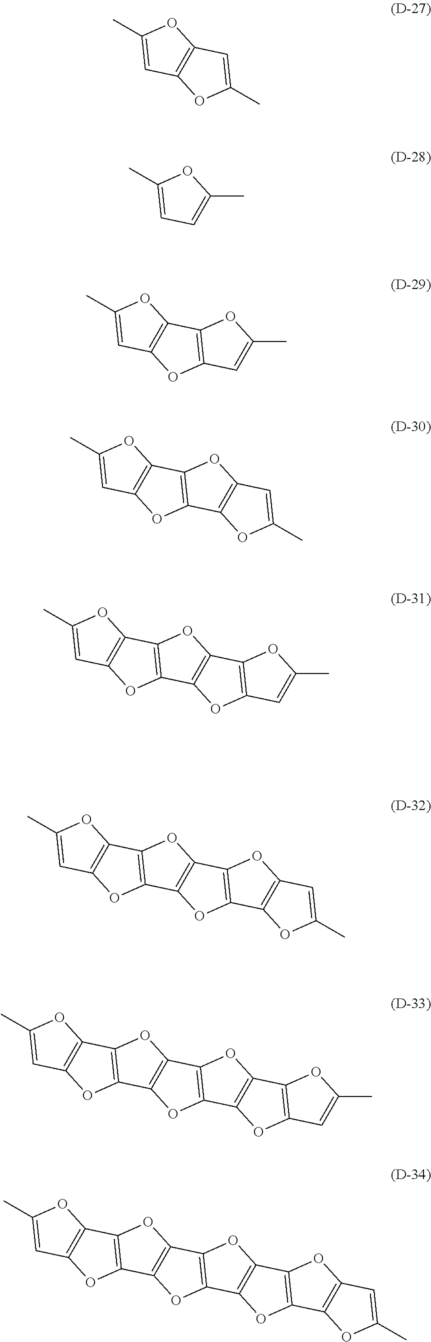

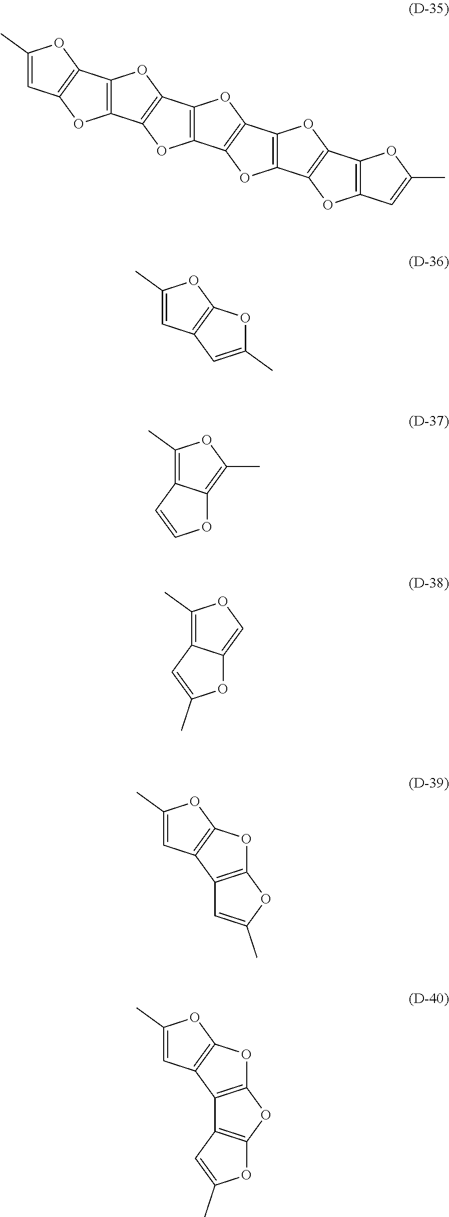

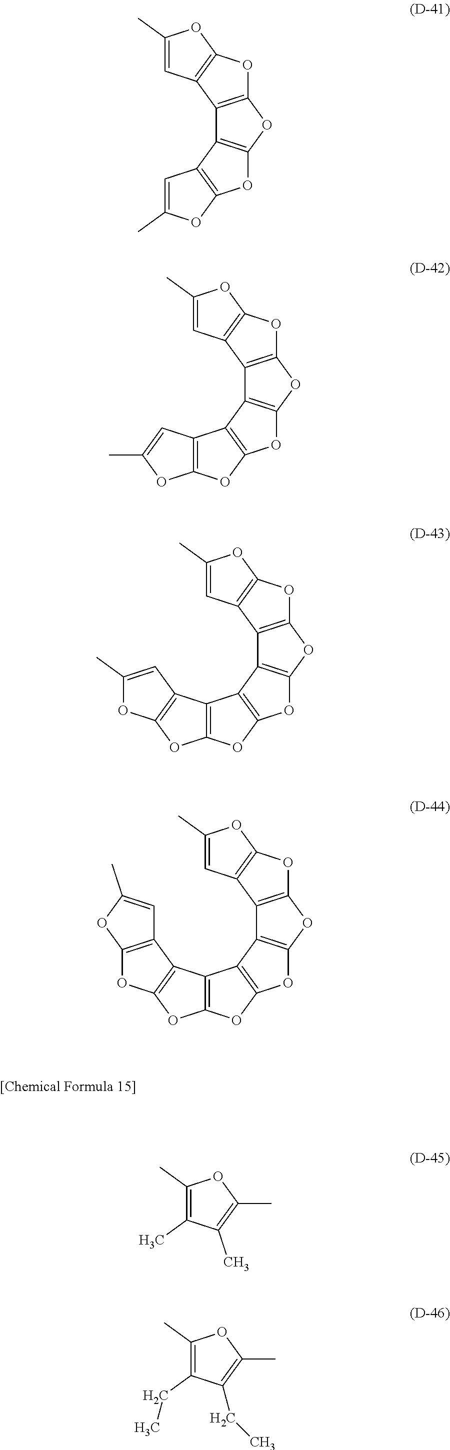

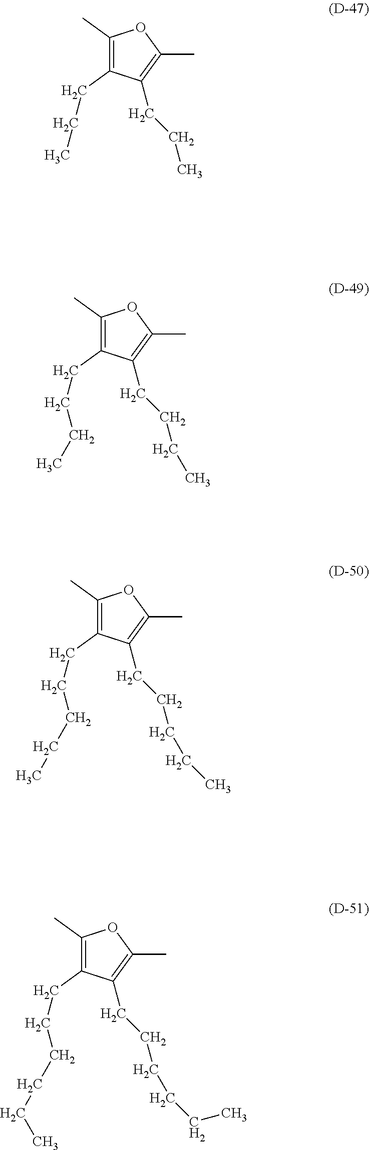

Examples of a substituted or unsubstituted heteroarylene group having 4 to 30 carbon atoms that can be used as each of Ar¹ and Ar² above include a substituted or unsubstituted thiophene-diyl group and a substituted or unsubstituted furan-diyl group. Examples of an arylene group having 6 to 30 carbon atoms that can be used as each of Ar¹ and Ar² above include a substituted or unsubstituted phenylene group and a substituted or unsubstituted naphthalene-diyl group. For example, groups represented by Structural Formula (Ar-1) to Structural Formula (Ar-10) below can be used as Ar¹ and Ar² above. Note that groups that can be used as Ar¹ and Ar² are not limited to these groups.

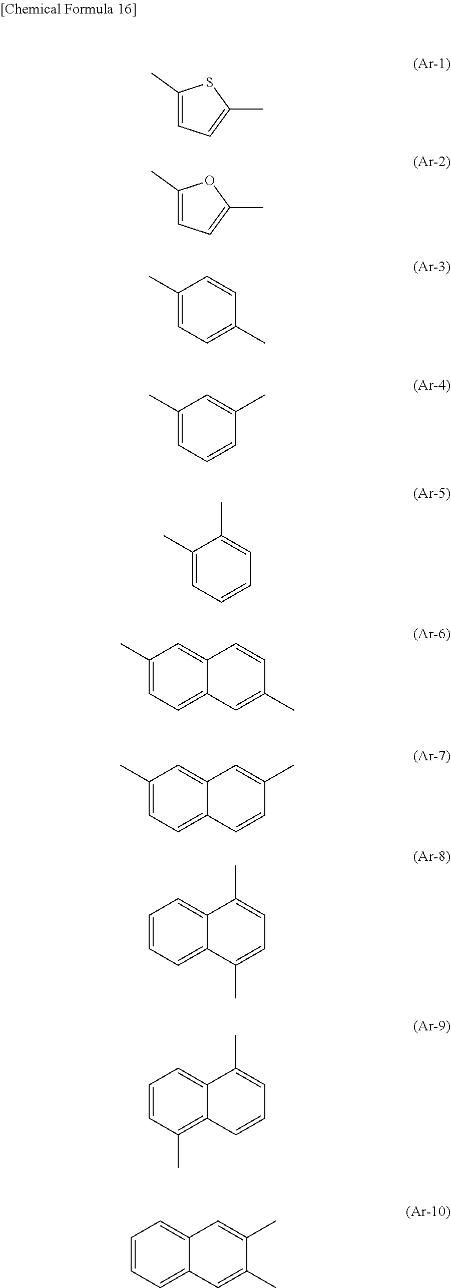

In General Formula (G1) above, groups represented by Structural Formula (A-1) to Structural Formula (A-25) below can be used as A¹ and A², for example. Note that groups that can be used as A¹ and A² are not limited to these groups.

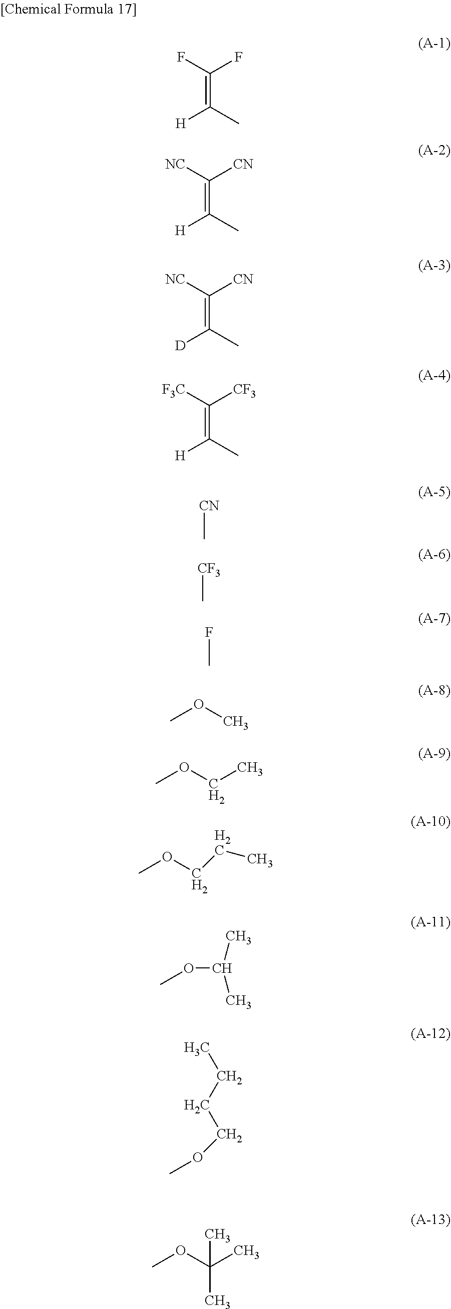

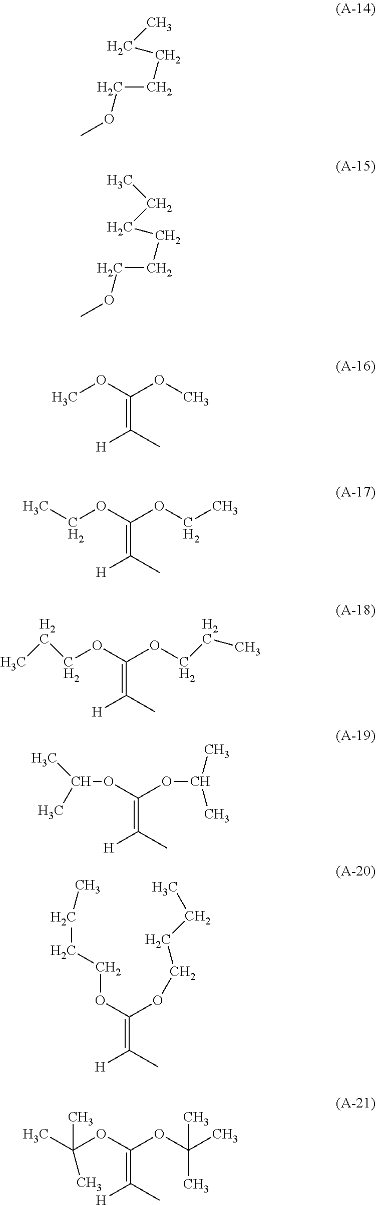

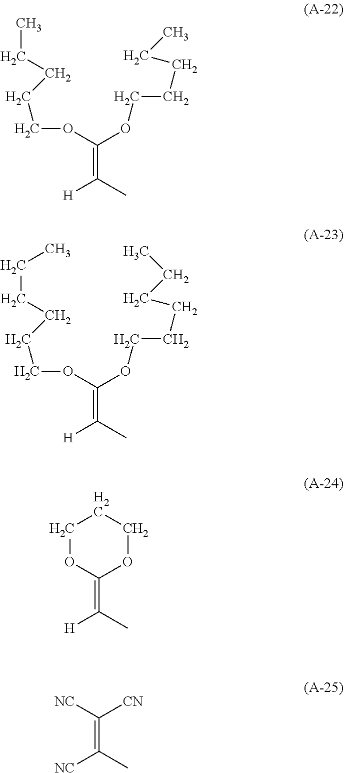

As an n-type semiconductor material contained in the active layer 23, an organic compound represented by any one of General Formula (G1-1) to General Formula (G1-3) can be used.

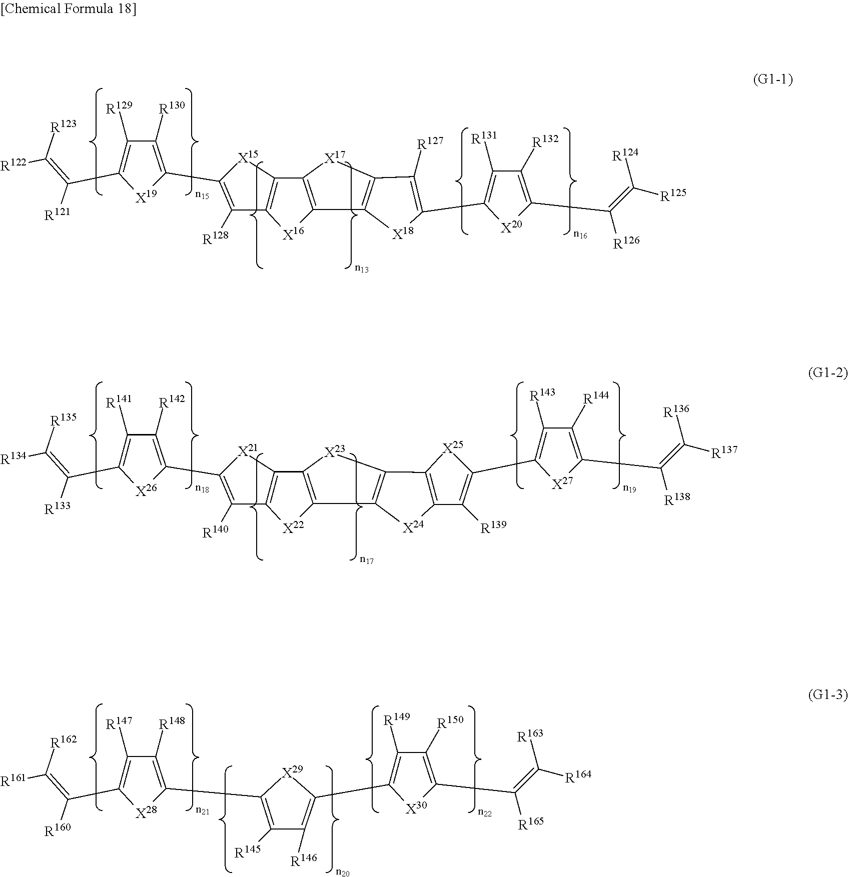

In General Formula (G1-1) to General Formula (G1-3), X¹⁵ to X³⁰ each independently represent oxygen or sulfur; n₁₄ and n₁₇ each independently represent an integer of 0 to 4; n₁₅, n₁₆, n₁₈, and n₁₉ to n₂₂ each independently represent an integer of 0 to 3; at least one of n₂₀ to n₂₂ represents an integer of 1 to 3; R¹²⁷ to R¹³² and R¹³⁹ to R¹⁵⁰ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; and R¹²¹ to R¹²⁶, R¹³³ to R¹³⁸, and R¹⁶⁰ to R¹⁶⁵ each independently represent hydrogen, deuterium, a cyano group, fluorine, chlorine, a substituted or unsubstituted alkyl halide group having 1 to 6 carbon atoms, or a substituted or unsubstituted alkoxy group having 1 to 6 carbon atoms.

In the case where n₁₄ is 2 or more, a plurality of X¹⁶ and a plurality of X¹⁷ each independently represent oxygen or sulfur. The same is applied to the case where n₁₅ to n₂₂ are each 2 or more; in the case where the number of any one or more of X¹⁸ to X³⁰ is two or more, a plurality of any one of X¹⁸ to X³⁰ each independently represent oxygen or sulfur.

In the case where n₁₅ is 2 or more, a plurality of R¹²⁹ may be the same, partly different, or completely different. Similarly, in the case where n15 is 2 or more, a plurality of R¹³⁰ may be the same, partly different, or completely different. The same is applied to the case where n₁₆ and n₁₈ to n₂₂ are each 2 or more; in the case where the number of any one or more of R¹³¹ to R¹⁵⁰ is two or more, a plurality of any one of R¹³¹ to R¹⁵⁰ may be the same, partly different, or completely different.

Specifically, as an n-type semiconductor material contained in the active layer 23, an organic compound represented by any of Structural Formula (100) to Structural Formula (137) can be given. Note that an organic compound that can be used for one embodiment of the present invention is not limited thereto.

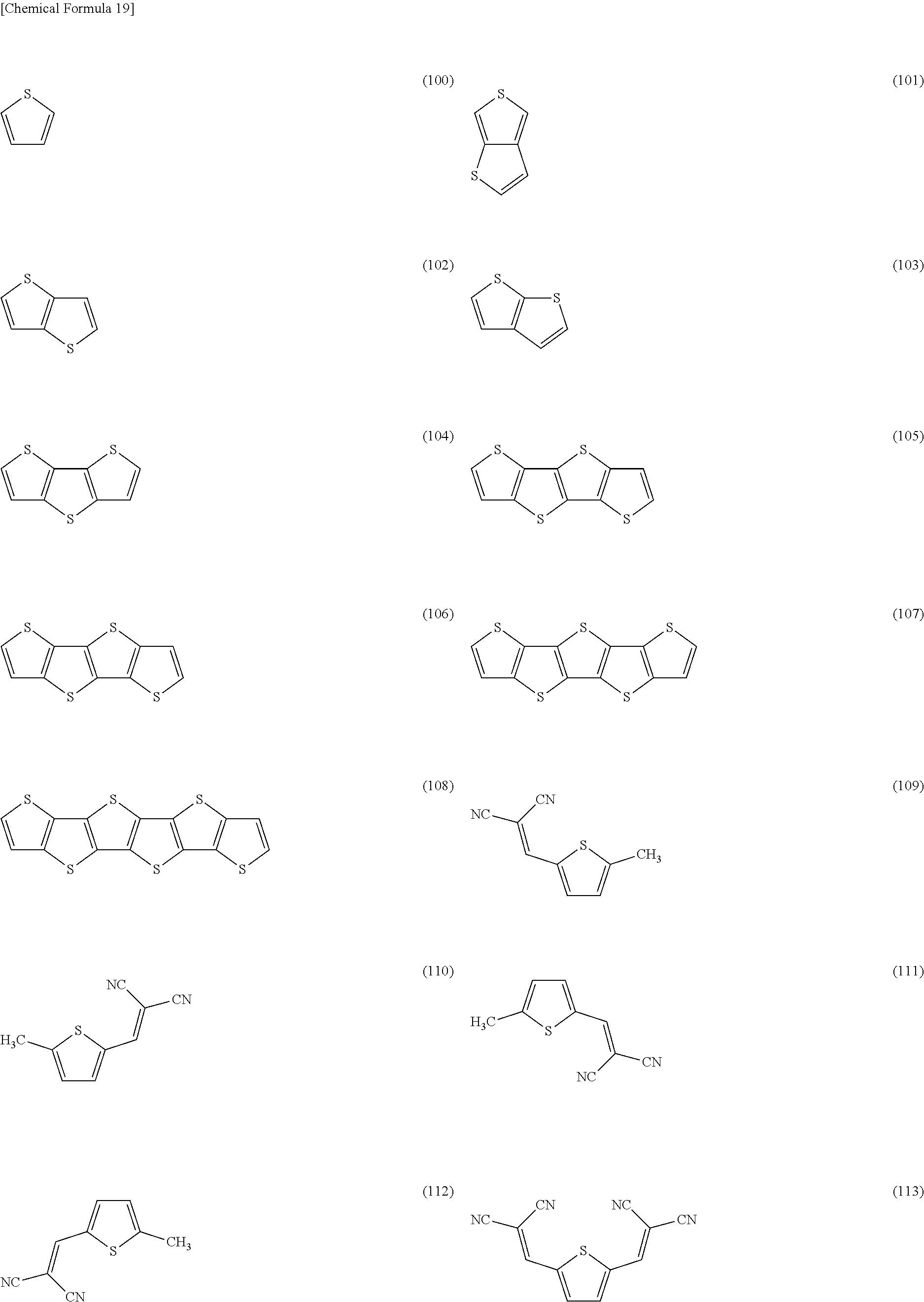

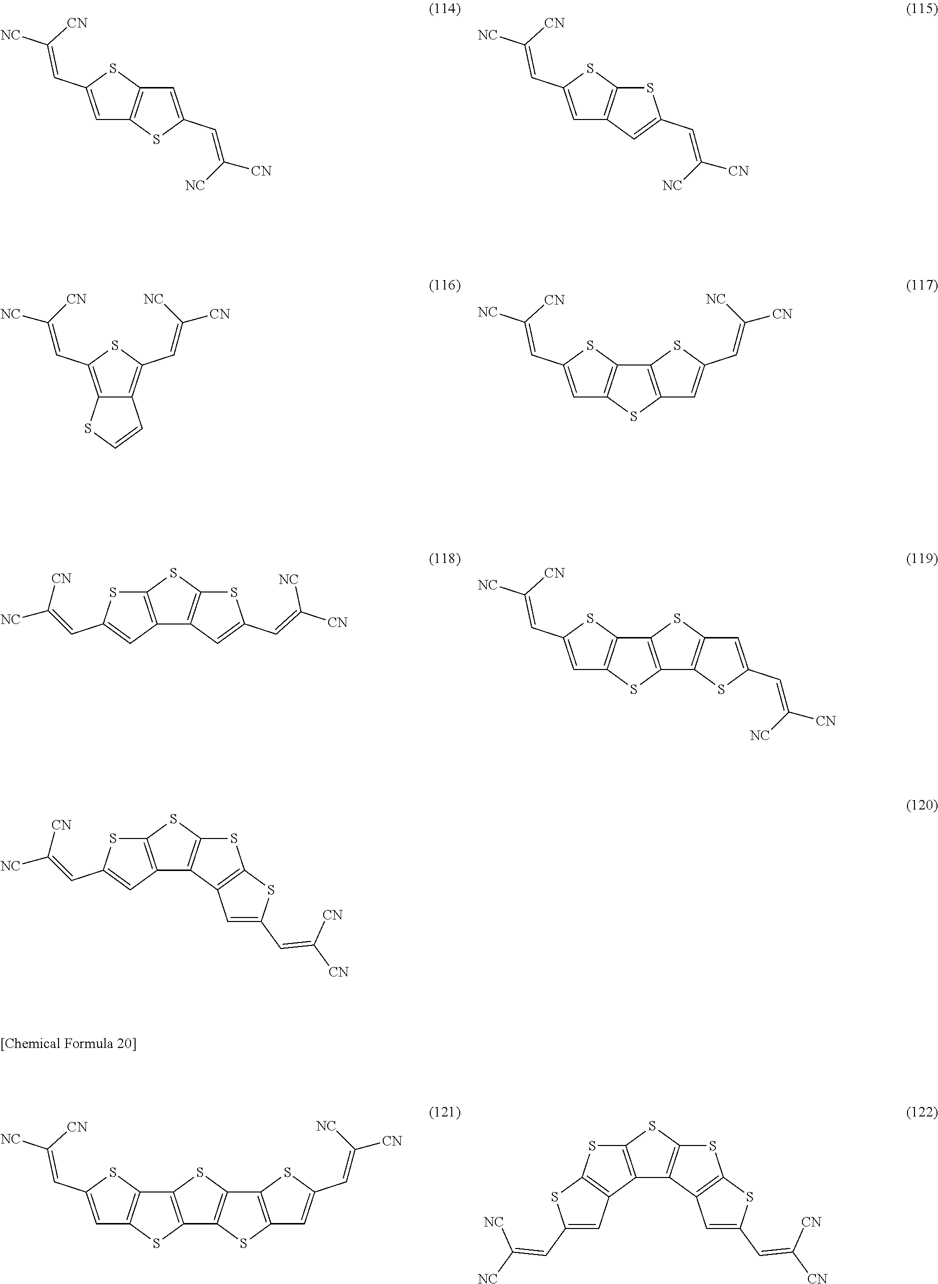

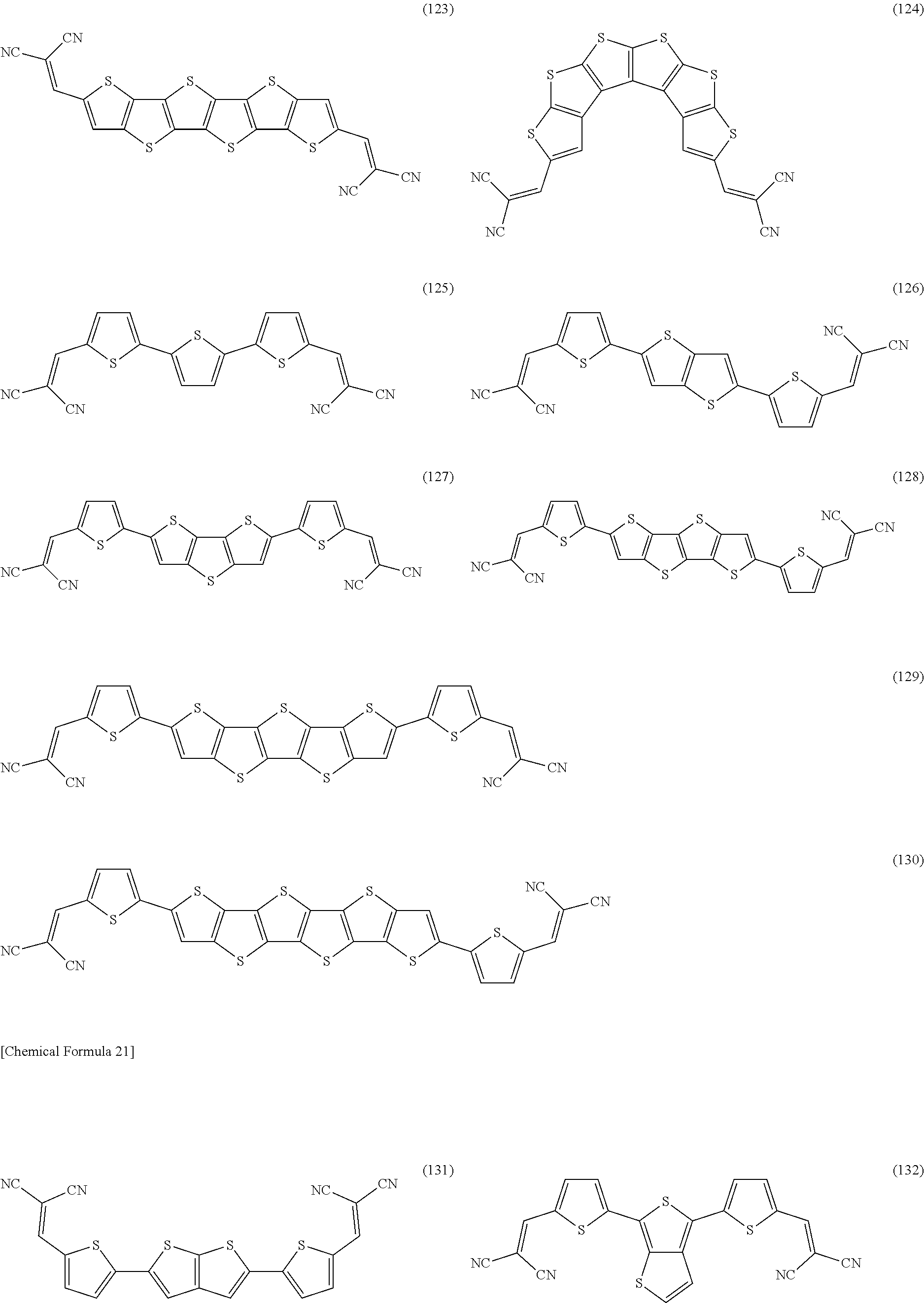

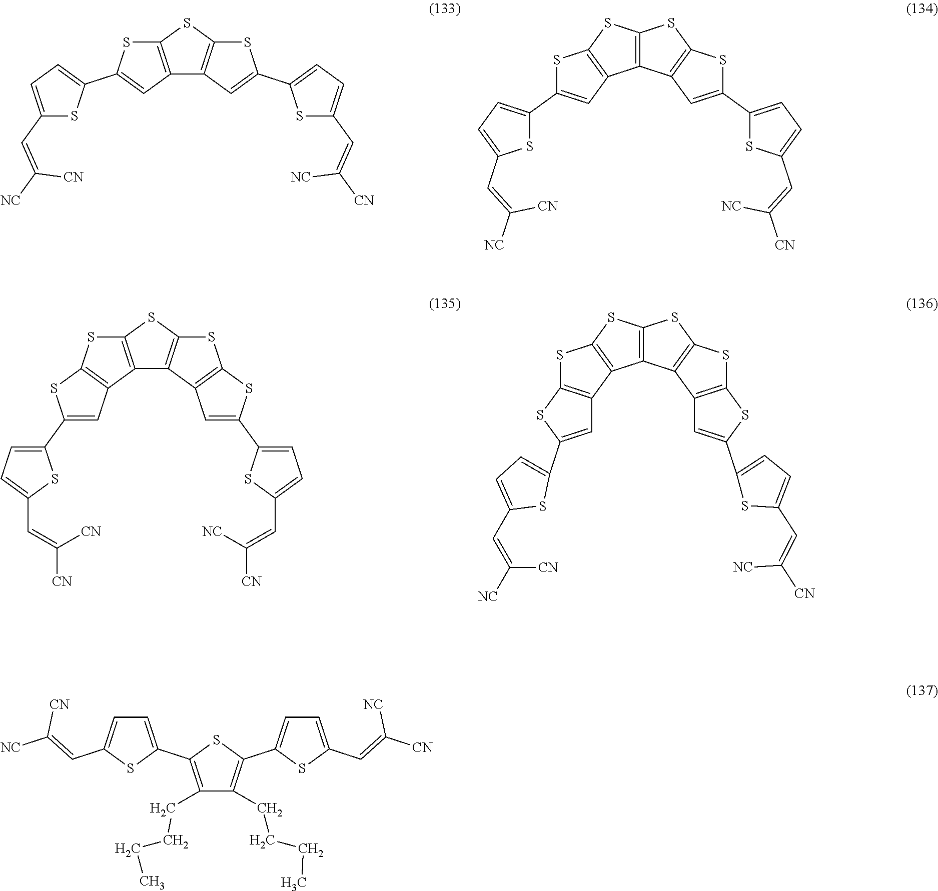 [SMILES: N#CC(C#N)=Cc1ccc(-c2cc3c(s2)sc2sc(-c4ccc(C=C(C#N)C#N)s4)cc23)s1 ; N#CC(C#N)=Cc1ccc(-c2cc3c(s2)sc2sc4sc(-c5ccc(C=C(C#N)C#N)s5)cc4c23)s1 ; N#CC(C#N)=Cc1ccc(-c2cc3c(s2)sc2sc4sc5sc(-c6ccc(C=C(C#N)C#N)s6)cc5c4c23)s1 ; N#CC(C#N)=Cc1ccc(-c2cc3c(s2)sc2sc4sc5sc6sc(-c7ccc(C=C(C#N)C#N)s7)cc6c5c4c23)s1 ; CCCCc1c(-c2ccc(C=C(C#N)C#N)s2)sc(-c2ccc(C=C(C#N)C#N)s2)c1CCCC]

Examples of an n-type semiconductor material contained in an active layer 273 include electron-accepting organic semiconductor materials such as fullerene (e.g., C₆₀ and C₇₀) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, the electron-donating property (donor property) usually increases. Although π-electrons widely spread in fullerene having a spherical shape, its electron-accepting property is high. The high electron-accepting property efficiently causes rapid charge separation and is useful for light-receiving devices. Both C₆₀ and C₇₀ have a wide absorption band in the visible light region, and C₇₀ is especially preferable because of having a larger π-electron conjugation system and a wider absorption band in the long wavelength region than C₆₀.

Examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

As a p-type semiconductor material contained in the active layer 23, an electron-donating organic semiconductor material can be used. An organic compound represented by General Formula (G2-1) can be used as the p-type semiconductor material.

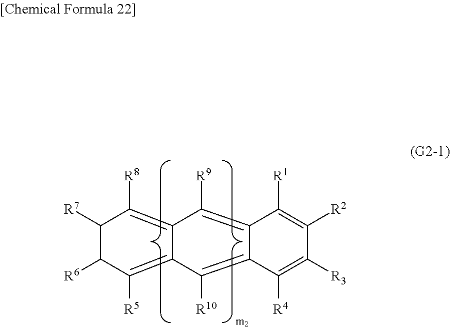

In General Formula (G2-1), R¹ to R¹⁰ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms, and m₂ represents an integer of 1 to 5.

Note that adjacent groups of R¹ to R⁴ and R⁵ to R⁸ may be bonded to each other to form a ring. In the case where m₂ is 2 or more, a plurality of R⁹ may be the same, partly different, or completely different. Similarly, in the case where m₂ is 2 or more, a plurality of R¹⁰ may be the same, partly different, or completely different.

The organic compound represented by General Formula (G2-1) has a relatively low boiling point, and thus the evaporation temperature can be low. In one embodiment of the present invention, with the use of the organic compound represented by General Formula (G2-1) in the active layer 23, quality change of another film can be inhibited, and the light-receiving device 10 with favorable characteristics can be obtained. In addition, the productivity of the light-receiving device 10 can be increased.

In General Formula (G2-1) above, groups represented by Structural Formula (R-1) to Structural Formula (R-78) below can be used as R¹ to R¹⁰, for example. Note that groups that can be used as R¹ to R¹⁰ are not limited to these groups.

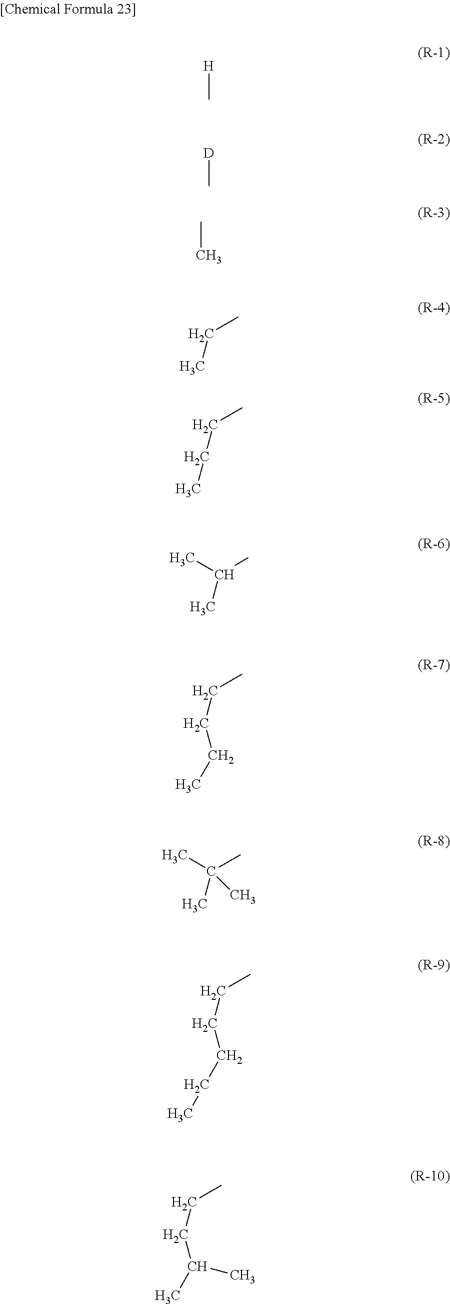

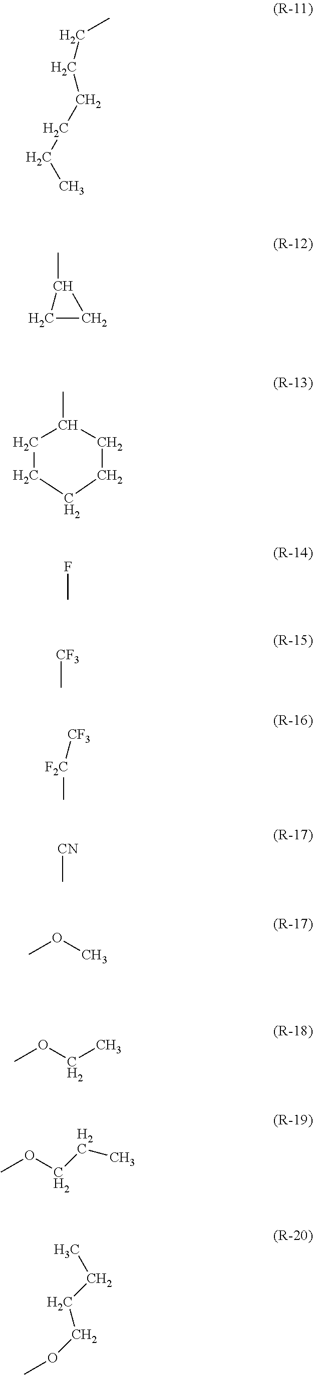

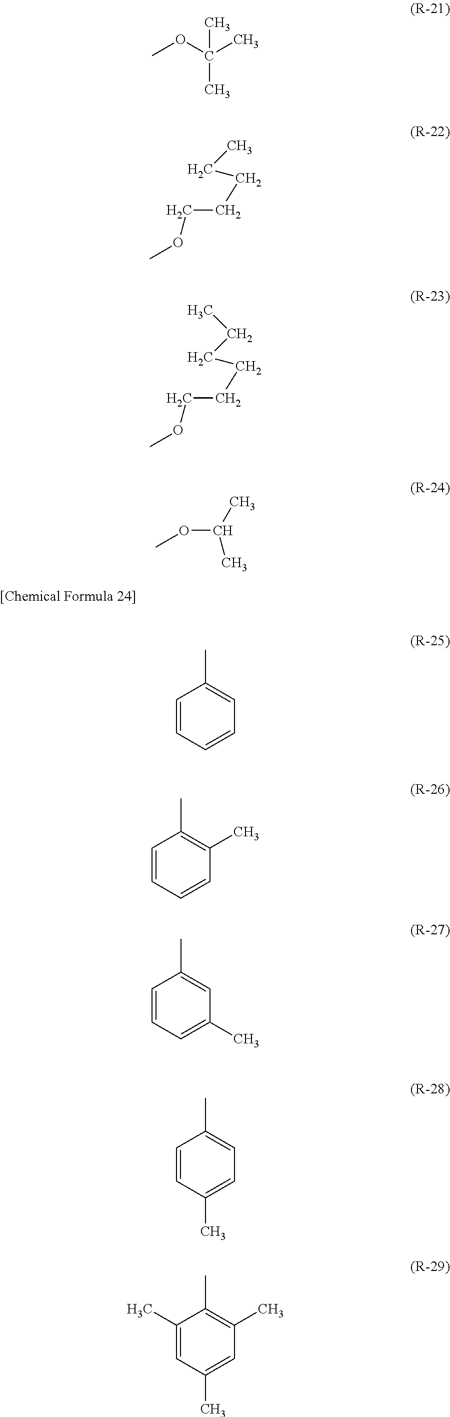

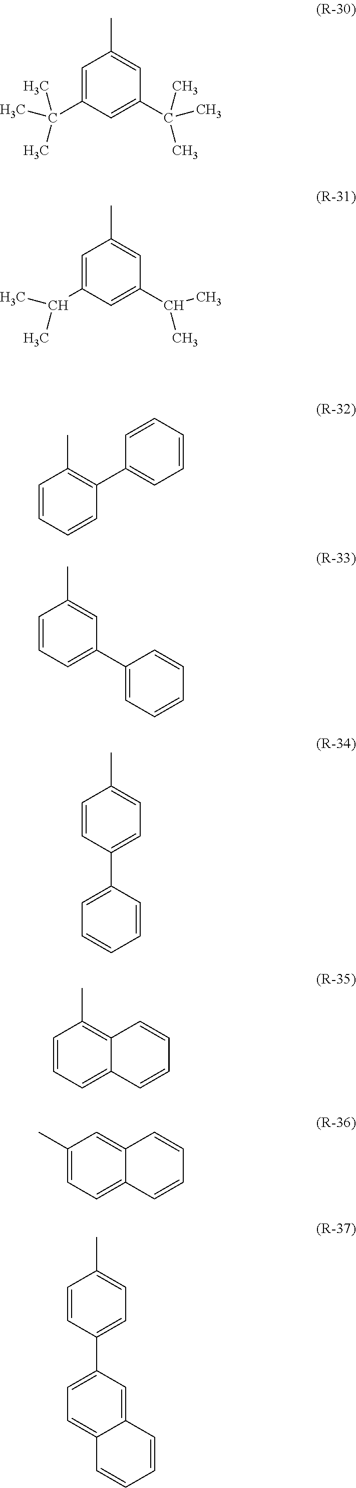

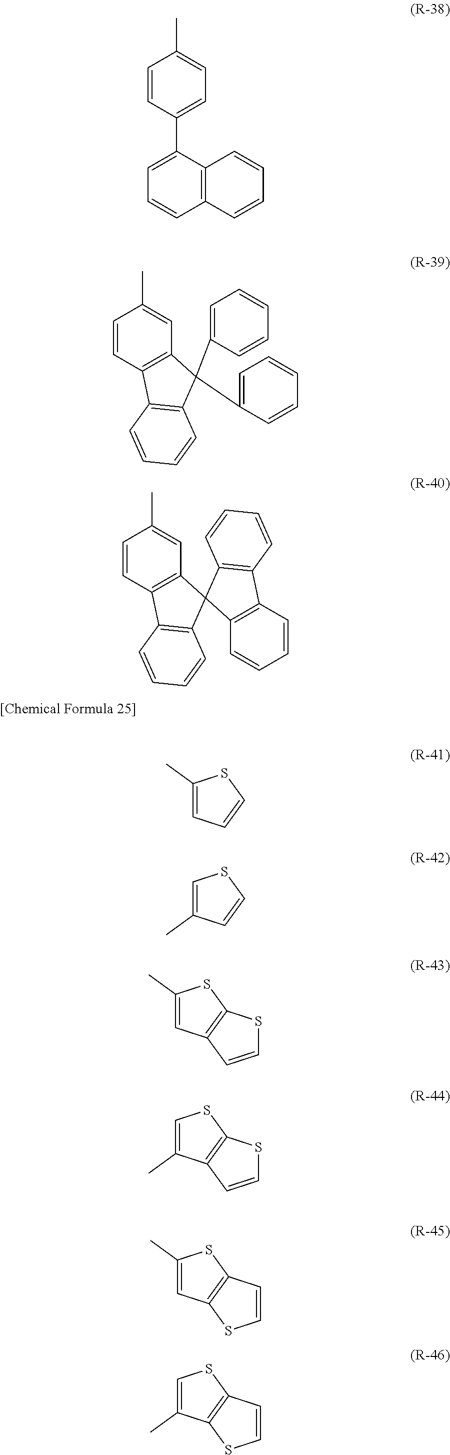

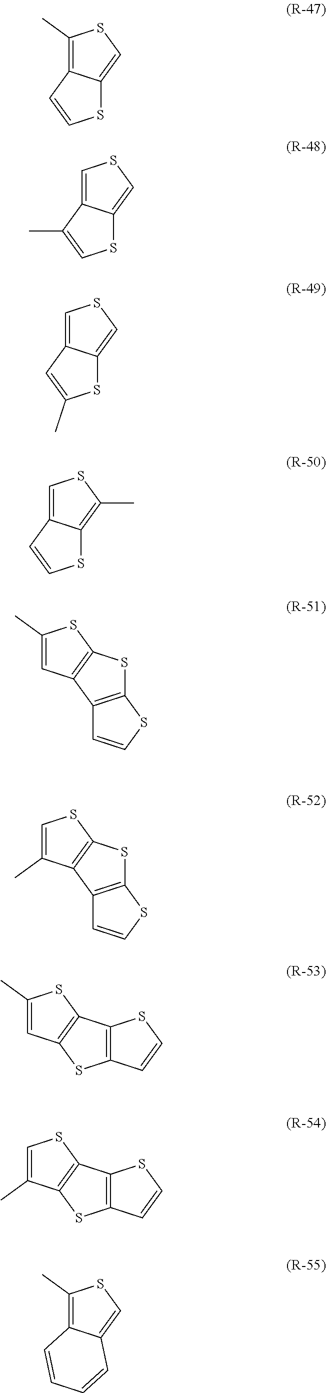

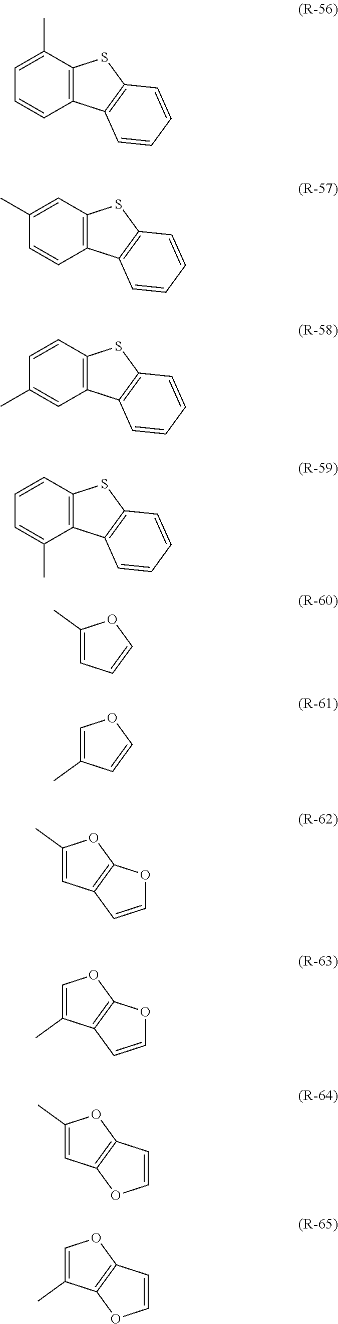

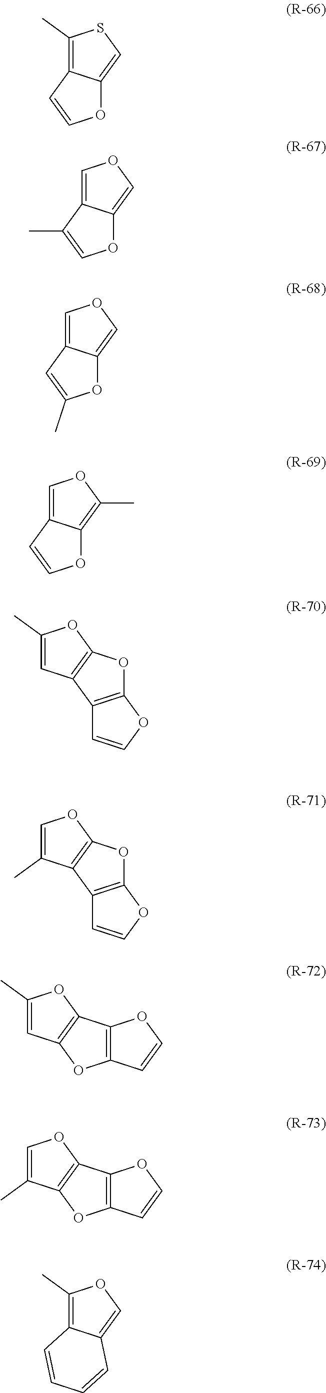

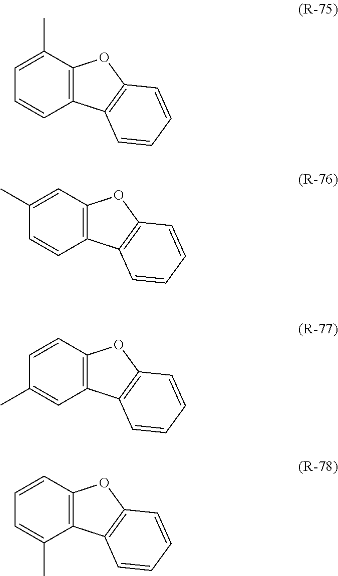

Specifically, as a p-type semiconductor material contained in the active layer 23, an organic compound represented by any of Structural Formula (201) to Structural Formula (216) can be given. Note that an organic compound that can be used for one embodiment of the present invention is not limited thereto.

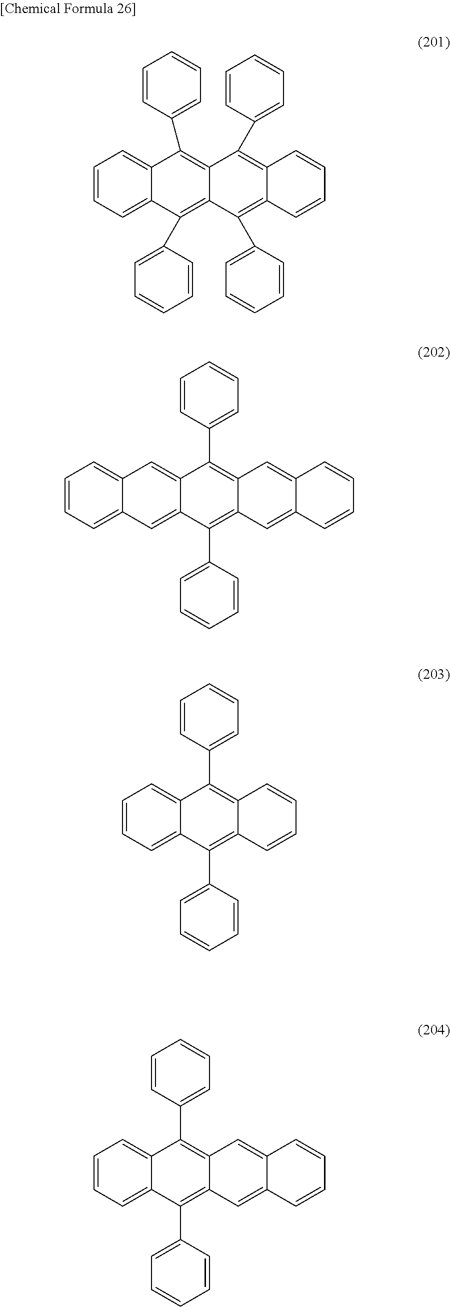

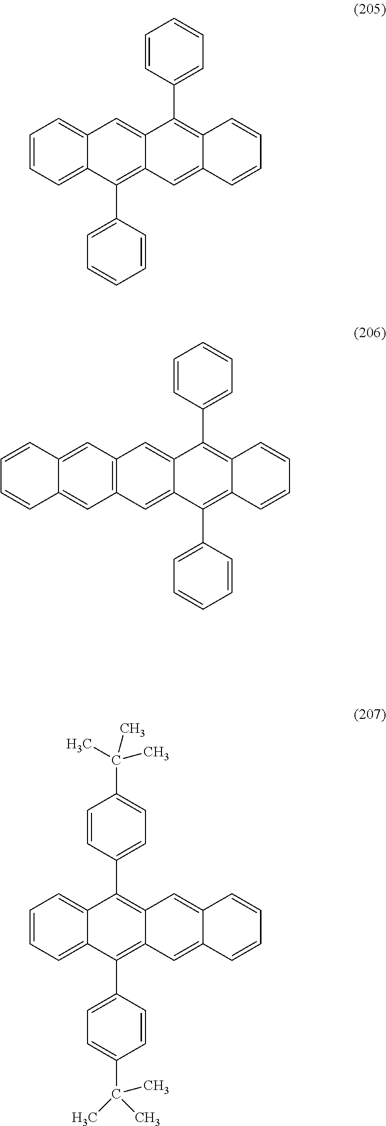

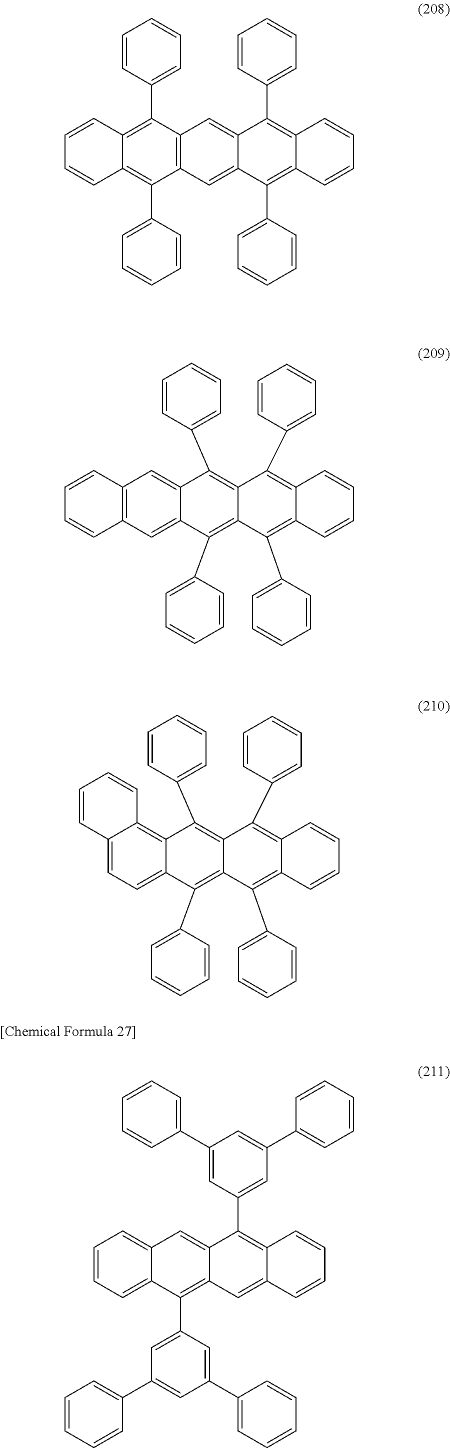

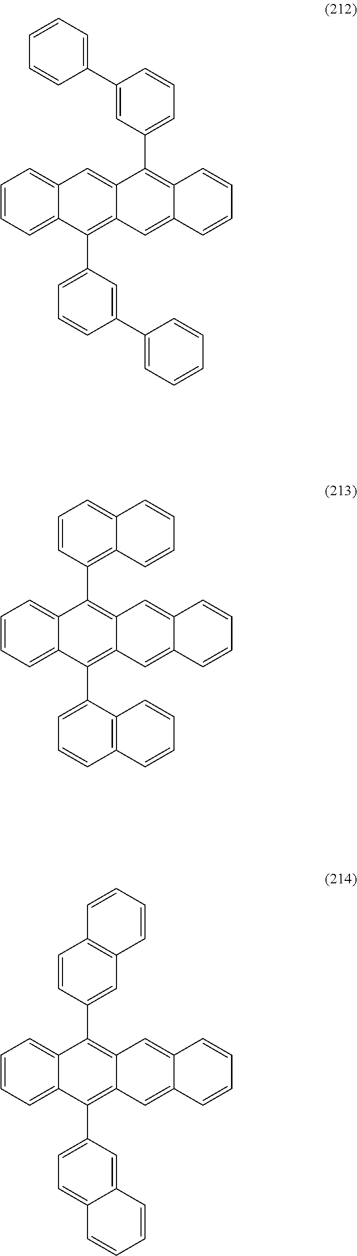

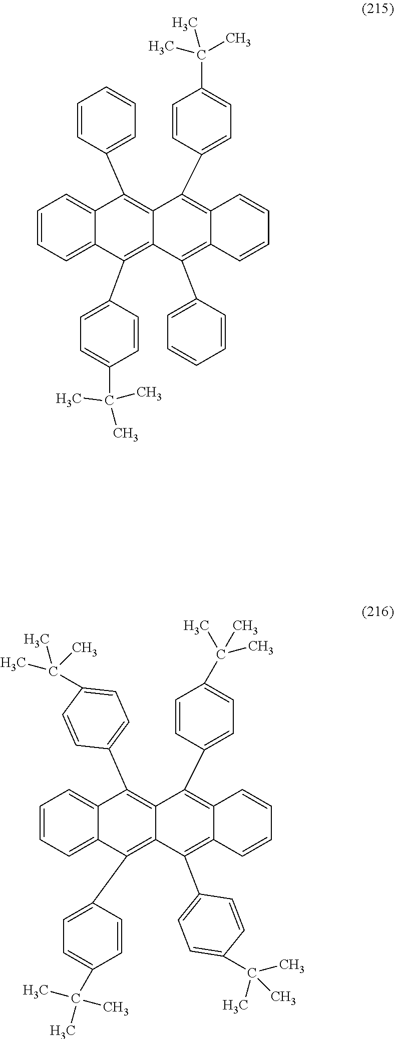

As a p-type semiconductor material contained in the active layer 23, an electron-donating organic semiconductor material can be used. An organic compound represented by General Formula (G2-2) or Structural Formula (310) can be used as the p-type semiconductor material.

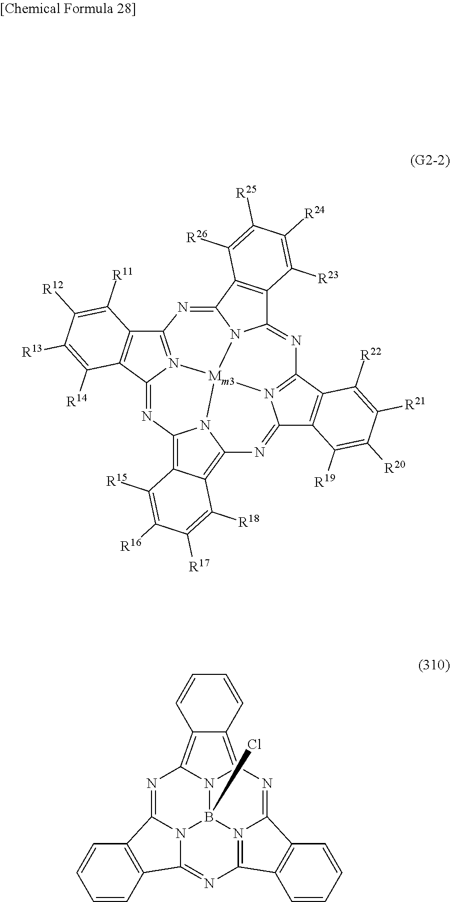

In General Formula (G2-2), M represents a metal, a metal oxide, or a metal halide; m₃ is 1 or 2; and R¹¹ to R²⁶ each independently represents hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

The organic compound represented by General Formula (G2-2) or Structural Formula (310) has a relatively low boiling point, and thus the evaporation temperature can be low. In one embodiment of the present invention, with the use of the organic compound represented by General Formula (G2-2) or Structural Formula (310) in the active layer 23, quality change of another film can be inhibited, and an optical device with favorable characteristics can be obtained. In addition, the productivity of the light-receiving device 10 can be increased.

Examples of R¹¹ to R²⁶ include the groups represented by Structural Formula (R-1) to Structural Formula (R-78) above.

Specifically, as a p-type semiconductor material contained in the active layer 23, an organic compound represented by any of Structural Formula (301) to Structural Formula (313) can be given. Note that an organic compound that can be used for one embodiment of the present invention is not limited thereto.

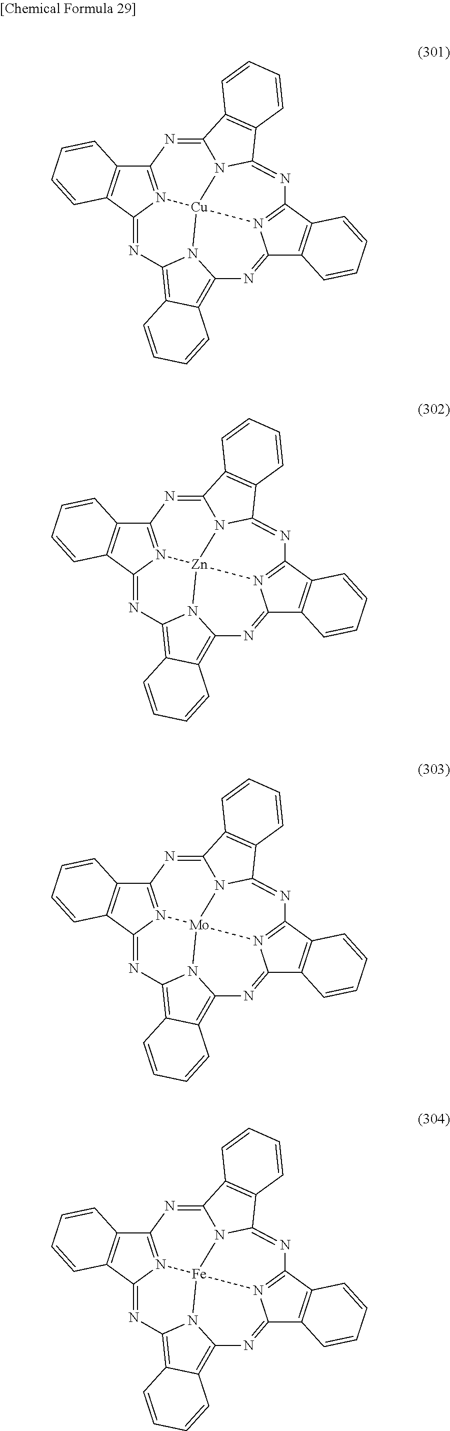

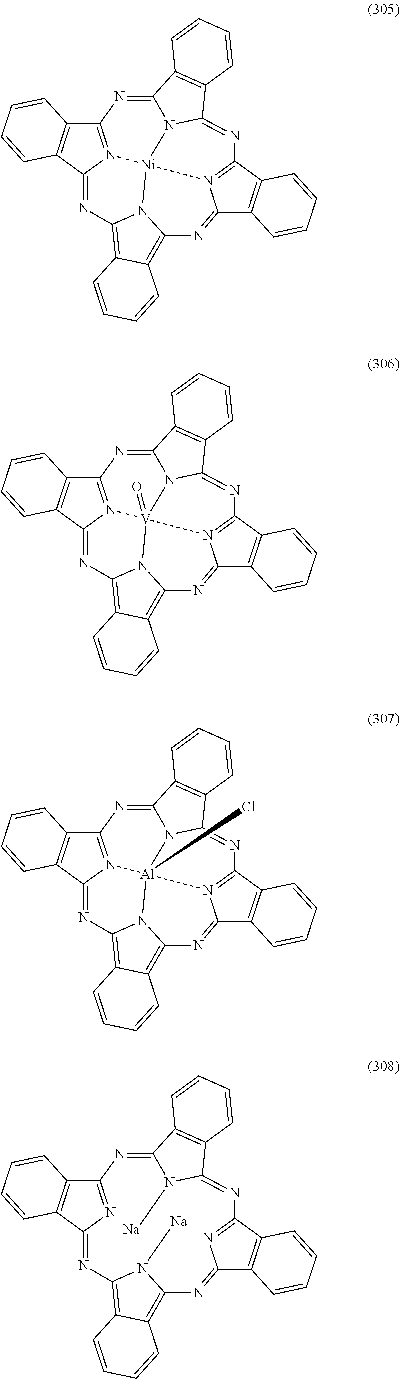

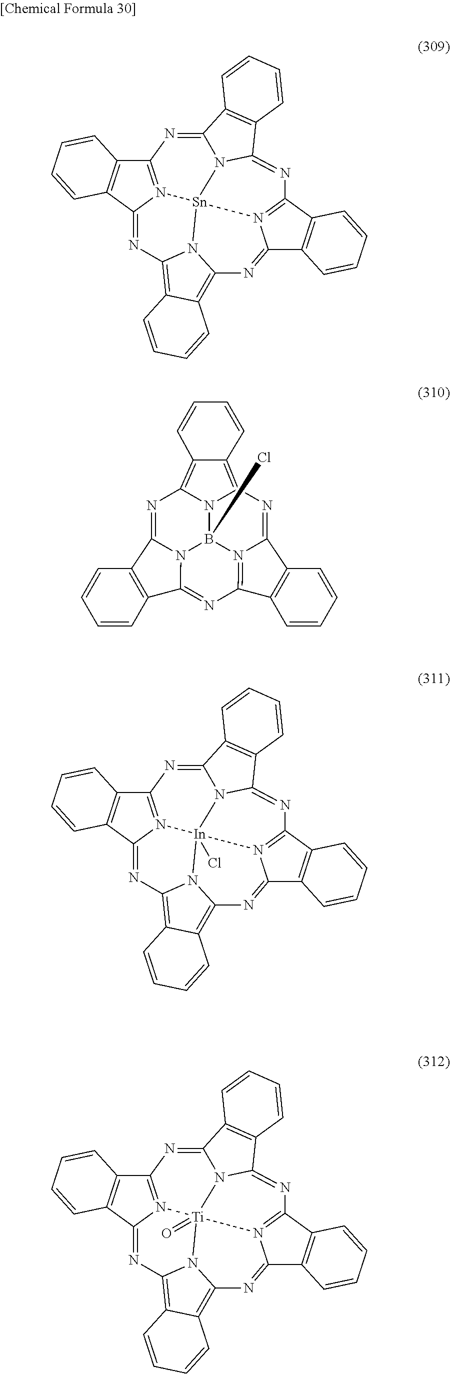

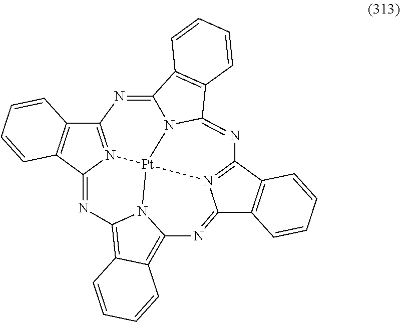

As a p-type semiconductor material contained in the active layer 23, an electron-donating organic semiconductor material can be used. An organic compound represented by General Formula (G2-3) can be used as the p-type semiconductor material.

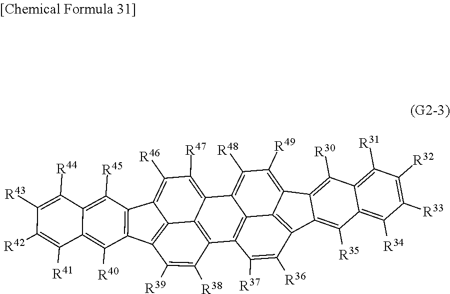

In General Formula (G2-3), R³⁰ to R⁴⁹ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

The organic compound represented by General Formula (G2-3) has a relatively low boiling point, and thus the evaporation temperature can be low. In one embodiment of the present invention, with the use of the organic compound represented by General Formula (G2-3) in the active layer 23, quality change of another film can be inhibited, and a light-receiving device with favorable characteristics can be obtained. In addition, the productivity of the light-receiving device 10 can be increased.

Examples of R³⁰ to R⁴⁹ include the groups represented by Structural Formula (R-1) to Structural Formula (R-78) above.

Specifically, as a p-type semiconductor material contained in the active layer 23, an organic compound represented by any of Structural Formula (401) to Structural Formula (403) can be given. Note that an organic compound that can be used for one embodiment of the present invention is not limited thereto.

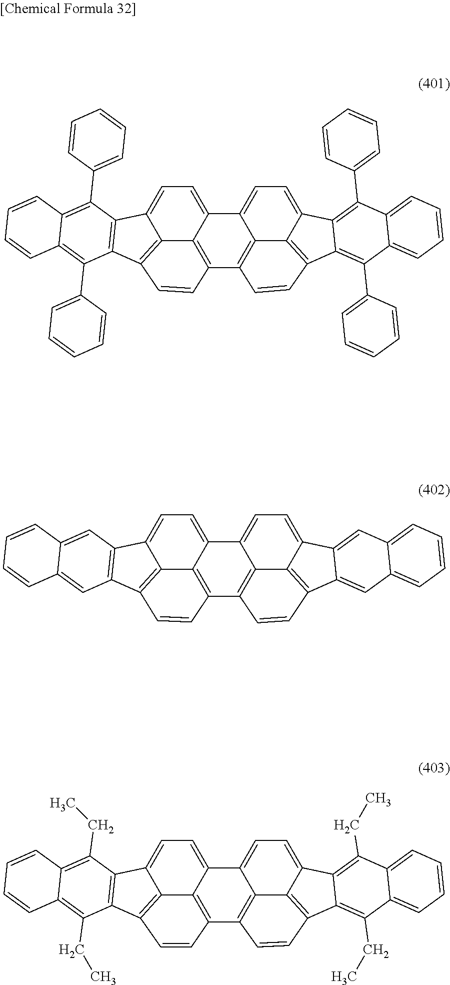

Examples of a p-type semiconductor material contained in the active layer 23 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can improve the carrier-transport property.

The active layer 23 contains the organic compound represented by General Formula (G1) and the organic compound represented by General Formula (G2-1), General Formula (G2-2), General Formula (G2-3), or Structural Formula (310), whereby the active layer 23 is unlikely to be affected by a material and thickness of a hole-transport layer 21 described later and a material and thickness of an electron-transport layer 25 described later, and the driving voltage of a light-receiving device can be lowered. In addition, a light-receiving device having high reliability can be achieved. Therefore, the range of choices for a material used for the light-receiving device can be expanded, and device design flexibility can be increased.

### [Carrier-Transport Layer]

In the light-receiving device 10, the layer 15 may include a carrier-transport layer. The carrier-transport layer is a layer containing a carrier-transport material. FIG. 1B illustrates an example where the light-receiving device 10 includes the hole-transport layer 21 as a carrier-transport layer and the electron-transport layer 25. The light-receiving device 10 illustrated in FIG. 1B has a structure in which the hole-transport layer 21, the active layer 23, and the electron-transport layer 25 are stacked in this order over the first electrode 11. Each of the hole-transport layer 21, the active layer 23, and the electron-transport layer 25 may have a single-layer structure or a stacked-layer structure. Note that although FIG. 1B illustrates an example where the light-receiving device 10 includes the hole-transport layer 21 and the electron-transport layer 25, one embodiment of the present invention is not limited thereto. A structure in which the light-receiving device 10 includes only one of the hole-transport layer 21 and the electron-transport layer 25 may be employed.

In the light-receiving device 10, the hole-transport layer 21 transports holes that are generated in the active layer 23 by incident light, to the anode. The hole-transport layer 21 is a layer containing a hole-transport material. As the hole-transport material, a substance having a hole mobility greater than or equal to 10⁻⁶ cm²/Vs is preferable. Note that other substances can also be used as long as they have a property of transporting more holes than electrons. As the hole-transport material, a material having a high hole-transport property, such as a π-electron-rich heteroaromatic compound (e.g., a carbazole derivative, a thiophene derivative, and a furan derivative) or an aromatic amine (a compound having an aromatic amine skeleton), is preferable.

The thickness of the hole-transport layer 21 is preferably greater than or equal to 5 nm and less than or equal to 500 nm, further preferably greater than or equal to 10 nm and less than or equal to 400 nm, still further preferably greater than or equal to 10 nm and less than or equal to 300 nm, yet further preferably greater than or equal to 10 nm and less than or equal to 200 nm.

When the thickness of the hole-transport layer 21 is made large, the driving voltage of the light-receiving device 10 is increased and power consumption is increased in some cases. The light-receiving device 10 of one embodiment of the present invention can inhibit the driving voltage from being increased even when the thickness of the hole-transport layer 21 is made large. Therefore, a light-receiving device with small power consumption can be obtained. Furthermore, when the thickness of the hole-transport layer 21 is in the above range, a light-receiving device with favorable characteristics and low power consumption can be obtained.

The driving voltage of the light-receiving device 10 is preferably greater than or equal to −5 V and less than or equal to 5 V, further preferably greater than or equal to −4 V and less than or equal to 4 V, still further preferably greater than or equal to −3 V and less than or equal to 3 V, yet further preferably greater than or equal to −2 V and less than or equal to 2 V, yet still further preferably greater than or equal to −1 V and less than or equal to 1 V. Furthermore, the driving voltage of the light-receiving device 10 is preferably as close to 0 V as possible. For example, driving voltage can be voltage at which current greater than or equal to a certain value flows. For example, voltage at which current greater than or equal to 20 nA flows can be driving voltage.

In the light-receiving device 10, the electron-transport layer 25 transports electrons that are generated in the active layer 23 by incident light, to the cathode. The electron-transport layer 25 is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The thickness of the electron-transport layer 25 is preferably greater than or equal to 5 nm and less than or equal to 500 nm, further preferably greater than or equal to 10 nm and less than or equal to 400 nm, still further preferably greater than or equal to 10 nm and less than or equal to 300 nm, yet further preferably greater than or equal to 20 nm and less than or equal to 300 nm.

When the thickness of the electron-transport layer 25 is made large, the driving voltage of the light-receiving device 10 is increased and power consumption is increased in some cases. The light-receiving device 10 of one embodiment of the present invention can inhibit the driving voltage from being increased even when the thickness of the electron-transport layer 25 is made large. Therefore, a light-receiving device with small power consumption can be obtained. Furthermore, when the thickness of the electron-transport layer 25 is in the above range, a light-receiving device with favorable characteristics and low power consumption can be obtained.

### [First Electrode and Second Electrode]

A conductive film that transmits visible light is used as the electrode through which light enters, which is either the first electrode 11 or the second electrode 13. A conductive film that reflects visible light is preferably used as the electrode through which no light is extracted. FIG. 1A and the like each illustrate an example of the light-receiving device 10 in which a conductive film that transmits visible light is used for the second electrode 13, and light entering the light-receiving device 10 is schematically denoted with a blank arrow.

Note that although this embodiment, FIG. 1A, and the like show the case where the first electrode 11 functions as an anode and the second electrode 13 functions as a cathode as an example, one embodiment of the present invention is not limited thereto. The first electrode 11 may function as a cathode and the second electrode 13 may function as an anode. In this case, the stacking order of the hole-transport layer 21, the active layer 23, and the electron-transport layer 25 is reversed.

As illustrated in FIG. 1C, the active layer 23 may have a stacked-layer structure of a first layer 23a and a second layer 23b. The first layer 23a includes a region in contact with the second layer 23b and is positioned between the first electrode 11 and the second layer 23b. FIG. 1C illustrates an example where the first layer 23a is provided on the side of the first electrode 11 functioning as an anode, and the second layer 23b is provided on the side of the second electrode 13 functioning as a cathode. A structure in which the first layer 23a contains a p-type semiconductor material and the second layer 23b contains an n-type semiconductor material (such a structure is referred to as a bilayer structure) can be employed. For example, the p-type semiconductor material that can be used for the active layer 23 can be used for the first layer 23a. The n-type semiconductor material that can be used for the active layer 23 can be used for the second layer 23b. When a bilayer structure is employed, leakage current can be inhibited in some cases. Therefore, an optical device with a high SN ratio can be obtained. Note that a structure applied to the active layer 23 (a bulk heterojunction structure or a bilayer structure) is appropriately selected. Furthermore, a structure other than a bulk heterojunction structure or a bilayer structure may be applied to the active layer 23.

As illustrated in FIG. 1D, in the light-receiving device 10, the hole-transport layer 21 may have a stacked-layer structure of a layer 21a and a layer 21b over the layer 21a. Furthermore, the electron-transport layer 25 may have a stacked-layer structure of a layer 25a and a layer 25b over the layer 25a.

As illustrated in FIG. 1E, in the light-receiving device 10, each of the hole-transport layer 21, the electron-transport layer 25, and the active layer 23 may have a stacked-layer structure.

### <Light-Emitting and Light-Receiving Device>

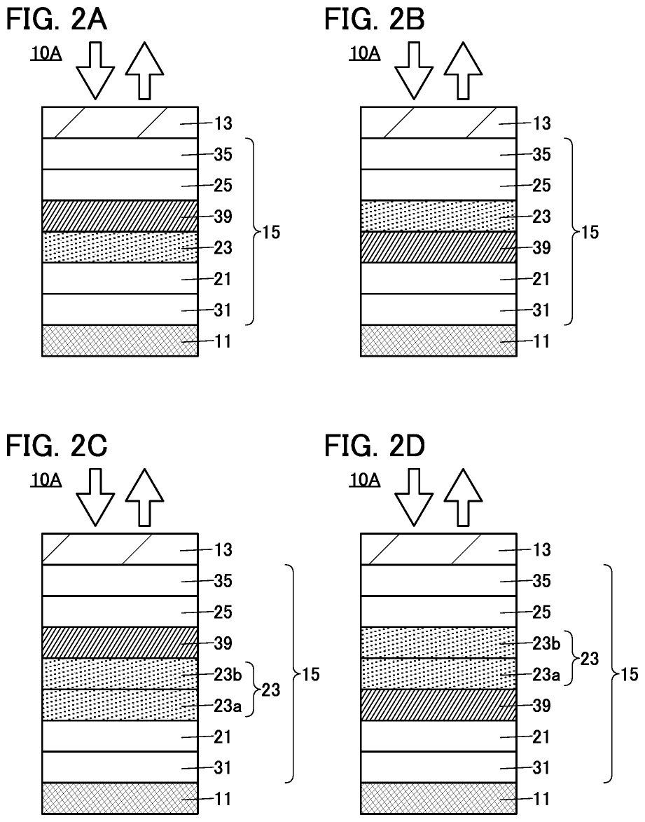

A structure example of a light-emitting and light-receiving device of one embodiment of the present invention is illustrated in FIG. 2A. FIG. 2A is a cross-sectional view illustrating a structure of a light-emitting and light-receiving device 10A. The light-emitting and light-receiving device 10A includes the first electrode 11, the second electrode 13, and the layer 15 positioned between the first electrode 11 and the second electrode 13. The layer 15 includes at least the active layer 23 and a light-emitting layer 39.

The light-emitting and light-receiving device 10A has both a function of emitting light (a light-emitting function) and a function of receiving light (a light-receiving function). The light-emitting and light-receiving device 10A can detect light having a shorter wavelength than light emitted from the light-emitting and light-receiving device 10A itself. FIG. 2A and the like each illustrate an example of the light-emitting and light-receiving device 10A in which a conductive film that transmits visible light is used for the second electrode 13, and light entering the light-emitting and light-receiving device 10A and light emitted from the light-emitting and light-receiving device 10A are schematically denoted with blank arrows.

The light-emitting and light-receiving device 10A can be fabricated by combining an organic EL element and an organic photodiode. For example, the light-emitting and light-receiving device 10A can be fabricated by adding the light-emitting layer 39 to the light-receiving device 10. In the light-emitting and light-receiving device 10A, concurrently forming layers that can be shared by the organic EL element and the organic photodiode can inhibit an increase in the number of deposition steps.

An organic EL element can easily be a thin and lightweight device having a large area and has a high degree of freedom for shape and design; thus, the light-emitting and light-receiving device 10A including an organic EL element can be used in a variety of devices.

In the light-emitting and light-receiving device 10A illustrated in FIG. 2A, the layer 15 includes a hole-injection layer 31, the hole-transport layer 21, the active layer 23, the light-emitting layer 39, the electron-transport layer 25, and an electron-injection layer 35. The light-emitting and light-receiving device 10A has a structure in which the hole-injection layer 31, the hole-transport layer 21, the active layer 23, the light-emitting layer 39, the electron-transport layer 25, and the electron-injection layer 35 are stacked in this order over the first electrode 11. Each of the hole-injection layer 31, the hole-transport layer 21, the active layer 23, the light-emitting layer 39, the electron-transport layer 25, and the electron-injection layer 35 may have a single-layer structure or a stacked-layer structure.

### [Light-Emitting Layer]

The light-emitting layer 39 is a layer containing a light-emitting substance. The light-emitting layer 39 can contain one or more kinds of light-emitting substances. As the light-emitting substance, a substance that exhibits an emission color of blue, purple, bluish purple, green, yellowish green, yellow, orange, red, or the like is appropriately used. As the light-emitting substance, a substance that emits near-infrared light can also be used.

Examples of the light-emitting substance include a fluorescent material, a phosphorescent material, a thermally activated delayed fluorescent (TADF) material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer 39 may contain one or more kinds of organic compounds (e.g., a host material and an assist material) in addition to the light-emitting substance (a guest material). As the one or more kinds of organic compounds, one or both of the hole-transport material and the electron-transport material can be used. Alternatively, as one or more kinds of organic compounds, a bipolar material or a TADF material may be used.

The light-emitting layer 39 preferably includes a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps the wavelength of a lowest-energy-side absorption band of the light-emitting substance, energy can be transferred smoothly and light emission can be obtained efficiently. With this structure, high efficiency, low-voltage driving, and a long lifetime of the light-emitting and light-receiving device 10A can be achieved at the same time.

In the combination of materials for forming an exciplex, the HOMO level (highest occupied molecular orbital level) of the hole-transport material is preferably higher than or equal to the HOMO level of the electron-transport material. The LUMO level (lowest unoccupied molecular orbital level) of the hole-transport material is preferably higher than or equal to the LUMO level of the electron-transport material. The LUMO levels and the HOMO levels of the materials can be derived from the electrochemical characteristics (reduction potentials and oxidation potentials) of the materials that are measured by cyclic voltammetry (CV).

Note that the formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

The hole-injection layer 31 is a layer injecting holes from the first electrode 11 to the hole-transport layer 21, and a layer containing a material with a high hole-injection property. As the material with a high hole-injection property, an aromatic amine compound or a composite material containing a hole-transport material and an acceptor material (electron-accepting material) can be used.

The electron-injection layer 35 is a layer injecting electrons from the second electrode 13 to the electron-transport layer 25, and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

Note that a layer included in the light-emitting and light-receiving device 10A might have a different function between the case where the light-emitting and light-receiving device 10A functions as the light-receiving device and the case where the light-emitting and light-receiving device 10A functions as the light-emitting device. In this specification, the name of a component is based on its function in the case where the light-emitting and light-receiving device 10A functions as a light-emitting device in some cases. For example, a hole-injection layer functions as a hole-injection layer in the case where the light-emitting and light-receiving device functions as a light-emitting device, and functions as a hole-transport layer in the case where the light-emitting and light-receiving device functions as a light-receiving device. Similarly, an electron-injection layer functions as an electron-injection layer in the case where the light-emitting and light-receiving device functions as a light-emitting device, and functions as an electron-transport layer in the case where the light-emitting and light-receiving device functions as a light-receiving device. A layer included in the light-emitting and light-receiving device might have the same function in both the case where the light-emitting and light-receiving device functions as the light-receiving device and the case where the light-emitting and light-receiving device functions as the light-emitting device. The hole-transport layer functions as a hole-transport layer in the case where the light-emitting and light-receiving device functions as either a light-emitting device or a light-receiving device, and the electron-transport layer functions as an electron-transport layer in the case where the light-emitting and light-receiving device functions as either a light-emitting device or a light-receiving device.

For example, when the light-emitting and light-receiving device 10A functions as a light-receiving device, the hole-injection layer 31 functions as a hole-transport layer; and when the light-emitting and light-receiving device 10A functions as a light-emitting device, the hole-injection layer 31 functions as a hole-injection layer. When the light-emitting and light-receiving device 10A functions as a light-receiving device, the electron-injection layer 35 functions as an electron-transport layer; and when the light-emitting and light-receiving device 10A functions as a light-emitting device, the electron-injection layer 35 functions as an electron-injection layer.

Note that in the light-receiving device 10 illustrated in FIG. 1D and the like, the material that can be used for the hole-injection layer 31 can be used for the layer 21a. Furthermore, the material that can be used for the electron-injection layer 35 can be used for the layer 25b.

As illustrated in FIG. 2B, the light-emitting and light-receiving device 10A may have a structure in which the hole-injection layer 31, the hole-transport layer 21, the light-emitting layer 39, the active layer 23, the electron-transport layer 25, and the electron-injection layer 35 are stacked in this order over the first electrode 11.

As illustrated in FIG. 2C and FIG. 2D, the active layer 23 may have a stacked-layer structure of the first layer 23a and the second layer 23b. The above description can be referred to for the first layer 23a and the second layer 23b; thus, the detailed description thereof is omitted.

The active layer 23 contains the organic compound represented by General Formula (G1) and the organic compound represented by General Formula (G2-1), General Formula (G2-2), or General Formula (G2-3), whereby the active layer 23 is unlikely to be affected by a material and thickness of the hole-transport layer 21 and a material and thickness of the electron-transport layer 25, and the driving voltage of a light-emitting and light-receiving device can be lowered. In addition, a light-emitting and light-receiving device having high reliability can be achieved. Therefore, the range of choices for a material used for the light-emitting and light-receiving device can be expanded, and device design flexibility can be increased.

This embodiment can be combined with the other embodiment as appropriate.

### EMBODIMENT 2

In this embodiment, a display apparatus of one embodiment of the present invention will be described.

The display apparatus of one embodiment of the present invention includes a light-receiving device and a light-emitting device (also referred to as a light-emitting element). One or both of the light-receiving device and the light-emitting and light-receiving device described in Embodiment 1 can be suitably used for the display apparatus of one embodiment of the present invention.

The display apparatus of one embodiment of the present invention has a function of detecting light using the light-receiving device. The light-receiving device can be used as an image sensor. For example, the display apparatus can take an image using the light-receiving device. For example, the display apparatus described in this embodiment can be used as a scanner.

For example, data on biological information such as a fingerprint or a palm print can be obtained with the use of the image sensor. That is, a biometric authentication sensor can be incorporated in the display apparatus of one embodiment of the present invention. When the display apparatus incorporates a biometric authentication sensor, the number of components of an electronic device can be reduced as compared to the case where a biometric authentication sensor is provided separately from the display apparatus; thus, a small and lightweight electronic device can be achieved.

The light-receiving device can be used as a touch sensor, for example. The display apparatus described in this embodiment can detect touch operation of an object using the light-receiving device.

As the light-emitting device, an EL element (also referred to as an EL device) such as an OLED (Organic Light Emitting Diode) or a QLED (Quantum-dot Light Emitting Diode) is preferably used. Examples of a light-emitting substance contained in the EL element include a substance exhibiting fluorescence (a fluorescent material), a substance exhibiting phosphorescence (a phosphorescent material), an inorganic compound (such as a quantum dot material), and a substance exhibiting thermally activated delayed fluorescence (a thermally activated delayed fluorescence (TADF) material). In addition, an LED (Light Emitting Diode) such as a micro-LED can be used as the light-emitting device.

In one embodiment of the present invention, an organic EL element (also referred to as an organic EL device) is used as the light-emitting device, and an organic photodiode is used as the light-receiving device. The organic EL element and the organic photodiode can be formed over one substrate. Thus, the organic photodiode can be incorporated in the display apparatus including the organic EL element.

If all the layers of the organic EL element and the organic photodiode are formed separately, the number of deposition steps becomes extremely large. Since a large number of layers of the organic photodiode can have structures in common with the organic EL element, concurrently depositing the layers that can have a common structure can inhibit an increase in the number of deposition steps.

For example, one of a pair of electrodes (a common electrode) can be a layer shared by the light-receiving device and the light-emitting device. As another example, at least one of a hole-injection layer, a hole-transport layer, an electron-transport layer, and an electron-injection layer is preferably shared by the light-receiving device and the light-emitting device. As another example, the light-receiving device and the light-emitting device can have the same structure except that the light-receiving device includes an active layer and the light-emitting device includes a light-emitting layer. In other words, the light-receiving device can be manufactured by only replacing the light-emitting layer of the light-emitting device with an active layer. When the light-receiving device and the light-emitting device include common layers in such a manner, the number of deposition steps and the number of masks can be reduced, thereby reducing the number of manufacturing steps and the manufacturing cost of the display apparatus. Furthermore, the display apparatus including the light-receiving device can be manufactured using an existing manufacturing apparatus and an existing manufacturing method for the display apparatus.

Note that a layer shared by the light-receiving device and the light-emitting device might have functions different in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device might have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

Next, a display apparatus including a light-emitting and light-receiving device and a light-emitting device is described.

In the display apparatus of one embodiment of the present invention, a subpixel exhibiting any color includes a light-emitting and light-receiving device instead of a light-emitting device, and subpixels exhibiting the other colors each include a light-emitting device. The light-emitting and light-receiving device has both a function of emitting light (a light-emitting function) and a function of receiving light (a light-receiving function). For example, in the case where a pixel includes three subpixels of red, green, and blue, at least one of the subpixels includes a light-emitting and light-receiving device and the other subpixels each include a light-emitting device. Thus, a display portion of the display apparatus of one embodiment of the present invention has a function of displaying an image using both a light-emitting and light-receiving device and a light-emitting device.

The light-emitting and light-receiving device functions as both a light-emitting device and a light-receiving device, whereby the pixel can have a light-receiving function without an increase in the number of subpixels included in the pixel. Thus, the display portion of the display apparatus can be provided with one or both of an image capturing function and a sensing function while keeping the aperture ratio of the pixel (aperture ratio of each subpixel) and the resolution of the display apparatus. Accordingly, in the display apparatus of one embodiment of the present invention, the aperture ratio of the pixel can be more increased and the resolution can be increased more easily than in a display apparatus provided with a subpixel including a light-receiving device separately from a subpixel including a light-emitting device.

In the display apparatus of one embodiment of the present invention, the light-emitting and light-receiving devices and the light-emitting devices are arranged in a matrix in the display portion, and an image can be displayed on the display portion. The display portion can be used as an image sensor or a touch sensor. In the display apparatus of one embodiment of the present invention, the light-emitting device can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting device included in the display portion, the light-emitting and light-receiving device can detect the reflected light (or the scattered light); thus, image capturing and touch operation detection are possible even in a dark place.

The light-emitting and light-receiving device can be manufactured by combining an organic EL element and an organic photodiode. For example, by adding an active layer of an organic photodiode to a stacked-layer structure of an organic EL element, the light-emitting and light-receiving device can be fabricated. Furthermore, in the light-emitting and light-receiving device manufactured of a combination of an organic EL element and an organic photodiode, concurrently forming layers that can be shared with the organic EL element can inhibit an increase in the number of deposition steps.

For example, one of a pair of electrodes (a common electrode) can be a layer shared by the light-emitting and light-receiving device and the light-emitting device. In another example, at least one of a hole-injection layer, a hole-transport layer, an electron-transport layer, and an electron-injection layer is preferably a layer shared by the light-emitting and light-receiving device and the light-emitting device. In another example, the light-emitting and light-receiving device and the light-emitting device can have the same structure except for the presence or absence of an active layer of the light-receiving device. In other words, the light-emitting and light-receiving device can be manufactured by only adding the active layer of the light-receiving device to the light-emitting device. When the light-emitting and light-receiving device and the light-emitting device include a common layer in such a manner, the number of deposition steps and the number of masks can be reduced, thereby reducing the number of manufacturing steps and the manufacturing cost of the display apparatus. Furthermore, the display apparatus including the light-emitting and light-receiving device can be manufactured using an existing manufacturing apparatus and an existing manufacturing method for the display apparatus.

The display apparatus of this embodiment has a function of displaying an image using the light-emitting device and the light-emitting and light-receiving device. That is, the light-emitting device and the light-emitting and light-receiving device function as display elements.

The display apparatus of this embodiment has a function of detecting light using the light-emitting and light-receiving device. The light-emitting and light-receiving device can detect light having a shorter wavelength than light emitted from the light-emitting and light-receiving device itself.

When the light-emitting and light-receiving device is used as an image sensor, the display apparatus of this embodiment can capture an image using the light-emitting and light-receiving device. For example, the display apparatus of this embodiment can be used as a scanner.

When the light-emitting and light-receiving device is used as a touch sensor, the display apparatus of this embodiment can detect touch operation of an object with the use of the light-emitting and light-receiving device.

The light-emitting and light-receiving device functions as a photoelectric conversion element that detects light entering the light-emitting and light-receiving device and generates electric charge. The amount of electric charge generated from the light-emitting and light-receiving device depends on the amount of light entering the light-emitting and light-receiving device.

The light-emitting and light-receiving device can be manufactured by adding an active layer of a light-receiving device to the above-described structure of the light-emitting device.

For the light-emitting and light-receiving device, an active layer of a pn photodiode or a pin photodiode can be used, for example.

It is particularly preferable to use, for the light-emitting and light-receiving device, an active layer of an organic photodiode including a layer containing an organic compound. An organic photodiode is easily made thin, lightweight, and large in area and has a high degree of freedom for shape and design, and thus the light-emitting and light-receiving device including the organic photodiode can be used in a variety of devices.

Structure examples of the display apparatus of one embodiment of the present invention will be described.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, a top-emission display apparatus is described as an example.

### <Structure Example 1 of Display Apparatus>

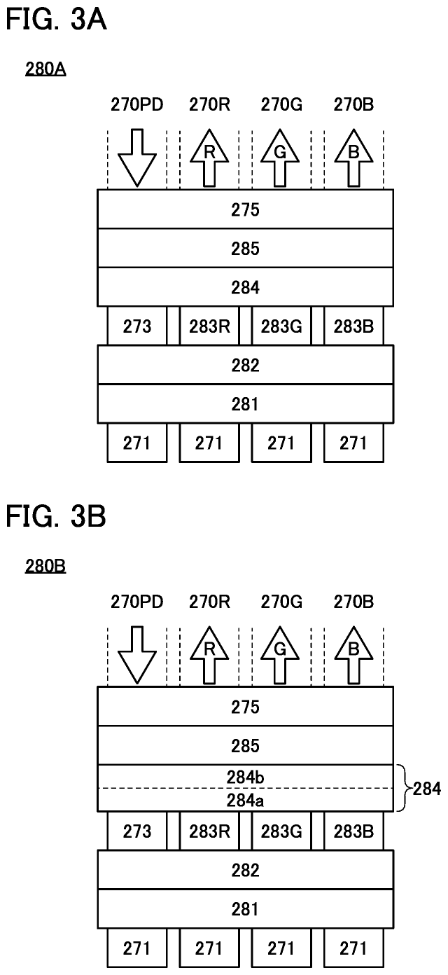

FIG. 3A illustrates a structure example of the display apparatus of one embodiment of the present invention. FIG. 3A is a cross-sectional view illustrating a structure example of a display apparatus 280A. The display apparatus 280A illustrated in FIG. 3A includes a light-receiving device 270PD, a light-emitting device 270R that emits red (R) light, a light-emitting device 270G that emits green (G) light, and a light-emitting device 270B that emits blue (B) light.

The light-receiving device 270PD is a photoelectric conversion element that receives light entering from the outside of the display apparatus 280A and converts it into an electric signal.

The light-receiving device 270PD includes a first pixel electrode 271, a hole-injection layer 281, a hole-transport layer 282, the active layer 273, an electron-transport layer 284, an electron-injection layer 285, and a second electrode 275 which are stacked in this order.

The structure of the light-receiving device 10 described in Embodiment 1 can be used for the light-receiving device 270PD. Note that in the light-receiving device 270PD, the first electrode 271 corresponds to the first electrode 11 of the light-receiving device 10 described in Embodiment 1. The hole-injection layer 281 corresponds to the layer 21a. The hole-transport layer 282 corresponds to the layer 21b. The active layer 273 corresponds to the active layer 23. The electron-transport layer 284 corresponds to the layer 25a. The electron-injection layer 285 corresponds to the layer 25b. The second electrode 275 corresponds to the second electrode 13.

A light-emitting device 270 is an electroluminescent device that emits light to the second electrode 275 side by voltage application between the first electrode 271 and the second electrode 275.

Each light-emitting device 270 includes the first electrode 271, the hole-injection layer 281, the hole-transport layer 282, a light-emitting layer, the electron-transport layer 284, the electron-injection layer 285, and the second electrode 275 which are stacked in this order. The light-emitting device 270R includes a light-emitting layer 283R, the light-emitting device 270G includes a light-emitting layer 283G, and the light-emitting device 270B includes a light-emitting layer 283B. The light-emitting layer 283R contains a light-emitting substance that emits red light, the light-emitting layer 283G contains a light-emitting substance that emits green light, and the light-emitting layer 283B contains a light-emitting substance that emits blue light. For example, the first electrode 271 functions as a pixel electrode and the second electrode 275 functions as a common electrode.

In this specification and the like, unless otherwise specified, in describing a structure including a plurality of elements (e.g., light-emitting devices and light-emitting layers), alphabets are not added when a common part of the elements is described. For example, when a common part of the light-emitting device 270R, the light-emitting device 270G, and the like is described, the light-emitting devices are simply referred to as the light-emitting device 270, in some cases. For example, when a common part of the light-emitting layer 283R, the light-emitting layer 283G, and the like is described, the light-emitting layers are simply referred to as a light-emitting layer 283, in some cases.

In the description made in this embodiment, the first electrode 271 functions as an anode and the second electrode 275 functions as a cathode in both the light-emitting device 270 and the light-receiving device 270PD. In other words, when the light-receiving device 270PD is driven by application of reverse bias between the first electrode 271 and the second electrode 275, light entering the light-receiving device 270PD can be detected and electric charge can be generated and extracted as current.

In the display apparatus of this embodiment, an organic compound is used for the active layer 273 of the light-receiving device 270PD. In the light-receiving device 270PD, the layers other than the active layer 273 can have structures in common with the layers in the light-emitting device 270. Therefore, the light-receiving device 270PD can be formed concurrently with formation of the light-emitting device 270 only by adding a step of depositing the active layer 273 in the manufacturing process of the light-emitting device 270. In addition, the light-emitting device 270 and the light-receiving device 270PD can be formed over the same substrate. Accordingly, the light-receiving device 270PD can be incorporated into the display apparatus without a significant increase in the number of manufacturing steps.

As a semiconductor in the active layer 273, it is particularly preferable to use an organic semiconductor. With the use of an organic semiconductor, the light-emitting layer 283 and the active layer 273 can be formed by the same method (e.g., a vacuum evaporation method) and thus the same manufacturing apparatus can be used.

The display apparatus 280A shows an example in which the light-receiving device 270PD and the light-emitting device 270 have a common structure except that the active layer 273 of the light-receiving device 270PD and the light-emitting layer 283 of the light-emitting device 270 are separately formed. Note that the structures of the light-receiving device 270PD and the light-emitting device 270 are not limited thereto. The light-receiving device 270PD and the light-emitting device 270 may have a separately formed layer in addition to the active layer 273 and the light-emitting layer 283. The light-receiving device 270PD and the light-emitting device 270 preferably include at least one layer used in common (common layer). Thus, the light-receiving device 270PD can be incorporated into the display apparatus without a significant increase in the number of manufacturing steps.

The light-emitting device 270 included in the display apparatus 280A preferably employ a microcavity structure. Therefore, one of the pair of electrodes of the light-emitting device 270 is preferably an electrode having properties of transmitting and reflecting visible light (a semi-transmissive and semi-reflective electrode), and the other is preferably an electrode having a property of reflecting visible light (a reflective electrode). When the light-emitting devices have a microcavity structure, light obtained from the light-emitting layers can be resonated between the electrodes, whereby light emitted from the light-emitting devices can be intensified.

Note that the semi-transmissive and semi-reflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting devices. The semi-transmissive and semi-reflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm. Note that in the case where any of the light-emitting devices emits near-infrared light (light with a wavelength greater than or equal to 750 nm and less than or equal to 1300 nm), the near-infrared light transmittance and reflectivity of these electrodes preferably satisfy the above-described numerical ranges of the visible light transmittance and reflectivity.

The light-emitting device 270 includes at least the light-emitting layer 283. In addition to the light-emitting layer 283, the light-emitting device 270 may further include a layer containing a substance with a high hole-injection property, a substance with a high hole-transport property, a hole-blocking material, a substance with a high electron-transport property, a substance with a high electron-injection property, a substance with a bipolar property (a substance with a high electron- and hole-transport property), or the like.

For example, the light-emitting device 270 and the light-receiving device 270PD can share at least one of the hole-injection layer, the hole-transport layer, the electron-transport layer, and the electron-injection layer. Furthermore, at least one of the hole-injection layer, the hole-transport layer, the electron-transport layer, and the electron-injection layer can be separately formed for the light-emitting device 270 and the light-receiving device 270PD.

The hole-injection layer is a layer injecting holes from an anode to the hole-transport layer, and a layer containing a material with a high hole-injection property. As the material with a high hole-injection property, an aromatic amine compound or a composite material containing a hole-transport material and an acceptor material (electron-accepting material) can be used.

In the light-emitting device 270, the hole-transport layer transports holes that are injected from the anode by the hole-injection layer, to the light-emitting layer.

The thickness of the hole-transport layer 282 is preferably greater than or equal to 5 nm and less than or equal to 500 nm, further preferably greater than or equal to 10 nm and less than or equal to 400 nm, still further preferably greater than or equal to 10 nm and less than or equal to 300 nm, yet further preferably greater than or equal to 10 nm and less than or equal to 200 nm.

In the light-receiving device, when the thickness of the hole-transport layer 282 is made large, the driving voltage of the light-receiving device 270PD is increased and power consumption is increased in some cases. Furthermore, as the power consumption of the light-receiving device 270PD is increased, the power consumption of the display apparatus 280A is increased in some cases. The light-receiving device 270PD of one embodiment of the present invention can inhibit the driving voltage from being increased even when the thickness of the hole-transport layer 282 is made large. Therefore, a light-receiving device with small power consumption can be obtained. Furthermore, when the thickness of the hole-transport layer 282 is in the above range, a light-receiving device with favorable characteristics and low power consumption can be obtained. Therefore, a display apparatus with favorable characteristics and low power consumption can be obtained.

For example, with the thickness of the hole-transport layer 282, the optical path length (cavity length) of the microcavity structure can be adjusted. In the light-receiving device of one embodiment of the present invention, an increase in driving voltage can be inhibited even when the thickness of the hole-transport layer 282 is made large, and thus both optical path length (cavity length) adjustment and low power consumption can be achieved.

In the light-emitting device 270, the electron-transport layer transports electrons that are injected from the cathode by the electron-injection layer, to the light-emitting layer.

The thickness of the electron-transport layer 284 is preferably greater than or equal to 5 nm and less than or equal to 500 nm, further preferably greater than or equal to 10 nm and less than or equal to 400 nm, still further preferably greater than or equal to 10 nm and less than or equal to 300 nm, yet further preferably greater than or equal to 20 nm and less than or equal to 300 nm.

In the light-receiving device, when the thickness of the electron-transport layer 284 is made large, the driving voltage of the light-receiving device 270PD is increased and power consumption is increased in some cases. Furthermore, as the power consumption of the light-receiving device 270PD is increased, the power consumption of the display apparatus 280A is increased in some cases. The light-receiving device 270PD of one embodiment of the present invention can inhibit the driving voltage from being increased even when the thickness of the electron-transport layer 284 is made large. Therefore, a light-receiving device with small power consumption can be obtained. Furthermore, when the thickness of the electron-transport layer 284 is in the above range, a light-receiving device with favorable characteristics and low power consumption can be obtained. Therefore, a display apparatus with favorable characteristics and low power consumption can be obtained.

The electron-injection layer is a layer injecting electrons from a cathode to the electron-transport layer, and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

### <Structure Example 2 of Display Apparatus>

A structure different from that of the display apparatus 280A illustrated in FIG. 3A is illustrated in FIG. 3B. A display apparatus 280B illustrated in FIG. 3B is different from the display apparatus 280A mainly in that the electron-transport layer 284 has a stacked-layer structure of a first electron-transport layer 284a and a second electron-transport layer 284b. The first electron-transport layer 284a is positioned on the active layer 273 side, and the second electron-transport layer 284b is positioned on the electron-injection layer 285 side.

Note that although in FIG. 3B, an example is illustrated in which the electron-transport layer 284 has a two-layer structure of the first electron-transport layer 284a and the second electron-transport layer 284b, one embodiment of the present invention is not limited thereto. The electron-transport layer 284 may have a stacked-layer structure of three or more layers, and each of the first electron-transport layer 284a and the second electron-transport layer 284b may have a stacked-layer structure.

### <Structure Example 3 of Display Apparatus>

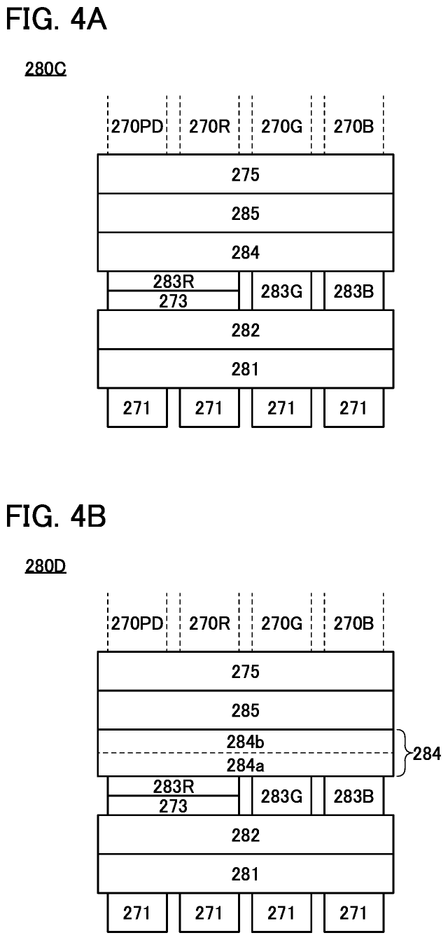

A structure different from that of the display apparatus 280A illustrated in FIG. 3A is illustrated in FIG. 4A. A display apparatus 280C illustrated in FIG. 4A is different from the display apparatus 280A mainly in that the light-receiving device 270PD and the light-emitting device 270R have the same structure.

The light-receiving device 270PD and the light-emitting device 270R share the active layer 273 and the light-emitting layer 283R.

Here, it is preferable that the light-receiving device 270PD have a structure in common with the light-emitting device that emits light with a longer wavelength than the light desired to be detected. For example, the light-receiving device 270PD having a structure in which blue light is detected can have a structure which is similar to that of one or both of the light-emitting device 270R and the light-emitting device 270G. For example, the light-receiving device 270PD having a structure in which green light is detected can have a structure similar to that of the light-emitting device 270R.

When the light-receiving device 270PD and the light-emitting device 270R have a common structure, the number of deposition steps and the number of masks can be reduced from those in the structure in which the light-receiving device 270PD and the light-emitting device 270R include separately formed layers. As a result, the number of manufacturing steps and the manufacturing cost of the display apparatus can be reduced.

The structure of the light-emitting and light-receiving device 10A described in Embodiment 1 can be applied to any one or more of the light-receiving device 270PD and the light-emitting device 270R. The structure of the light-emitting and light-receiving device 10A may be applied to both the light-receiving device 270PD and the light-emitting device 270R.

When the light-receiving device 270PD and the light-emitting device 270R have a common structure, a margin for misalignment can be narrower than that for the structure in which the light-receiving device 270PD and the light-emitting device 270R include separately formed layers. Accordingly, the aperture ratio of a pixel can be increased, so that the light extraction efficiency of the display apparatus can be increased. This can extend the life of the light-emitting device. Furthermore, the display apparatus can exhibit a high luminance. Furthermore, when the display apparatus of one embodiment of the present invention is used, a display apparatus having high resolution can be achieved.

The light-emitting layer 283R includes a light-emitting material that emits red light. The active layer 273 includes an organic compound that absorbs light with a wavelength shorter than that of red light (e.g., one or both of green light and blue light). The active layer 273 preferably includes an organic compound that does not easily absorb red light and that absorbs light with a wavelength shorter than that of red light. In this way, red light can be efficiently extracted from the light-emitting device 270R, and the light-receiving device 270PD can detect light with a shorter wavelength than red light at high accuracy.

Although the light-emitting device 270R and the light-receiving device 270PD have the same structure in an example of the display apparatus 280C, the light-emitting device 270R and the light-receiving device 270PD may include optical adjustment layers with different thicknesses.

### <Structure Example 4 of Display Apparatus>

A structure different from that of the display apparatus 280C illustrated in FIG. 4A is illustrated in FIG. 4B. A display apparatus 280D illustrated in FIG. 4B is different from the display apparatus 280A mainly in that the electron-transport layer 284 has a stacked-layer structure of the first electron-transport layer 284a and the second electron-transport layer 284b.

The above description can be referred to for the first electron-transport layer 284a and the second electron-transport layer 284b; thus, the detailed description thereof is omitted.

### <Structure Example 5 of Display Apparatus>

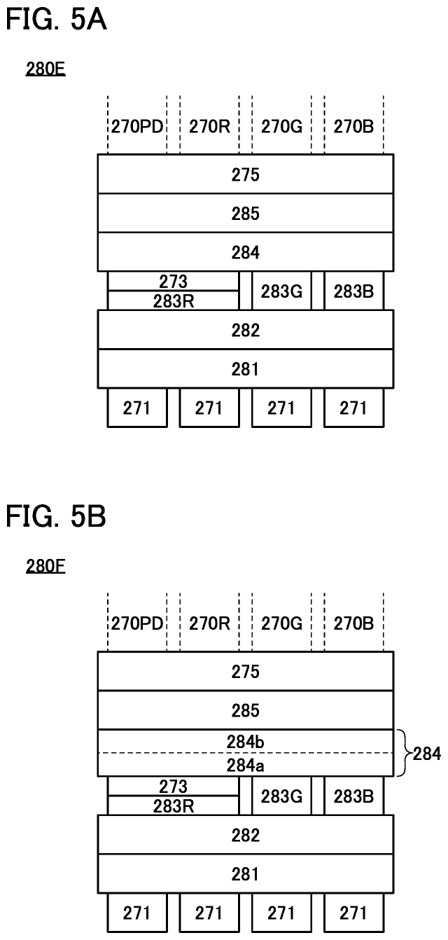

Although an example is described in which the display apparatus 280C illustrated in FIG. 4A and the display apparatus 280D illustrated in FIG. 4B are each provided with the active layer 273 on the first electrode 281 side and the light-emitting layer 283R on the second electrode 275 side, one embodiment of the present invention is not limited thereto. A structure different from that of the display apparatus 280C is illustrated in FIG. 5A. A structure different from that of the display apparatus 280D is illustrated in FIG. 5B. A display apparatus 280E and a display apparatus 280F are different from the display apparatus 280C and the display apparatus 280D mainly in the structures of the active layer 273 and the light-emitting layer 283R.

The display apparatus 280E and the display apparatus 280F each include the light-emitting layer 283R on the first electrode 281 side and the active layer 273 on the second electrode 275 side.

### <Structure Example 6 of Display Apparatus>

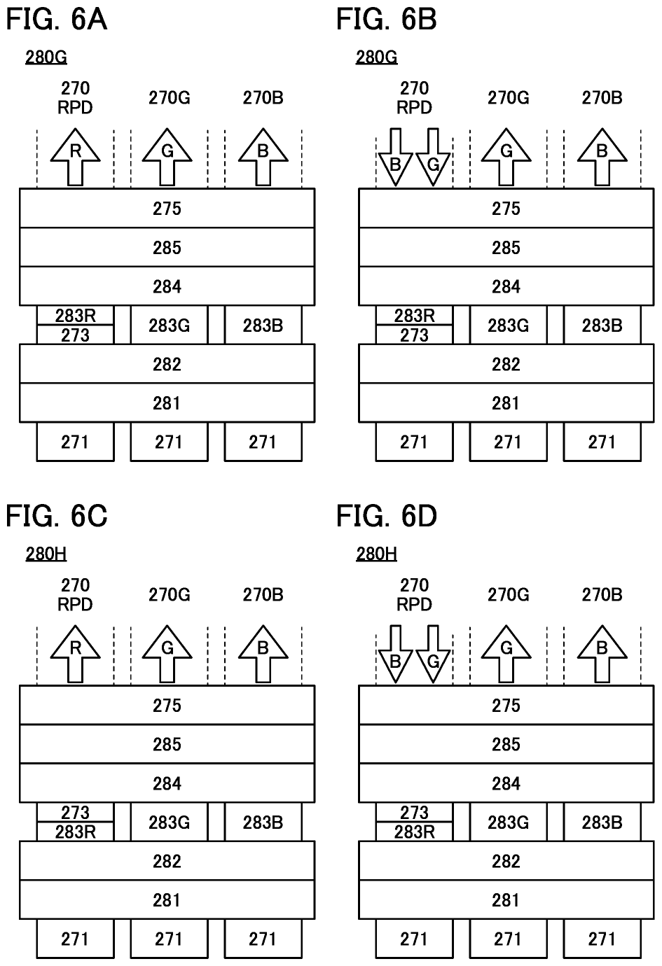

A structure different from that of the display apparatus 280A illustrated in FIG. 3A is illustrated in FIG. 6A and FIG. 6B. A display apparatus 280G illustrated in FIG. 6A and FIG. 6B includes a light-emitting and light-receiving device 270RPD that emits red (R) light and has a light-receiving function, the light-emitting device 270G that emits green (G) light, and the light-emitting device 270B that emits blue (B) light.

Each of the light-emitting devices includes the first electrode 271, the hole-injection layer 281, the hole-transport layer 282, the light-emitting layer, the electron-transport layer 284, the electron-injection layer 285, and the second electrode 275 which are stacked in this order. The light-emitting device 270G includes the light-emitting layer 283G, and the light-emitting device 270B includes the light-emitting layer 283B. The light-emitting layer 283G contains a light-emitting substance that emits green light, and the light-emitting layer 283B contains a light-emitting substance that emits blue light.

The light-emitting and light-receiving device 270RPD includes the first electrode 271, the hole-injection layer 281, the hole-transport layer 282, the active layer 273, the light-emitting layer 283R, the electron-transport layer 284, the electron-injection layer 285, and the second electrode 275 which are stacked in this order.

Note that the light-emitting and light-receiving device 270RPD included in the display apparatus 280G has the same structure as the light-emitting device 270R and the light-receiving device 270PD included in the display apparatus 280C. Furthermore, the light-emitting devices 270G and 270B included in the display apparatus 280G also have the same structures as the light-emitting devices 270G and 270B, which are included in the display apparatus 280C.

FIG. 6A illustrates a case where the light-emitting and light-receiving device 270RPD functions as a light-emitting device. FIG. 6A illustrates an example in which the light-emitting device 270B emits blue light, the light-emitting device 270G emits green light, and the light-emitting and light-receiving device 270RPD emits red light.

FIG. 6B illustrates a case where the light-emitting and light-receiving device 270RPD functions as a light-receiving device. FIG. 6B illustrates an example in which the light-emitting and light-receiving device 270RPD detects blue light emitted from the light-emitting device 270B and green light emitted from the light-emitting device 270G.

The light-emitting device 270B, the light-emitting device 270G, and the light-emitting and light-receiving device 270RPD each include the first electrode 271 and the second electrode 275. In this embodiment, the case where the first electrode 271 functions as an anode and the second electrode 275 functions as a cathode is described as an example.

In the description made in this embodiment, also in the light-emitting and light-receiving device 270RPD, the first electrode 271 functions as an anode and the second electrode 275 functions as a cathode as in the light-emitting device. In other words, when the light-emitting and light-receiving device 270RPD is driven by application of reverse bias between the first electrode 271 and the second electrode 275, light entering the light-emitting and light-receiving device 270RPD can be detected and electric charge can be generated and extracted as current.

Note that it can be said that the light-emitting and light-receiving device 270RPD illustrated in FIG. 6A and FIG. 6B has a structure in which the active layer 273 is added to the light-emitting device. That is, the light-emitting and light-receiving device 270RPD can be formed concurrently with formation of the light-emitting device only by adding a step of forming the active layer 273 in the manufacturing process of the light-emitting device. The light-emitting device and the light-emitting and light-receiving device can be formed over the same substrate. Thus, the display portion can be provided with one or both of an image capturing function and a sensing function without a significant increase in the number of manufacturing steps.

The stacking order of the light-emitting layer 283R and the active layer 273 is not limited. FIG. 6A and FIG. 6B each illustrate an example in which the active layer 273 is provided over the hole-transport layer 282, and the light-emitting layer 283R is provided over the active layer 273. The light-emitting layer 283R may be provided over the hole-transport layer 282, and the active layer 273 may be provided over the light-emitting layer 283R.

As illustrated in FIG. 6A and FIG. 6B, the active layer 273 and the light-emitting layer 283R may be in contact with each other. Furthermore, a buffer layer may be interposed between the active layer 273 and the light-emitting layer 283R. As the buffer layer, at least one layer of a hole-injection layer, a hole-transport layer, an electron-transport layer, an electron-injection layer, a hole-blocking layer, an electron-blocking layer, and the like can be used.

The buffer layer provided between the active layer 273 and the light-emitting layer 283R can inhibit transfer of excitation energy from the light-emitting layer 283R to the active layer 273. Furthermore, the buffer layer can also be used to adjust the optical path length (cavity length) of the microcavity structure. Thus, a high emission efficiency can be obtained from the light-emitting and light-receiving device including the buffer layer between the active layer 273 and the light-emitting layer 283R.

The light-emitting and light-receiving device may exclude at least one of the hole-injection layer 281, the hole-transport layer 282, the electron-transport layer 284, and the electron-injection layer 285. Furthermore, the light-emitting and light-receiving device may include another functional layer such as a hole-blocking layer or an electron-blocking layer.

The light-emitting and light-receiving device may include, instead of including the active layer 273 and the light-emitting layer 283R, a layer serving as both a light-emitting layer and an active layer. As the layer serving as both a light-emitting layer and an active layer, a layer containing three materials which are an n-type semiconductor that can be used for the active layer 273, a p-type semiconductor that can be used for the active layer 273, and a light-emitting substance that can be used for the light-emitting layer 283R can be used, for example.

Note that an absorption band on the lowest energy side of an absorption spectrum of a mixed material of the n-type semiconductor and the p-type semiconductor and a maximum peak of an emission spectrum (PL spectrum) of the light-emitting substance preferably do not overlap each other and are further preferably positioned fully apart from each other.

In the light-emitting and light-receiving device, a conductive film that transmits visible light is used as the electrode through which light is extracted. A conductive film that reflects visible light is preferably used as the electrode through which no light is extracted.

The functions and materials of the layers constituting the light-emitting and light-receiving device are similar to those of the layers constituting the light-emitting devices and the light-receiving device and not described in detail here.

### <Structure Example 7 of Display Apparatus>

A structure different from that of the display apparatus 280G illustrated in FIG. 6A and FIG. 6B is illustrated in FIG. 6C and FIG. 6D.

The display apparatus 280H illustrated in FIG. 6C and FIG. 6D include the light-emitting layer 283R on the first electrode 281 side and the active layer 273 on the second electrode 275 side.

This embodiment can be combined with the other embodiment as appropriate.

### EMBODIMENT 3

In this embodiment, a display apparatus of one embodiment of the present invention will be described in detail.

The display apparatus of one embodiment of the present invention includes a light-receiving device and a light-emitting device in its display portion. The light-receiving device described in Embodiment 1 can be suitably used in the display apparatus of one embodiment of the present invention. The display apparatus of one embodiment of the present invention includes the light-receiving device and the light-emitting device in its display portion, has a function of displaying an image using the light-emitting device, and has one or both of an image capturing function and a sensing function.

Alternatively, the display apparatus of one embodiment of the present invention includes a light-emitting and light-receiving device (also referred to as a light-emitting and light-receiving device) and a light-emitting device.

First, the display apparatus including a light-receiving device and a light-emitting device is described.

In the display apparatus of one embodiment of the present invention, a plurality of pixels are arranged in a matrix in the display portion. The pixels each include a light-emitting device and a light-receiving device. That is, in the display apparatus of one embodiment of the present invention, the light-emitting devices are arranged in a matrix in the display portion, and an image can be displayed on the display portion. Furthermore, the light-receiving devices are arranged in a matrix in the display portion, and the display portion has one or both of an image capturing function and a sensing function. The display portion can be used as one or both of an image sensor and a touch sensor. That is, by detecting light with the display portion, an image can be captured or touch operation of an object (e.g., a finger or a stylus) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting device included in the display portion, the light-receiving device can detect the reflected light (or the scattered light); thus, image capturing or touch operation detection is possible even in a dark place.

The display apparatus of one embodiment of the present invention has a function of displaying an image using the light-emitting device. That is, the light-emitting device functions as a display device (also referred to as a display element).

In one embodiment of the present invention, an organic EL element (also referred to as an organic EL device) is used as the light-emitting device, and an organic photodiode is used as the light-receiving device. The organic EL element and the organic photodiode can be formed over one substrate. Thus, the organic photodiode can be incorporated in the display apparatus including the organic EL element.

The display apparatus of one embodiment of the present invention will be described below.

### <Structure Example 1 of Display Apparatus>

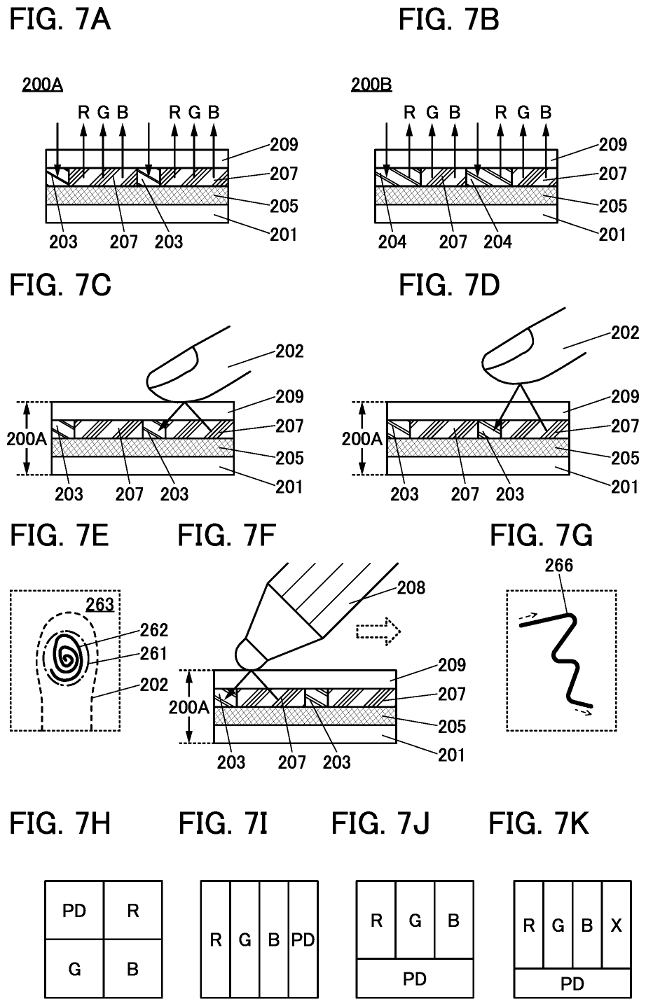

FIG. 7A to FIG. 7D and FIG. 7F each illustrate a cross-sectional view of the display apparatus of one embodiment of the present invention.

A display apparatus 200A illustrated in FIG. 7A includes a layer 203 including a light-receiving device, a functional layer 205, and a layer 207 including a light-emitting device between a substrate 201 and a substrate 209.

In the display apparatus 200A, red (R) light, green (G) light, and blue (B) light are emitted from the layer 207 including a light-emitting device.

The light-receiving device included in the layer 203 including a light-receiving device can detect light that enters from the outside of the display apparatus 200A.

A display apparatus 200B illustrated in FIG. 7B includes a layer 204 including a light-emitting and light-receiving device, the functional layer 205, and the layer 207 including a light-emitting device between the substrate 201 and the substrate 209.

In the display apparatus 200B, green (G) light and blue (B) light are emitted from the layer 207 including a light-emitting device, and red (R) light is emitted from the layer 204 including a light-emitting and light-receiving device. In the display apparatus of one embodiment of the present invention, the color of light emitted from the layer 204 including a light-emitting and light-receiving device is not limited to red. Furthermore, the color of light emitted from the layer 207 including a light-emitting device is not limited to the combination of green and blue.

The light-emitting and light-receiving device included in the layer 204 including a light-emitting and light-receiving device can detect light that enters from the outside of the display apparatus 200B. The light-emitting and light-receiving device can detect one or both of green (G) light and blue (B) light, for example.

The functional layer 205 includes a circuit for driving the light-receiving device or the light-emitting and light-receiving device and a circuit for driving the light-emitting device. A switch, a transistor, a capacitor, a resistor, a wiring, a terminal, and the like can be provided in the functional layer 205. Note that in the case where the light-emitting device and the light-receiving device are driven by a passive-matrix method, a structure not provided with a switch or a transistor may be employed.

The display apparatus of one embodiment of the present invention may have a function of detecting an object such as a finger that is touching the display apparatus (a function of a touch panel). For example, light emitted from the light-emitting device in the layer 207 including a light-emitting device is reflected by a finger 202 that is touching the display apparatus 200A as illustrated in FIG. 7C; then, the light-receiving device in the layer 203 including a light-receiving device detects the reflected light. Thus, the touch of the finger 202 on the display apparatus 200A can be detected. Furthermore, in the display apparatus 200B, after light emitted from the light-emitting device in the layer 207 including a light-emitting device is reflected by a finger that is touching the display apparatus 200B, the light-emitting and light-receiving device in the layer 204 including a light-emitting and light-receiving device can detect the reflected light. Although a case where light emitted from the light-emitting device is reflected by an object is described below as an example, light might be scattered by an object.

The display apparatus of one embodiment of the present invention may have a function of detecting an object that is close to (but is not touching) the display apparatus as illustrated in FIG. 7D or capturing an image of such an object.

The display apparatus of one embodiment of the present invention may have a function of detecting a fingerprint of the finger 202. FIG. 7E illustrates a diagram of an image captured by the display apparatus of one embodiment of the present invention. In an image-capturing range 263 in FIG. 7E, the outline of the finger 202 is indicated by a dashed line and the outline of a contact portion 261 is indicated by a dashed-dotted line. In the contact portion 261, a high-contrast image of a fingerprint 262 can be captured owing to a difference in the amount of light entering the light-receiving device (or the light-emitting and light-receiving device).

The display apparatus of one embodiment of the present invention can also function as a pen tablet. FIG. 7F illustrates a state in which a tip of a stylus 208 slides in a direction indicated by a dashed arrow while the tip of the stylus 208 touches the substrate 209.

As illustrated in FIG. 7F, when the scattered light scattered by the contact surface between the tip of the stylus 208 and the substrate 209 enters the light-receiving device (or the light-emitting and light-receiving device) that is positioned in a portion overlapping with the contact surface, the position of the tip of the stylus 208 can be detected with high accuracy.

FIG. 7G illustrates an example of a path 266 of the stylus 208 that is detected by the display apparatus of one embodiment of the present invention. The display apparatus of one embodiment of the present invention can detect the position of an object to be detected, such as the stylus 208, with high position accuracy, so that high-resolution drawing can be performed using a drawing application or the like. Unlike the case of using a capacitive touch sensor, an electromagnetic induction touch pen, or the like, the display apparatus can detect even the position of a highly insulating object to be detected, the material of a tip portion of the stylus 208 is not limited, and a variety of writing materials (e.g., a brush, a glass pen, a quill pen, and the like) can be used.

Pixel arrangement will be described.

The display apparatus of one embodiment of the present invention includes a plurality of pixels arranged in a matrix. One pixel includes a plurality of subpixels. One subpixel includes one light-emitting device, one light-emitting and light-receiving device, or one light-receiving device.

The plurality of pixels each include one or more of a subpixel including a light-emitting device, a subpixel including a light-receiving device, and a subpixel including a light-emitting and light-receiving device.

For example, the pixel includes a plurality of (e.g., three or four) subpixels each including a light-emitting device and one subpixel including a light-receiving device.

Note that the light-receiving device may be provided in all the pixels or may be provided in some of the pixels. In addition, one pixel may include a plurality of light-receiving devices. One light-receiving device may be provided across a plurality of pixels. The resolution of the light-receiving device may be different from the resolution of the light-emitting device.

In the case where the pixel includes three subpixels each including a light-emitting device, as the three subpixels, subpixels of three colors of R, G, and B, subpixels of three colors of yellow (Y), cyan (C), and magenta (M), and the like can be given. In the case where the pixel includes four subpixels each including a light-emitting device, as the four subpixels, subpixels of four colors of R, G, B, and white (W), subpixels of four colors of R, G, B, and Y, and the like can be given.

FIG. 7H, FIG. 7I, FIG. 7J, and FIG. 7K illustrate examples of a pixel which includes a plurality of subpixels each including a light-emitting device and includes one subpixel including a light-receiving device. Note that the arrangement of subpixels is not limited to the illustrated order in this embodiment. For example, the positions of a subpixel (B) and a subpixel (G) may be reversed.

The pixels illustrated in FIG. 7H, FIG. 7I, and FIG. 7J each include a subpixel (PD) having a light-receiving function, a subpixel (R) that exhibits red light, a subpixel (G) that exhibits green light, and a subpixel (B) that exhibits blue light.

Matrix arrangement is applied to the pixel illustrated in FIG. 7H, and stripe arrangement is applied to the pixel illustrated in FIG. 7I. FIG. 7J illustrates an example in which the subpixel (R) that exhibits red light, the subpixel (G) that exhibits green light, and the subpixel (B) that exhibits blue light are arranged laterally in one row and the subpixel (PD) having a light-receiving function is arranged thereunder. In other words, in FIG. 7J, the subpixel (R), the subpixel (G), and the subpixel (B) are arranged in the same row, which is different from the row in which the subpixel (PD) is provided.

The pixel illustrated in FIG. 7K includes a subpixel (X) that exhibits light of a color other than R, G, and B, in addition to the components of the pixel illustrated in FIG. 7J. The light of a color other than R, G, and B can be white (W) light, yellow (Y) light, cyan (C) light, magenta (M) light, infrared light (IR), or the like. In the case where the subpixel (X) exhibits infrared light, the subpixel (PD) having a light-receiving function preferably has a function of detecting infrared light. The subpixel (PD) having a light-receiving function may have a function of detecting both visible light and infrared light. The wavelength of light detected by the light-receiving device can be determined depending on the application of a sensor.

Alternatively, for example, the pixel includes a plurality of subpixels each including a light-emitting device and one subpixel including a light-emitting and light-receiving device.

The display apparatus including the light-emitting and light-receiving device has no need to change the pixel arrangement when incorporating a light-receiving function into pixels; thus, a display portion can be provided with one or both of an image capturing function and a sensing function without reductions in aperture ratio and resolution.

Note that the light-emitting and light-receiving device may be provided in all the pixels or may be provided in some of the pixels. In addition, one pixel may include a plurality of light-emitting and light-receiving devices.

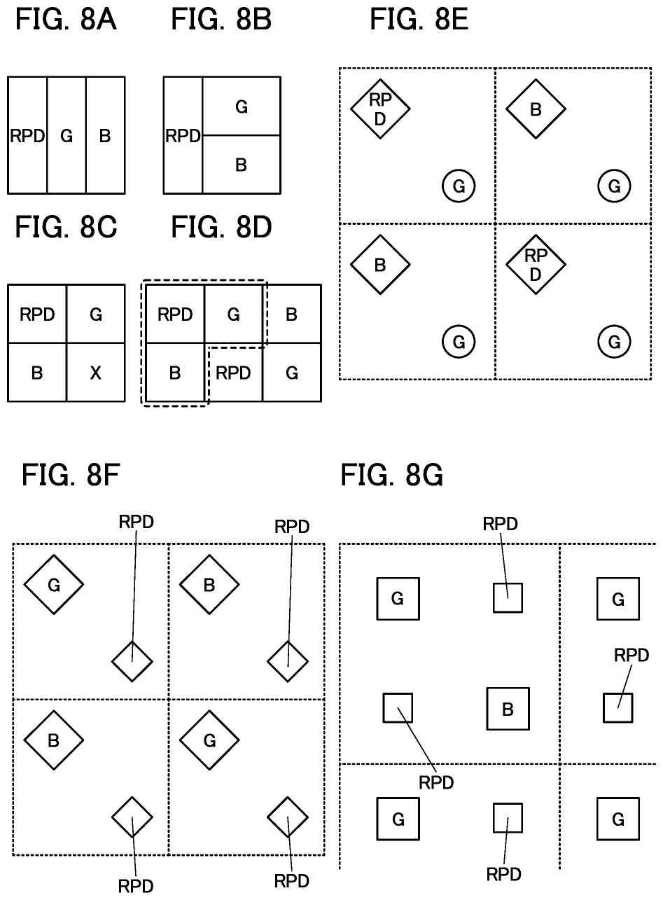

FIG. 8A to FIG. 8D illustrate examples of a pixel which includes a plurality of subpixels each including a light-emitting device and includes one subpixel including a light-emitting and light-receiving device.

A pixel illustrated in FIG. 8A employs stripe arrangement and includes a subpixel (RPD) that exhibits red light and has a light-receiving function, a subpixel (G) that exhibits green light, and a subpixel (B) that exhibits blue light. In a display apparatus including a pixel composed of three subpixels of R, G, and B, a light-emitting device used in the R subpixel can be replaced with a light-emitting and light-receiving device, so that the display apparatus can have a light-receiving function in the pixel.

A pixel illustrated in FIG. 8B includes a subpixel (RPD) that exhibits red light and has a light-receiving function, a subpixel (G) that exhibits green light, and a subpixel (B) that exhibits blue light. The subpixel (RPD) is provided in a column different from a column where the subpixel (G) and the subpixel (B) are positioned. The subpixel (G) and the subpixel (B) are alternately arranged in the same column; one is provided in an odd-numbered row and the other is provided in an even-numbered row. The color of the subpixel positioned in a column different from the column where the subpixels of the other colors are positioned is not limited to red (R) and may be green (G) or blue (B).

A pixel illustrated in FIG. 8C employs matrix arrangement and includes a subpixel (RPD) that exhibits red light and has a light-receiving function, a subpixel (G) that exhibits green light, a subpixel (B) that exhibits blue light, and a subpixel (X) that exhibits light of a color other than R, G, and B. Also in a display apparatus including a pixel composed of four subpixels of R, G, B, and X, a light-emitting device used in the R subpixel can be replaced with a light-emitting and light-receiving device, so that the display apparatus can have a light-receiving function in the pixel.

FIG. 8D illustrates two pixels, each of which is composed of three subpixels surrounded by dotted lines. The pixels illustrated in FIG. 8D each include a subpixel (RPD) that exhibits red light and has a light-receiving function, a subpixel (G) that exhibits green light, and a subpixel (B) that exhibits blue light. In the pixel on the left in FIG. 8D, the subpixel (G) is positioned in the same row as the subpixel (RPD), and the subpixel (B) is positioned in the same column as the subpixel (RPD). In the pixel on the right in FIG. 8D, the subpixel (G) is positioned in the same row as the subpixel (RPD), and the subpixel (B) is positioned in the same column as the subpixel (G). In every odd-numbered row and every even-numbered row of the pixel layout illustrated in FIG. 8D, the subpixel (RPD), the subpixel (G), and the subpixel (B) are repeatedly arranged. In addition, subpixels of different colors are arranged in the odd-numbered row and the even-numbered row in every column.

FIG. 8E illustrates four pixels which employ pentile arrangement; adjacent two pixels each have a different combination of two subpixels that exhibit light of different colors. Note that the shapes of the subpixels illustrated in FIG. 8E each indicate a top-surface shape of the light-emitting device or the light-emitting and light-receiving device included in the subpixel. FIG. 8F is a modification example of the pixel arrangement of FIG. 8E.

The upper-left pixel and the lower-right pixel in FIG. 8E each include a subpixel (RPD) that exhibits red light and has a light-receiving function and a subpixel (G) that exhibits green light. The lower-left pixel and the upper-right pixel in FIG. 8E each include a subpixel (G) that exhibits green light and a subpixel (B) that exhibits blue light.

The upper-left pixel and the lower-right pixel in FIG. 8F each include a subpixel (RPD) that exhibits red light and has a light-receiving function and a subpixel (G) that exhibits green light. The lower-left pixel and the upper-right pixel in FIG. 8F each include a subpixel (RPD) that exhibits red light and has a light-receiving function and a subpixel (B) that exhibits blue light.

In FIG. 8E, the subpixel (G) that exhibits green light is provided in each pixel. Meanwhile, in FIG. 8F, the subpixel (RPD) that exhibits red light and has a light-receiving function is provided in each pixel. The structure illustrated in FIG. 8F achieves higher-resolution image capturing than the structure illustrated in FIG. 8E because of having a subpixel having a light-receiving function in each pixel. Thus, the accuracy of biometric authentication can be increased, for example.

The top-surface shapes of the light-emitting devices and the light-emitting and light-receiving devices are not particularly limited and can be a circular shape, an elliptical shape, a polygonal shape, a polygonal shape with rounded corners, or the like. The top-surface shape of the light-emitting devices included in the subpixels (G) is a circular in the example in FIG. 8E and square in the example in FIG. 8F. The top-surface shape of the light-emitting devices and the light-emitting and light-receiving devices may vary depending on the color thereof, or the light-emitting devices and the light-emitting and light-receiving devices of some colors or every color may have the same top-surface shape.

The aperture ratio of subpixels may vary depending on the color of the subpixels, or may be the same among the subpixels of some colors or every color. For example, the aperture ratio of a subpixel of a color provided in each pixel (the subpixel (G) in FIG. 8E, and the subpixel (RPD) in FIG. 8F) may be made lower than those of subpixels of the other colors.

FIG. 8G is a modification example of the pixel arrangement of FIG. 8F. Specifically, the structure of FIG. 8G is obtained by rotating the structure of FIG. 8F by 45°. Although one pixel is regarded as being formed of two subpixels in FIG. 8F, one pixel can be regarded as being formed of four subpixels as illustrated in FIG. 8G.

In the description with reference to FIG. 8G, one pixel is regarded as being formed of four subpixels surrounded by dotted lines. A pixel includes two subpixels (RPD), one subpixel (G), and one subpixel (B). The pixel including a plurality of subpixels each having a light-receiving function allows high-resolution image capturing. Accordingly, the accuracy of biometric authentication can be increased. For example, the resolution of image capturing can be the square root of 2 times the resolution of display.

A display apparatus which employs the structure illustrated in FIG. 8F or FIG. 8G includes p (p is an integer greater than or equal to 2) first light-emitting devices, q (q is an integer greater than or equal to 2) second light-emitting devices, and r (r is an integer greater than p and q) light-emitting and light-receiving devices. As for p and r, r=2p is satisfied. As for p, q, and r, r=p+q is satisfied. Either the first light-emitting devices or the second light-emitting devices emit green light, and the other light-emitting devices emit blue light. The light-emitting and light-receiving devices emit red light and have a light-receiving function.

In the case where touch operation is detected with the light-emitting and light-receiving devices, for example, it is preferable that light emitted from a light source be hard for a user to recognize. Since blue light has lower visibility than green light, light-emitting devices that emit blue light are preferably used as a light source. Accordingly, the light-emitting and light-receiving devices preferably have a function of receiving blue light.

As described above, the display apparatus of this embodiment can employ any of various types of pixel arrangements.

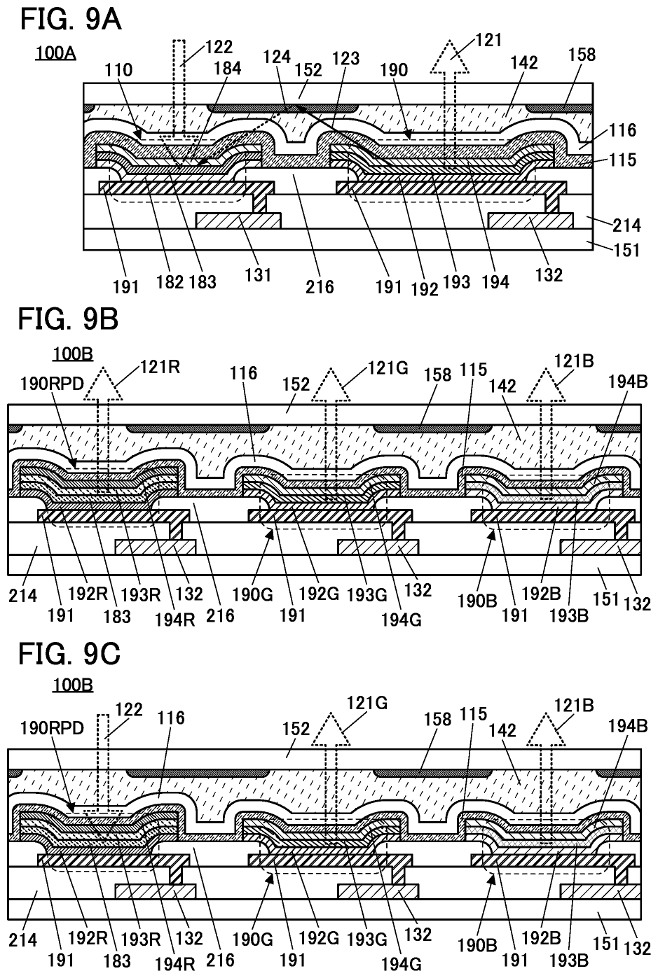

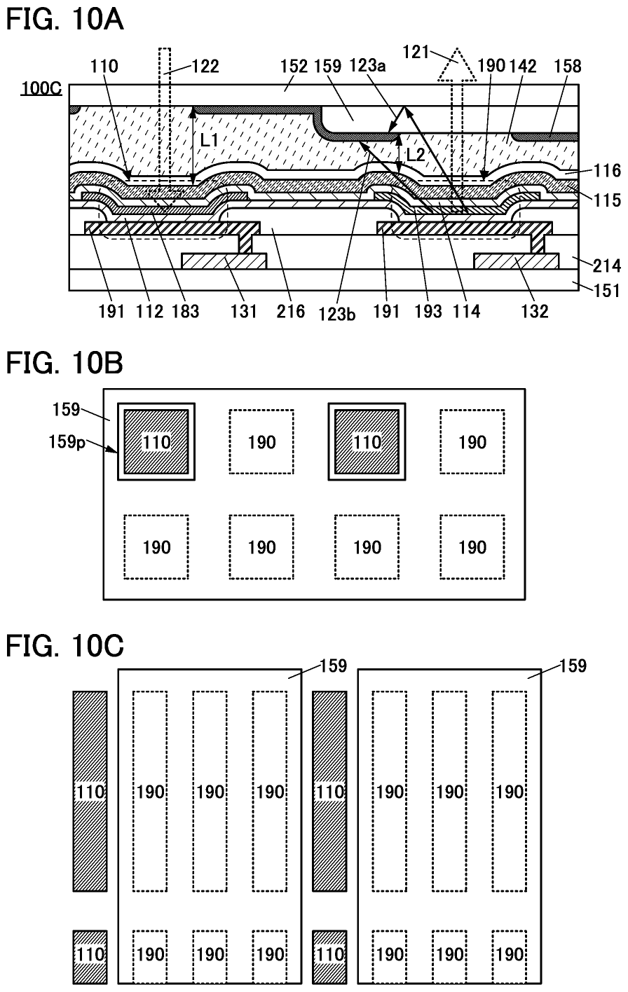

A detailed structure of the display apparatus of one embodiment of the present invention will be described with reference to FIG. 9 and FIG. 10.

### <Structure Example 2 of Display Apparatus >

### [Structure Example 2-1 of Display Apparatus]

FIG. 9A illustrates a structure example of the display apparatus of one embodiment of the present invention. FIG. 9A is a cross-sectional view of a display apparatus 100A.

The display apparatus 100A includes a light-receiving device 110 and a light-emitting device 190.

The light-emitting device 190 includes a pixel electrode 191, a buffer layer 192, a light-emitting layer 193, a buffer layer 194, and a common electrode 115 which are stacked in this order. The buffer layer 192 can include one or both of a hole-injection layer and a hole-transport layer. The light-emitting layer 193 contains an organic compound. The buffer layer 194 can include one or both of an electron-injection layer and an electron-transport layer. The light-emitting device 190 has a function of emitting visible light 121. Note that the display apparatus 100A may also include a light-emitting device having a function of emitting infrared light.

The light-receiving device 110 includes the pixel electrode 191, a buffer layer 182, an active layer 183, a buffer layer 184, and the common electrode 115 which are stacked in this order. The buffer layer 182 can include a hole-transport layer. The active layer 183 contains an organic compound. The buffer layer 184 can include an electron-transport layer. The light-receiving device 110 has a function of detecting visible light. Note that the light-receiving device 110 may also have a function of detecting infrared light.

This embodiment is described assuming that the pixel electrode 191 functions as an anode and the common electrode 115 functions as a cathode in both of the light-emitting device 190 and the light-receiving device 110. In other words, the light-receiving device 110 is driven by application of reverse bias between the pixel electrode 191 and the common electrode 115, so that light entering the light-receiving device 110 can be detected and electric charge can be generated and extracted as current in the display apparatus 100A.

The pixel electrode 191, the buffer layer 182, the buffer layer 192, the active layer 183, the light-emitting layer 193, the buffer layer 184, the buffer layer 194, and the common electrode 115 may each have a single-layer structure or a stacked-layer structure.

The pixel electrodes 191 are positioned over an insulating layer 214. The pixel electrodes 191 can be formed using the same material in the same step. End portions of the pixel electrodes 191 are covered with a partition 216. The two pixel electrodes 191 adjacent to each other are electrically insulated (electrically isolated) from each other by the partition 216.

An organic insulating film is suitable for the partition 216. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The partition 216 is a layer that transmits visible light. A partition that blocks visible light may be provided instead of the partition 216.

The common electrode 115 is a layer shared by the light-receiving device 110 and the light-emitting device 190.

The material, thickness, and the like of the pair of electrodes can be the same between the light-receiving device 110 and the light-emitting device 190. Accordingly, the manufacturing cost of the display apparatus can be reduced and the manufacturing process of the display apparatus can be simplified.

The display apparatus 100A includes the light-receiving device 110, the light-emitting device 190, a transistor 131, a transistor 132, and the like between a pair of substrates (a substrate 151 and a substrate 152).

In the light-receiving device 110, the buffer layer 182, the active layer 183, and the buffer layer 184, which are positioned between the pixel electrode 191 and the common electrode 115, can each be referred to as an organic layer (a layer containing an organic compound). The pixel electrode 191 preferably has a function of reflecting visible light. The common electrode 115 has a function of transmitting visible light. Note that in the case where the light-receiving device 110 is configured to detect infrared light, the common electrode 115 has a function of transmitting infrared light. Furthermore, the pixel electrode 191 preferably has a function of reflecting infrared light.

The light-receiving device 110 has a function of detecting light. Specifically, the light-receiving device 110 is a photoelectric conversion device that receives light 122 entering from the outside of the display apparatus 100A and converts it into an electric signal. The light 122 can also be expressed as light that is emitted from the light-emitting device 190 and then reflected by an object. The light 122 may enter the light-receiving device 110 through a lens or the like provided in the display apparatus 100A.

In the light-emitting device 190, the buffer layer 192, the light-emitting layer 193, and the buffer layer 194, which are positioned between the pixel electrode 191 and the common electrode 115, can be collectively referred to as an EL layer. The EL layer includes at least the light-emitting layer 193. As described above, the pixel electrode 191 preferably has a function of reflecting visible light. The common electrode 115 has a function of transmitting visible light. Note that in the case where the display apparatus 100A includes a light-emitting device that emits infrared light, the common electrode 115 has a function of transmitting infrared light. Furthermore, the pixel electrode 191 preferably has a function of reflecting infrared light.

The light-emitting device included in the display apparatus of this embodiment preferably employs a micro optical resonator (microcavity) structure.

The buffer layer 192 or the buffer layer 194 may have a function as an optical adjustment layer. By changing the thickness of the buffer layer 192 or the buffer layer 194, light of a particular color can be intensified and taken out from each light-emitting device.

The light-emitting device 190 has a function of emitting visible light. Specifically, the light-emitting device 190 is an electroluminescent device that emits light to the substrate 152 side by applying voltage between the pixel electrode 191 and the common electrode 115 (see the visible light 121).

The pixel electrode 191 included in the light-receiving device 110 is electrically connected to a source or a drain of the transistor 131 through an opening provided in the insulating layer 214.

The pixel electrode 191 included in the light-emitting device 190 is electrically connected to a source or a drain of the transistor 132 through an opening provided in the insulating layer 214.

The transistor 131 and the transistor 132 are on and in contact with the same layer (the substrate 151 in FIG. 9A).

At least part of a circuit electrically connected to the light-receiving device 110 and a circuit electrically connected to the light-emitting device 190 are preferably formed using the same material in the same step. In that case, the thickness of the display apparatus can be reduced compared with the case where the two circuits are separately formed, resulting in simplification of the manufacturing steps.

The light-receiving device 110 and the light-emitting device 190 are preferably covered with a protective layer 116. In FIG. 9A, the protective layer 116 is provided on and in contact with the common electrode 115. Providing the protective layer 116 can inhibit entry of impurities such as water into the light-receiving device 110 and the light-emitting device 190, so that the reliability of the light-receiving device 110 and the light-emitting device 190 can be increased. The protective layer 116 and the substrate 152 are bonded to each other with an adhesive layer 142.

A light shielding layer 158 is provided on a surface of the substrate 152 on the substrate 151 side. The light shielding layer 158 has openings in a position overlapping with the light-emitting device 190 and in a position overlapping with the light-receiving device 110.

Here, the light-receiving device 110 detects light that is emitted from the light-emitting device 190 and then reflected by an object. However, in some cases, light emitted from the light-emitting device 190 is reflected inside the display apparatus 100A and enters the light-receiving device 110 without through an object. The light shielding layer 158 can reduce the influence of such stray light. For example, in the case where the light shielding layer 158 is not provided, light 123 emitted from the light-emitting device 190 is reflected by the substrate 152 and reflected light 124 enters the light-receiving device 110 in some cases. Providing the light shielding layer 158 can inhibit entry of the reflected light 124 into the light-receiving device 110. Consequently, noise can be reduced, and the sensitivity of a sensor using the light-receiving device 110 can be increased.

For the light shielding layer 158, a material that blocks light emitted from the light-emitting device can be used. The light shielding layer 158 preferably absorbs visible light. As the light shielding layer 158, a black matrix can be formed using a metal material or a resin material containing pigment (e.g., carbon black) or dye, for example. The light shielding layer 158 may have a stacked-layer structure of a red color filter, a green color filter, and a blue color filter.

### [Structure Example 2-2 of Display Apparatus]

FIG. 9B and FIG. 9C illustrate cross-sectional views of a display apparatus 100B. Note that in the description of the display apparatus below, components similar to those of the above-mentioned display apparatus are not described in some cases.

The display apparatus 100B includes a light-emitting device 190B, a light-emitting device 190G, and a light-emitting and light-receiving device 190RPD.

The light-emitting device 190B includes the pixel electrode 191, a buffer layer 192B, a light-emitting layer 193B, a buffer layer 194B, and the common electrode 115 which are stacked in this order. The light-emitting device 190B has a function of emitting blue light 121B.

The light-emitting device 190G includes the pixel electrode 191, a buffer layer 192G, a light-emitting layer 193G, a buffer layer 194G, and the common electrode 115 which are stacked in this order. The light-emitting device 190G has a function of emitting green light 121G.

The light-emitting and light-receiving device 190RPD includes the pixel electrode 191, a buffer layer 192R, the active layer 183, a light-emitting layer 193R, a buffer layer 194R, and the common electrode 115 which are stacked in this order. The light-emitting and light-receiving device 190RPD has a function of emitting red light 121R and a function of detecting the light 122.

FIG. 9B illustrates a case where the light-emitting and light-receiving device 190RPD functions as a light-emitting device. FIG. 9B illustrates an example in which the light-emitting device 190B emits blue light, the light-emitting device 190G emits green light, and the light-emitting and light-receiving device 190RPD emits red light.

FIG. 9C illustrates a case where the light-emitting and light-receiving device 190RPD functions as a light-receiving device. FIG. 9C illustrates an example in which the light-emitting and light-receiving device 190RPD detects blue light emitted from the light-emitting device 190B and green light emitted from the light-emitting device 190G.

The display apparatus 100B includes the light-emitting and light-receiving device 190RPD, the light-emitting device 190G, the light-emitting device 190B, the transistor 132, and the like between the pair of substrates (the substrate 151 and the substrate 152).

The pixel electrode 191 is positioned over the insulating layer 214. The two pixel electrodes 191 adjacent to each other are electrically insulated from each other by the partition 216. The pixel electrode 191 is electrically connected to the source or the drain of the transistor 132 through the opening provided in the insulating layer 214.

The light-emitting and light-receiving device and the light-emitting devices are preferably covered with the protective layer 116. The protective layer 116 and the substrate 152 are bonded to each other with the adhesive layer 142. The light shielding layer 158 is provided on the surface of the substrate 152 on the substrate 151 side.

### [Structure Example 2-3 of Display Apparatus]

FIG. 10A illustrates a cross-sectional view of a display apparatus 100C.

The display apparatus 100C includes the light-receiving device 110 and the light-emitting device 190.

The light-emitting device 190 includes the pixel electrode 191, a common layer 112, the light-emitting layer 193, a common layer 114, and the common electrode 115 in this order. The common layer 112 can include one or both of a hole-injection layer and a hole-transport layer. The light-emitting layer 193 contains an organic compound. The common layer 114 can include one or both of an electron-injection layer and an electron-transport layer. The light-emitting device 190 has a function of emitting visible light. Note that the display apparatus 100C may also include a light-emitting device having a function of emitting infrared light.

The light-receiving device 110 includes the pixel electrode 191, the common layer 112, the active layer 183, the common layer 114, and the common electrode 115 which are stacked in this order. The active layer 183 contains an organic compound. The light-receiving device 110 has a function of detecting visible light. Note that the light-receiving device 110 may also have a function of detecting infrared light.

The pixel electrode 191, the common layer 112, the active layer 183, the light-emitting layer 193, the common layer 114, and the common electrode 115 may each have a single-layer structure or a stacked-layer structure.

The pixel electrode 191 is positioned over the insulating layer 214. The two pixel electrodes 191 adjacent to each other are electrically insulated from each other by the partition 216. The pixel electrode 191 is electrically connected to the source or the drain of the transistor 132 through the opening provided in the insulating layer 214.

The common layer 112, the common layer 114, and the common electrode 115 are layers shared by the light-receiving device 110 and the light-emitting device 190. At least some of the layers constituting the light-receiving device 110 and the light-emitting device 190 are preferably shared, so that the number of manufacturing steps of the display apparatus can be reduced.

The display apparatus 100C includes the light-receiving device 110, the light-emitting device 190, the transistor 131, the transistor 132, and the like between the pair of substrates (the substrate 151 and the substrate 152).

The light-receiving device 110 and the light-emitting device 190 are preferably covered with the protective layer 116. The protective layer 116 and the substrate 152 are bonded to each other with the adhesive layer 142.

A resin layer 159 is provided on the surface of the substrate 152 on the substrate 151 side. The resin layer 159 is provided in a position overlapping with the light-emitting device 190 and is not provided in a position overlapping with the light-receiving device 110.

The resin layer 159 can be provided in the position overlapping with the light-emitting device 190 and have an opening 159p in the position overlapping with the light-receiving device 110, as illustrated in FIG. 10B, for example. Alternatively, as illustrated in FIG. 10C, the resin layer 159 can be provided to have an island shape in a position overlapping with the light-emitting device 190 but not in a position overlapping with the light-receiving device 110.

The light shielding layer 158 is provided on the surface of the substrate 152 on the substrate 151 side and on a surface of the resin layer 159 on the substrate 151 side. The light shielding layer 158 has openings in a position overlapping with the light-emitting device 190 and in a position overlapping with the light-receiving device 110.

Here, the light-receiving device 110 detects light that is emitted from the light-emitting device 190 and then reflected by an object. However, in some cases, light emitted from the light-emitting device 190 is reflected inside the display apparatus 100C and enters the light-receiving device 110 without through an object. The light shielding layer 158 can absorb such stray light and thereby reduce entry of stray light into the light-receiving device 110. For example, the light shielding layer 158 can absorb stray light 123a that has passed through the resin layer 159 and has been reflected by the surface of the substrate 152 on the substrate 151 side. Moreover, the light shielding layer 158 can absorb stray light 123b before the stray light 123b reaches the resin layer 159. This can inhibit stray light from entering the light-receiving device 110. Consequently, noise can be reduced, and the sensitivity of a sensor using the light-receiving device 110 can be increased. It is particularly preferable that the light shielding layer 158 be positioned close to the light-emitting device 190, in which case stray light can be further reduced. This is preferable also in terms of improving display quality, because the light shielding layer 158 positioned close to the light-emitting device 190 can inhibit viewing angle dependence of display.

Providing the light shielding layer 158 can control the range where the light-receiving device 110 detects light. When the light shielding layer 158 is positioned apart from the light-receiving device 110, the image-capturing range is narrowed, and the image-capturing resolution can be increased.

In the case where the resin layer 159 has an opening, the light shielding layer 158 preferably covers at least part of the opening and at least part of the side surface of the resin layer 159 exposed in the opening.

In the case where the resin layer 159 is provided in an island shape, the light shielding layer 158 preferably covers at least part of the side surface of the resin layer 159.

Since the light shielding layer 158 is provided along the shape of the resin layer 159 in such a manner, the distance from the light shielding layer 158 to the light-emitting device 190 (specifically, the light-emitting region of the light-emitting device 190) is shorter than the distance from the light shielding layer 158 to the light-receiving device 110 (specifically, the light-receiving region of the light-receiving device 110). Accordingly, noise of the sensor can be reduced, the image-capturing resolution can be increased, and viewing angle dependence of display can be inhibited. Thus, both the display quality and the imaging quality of the display apparatus can be increased.

The resin layer 159 is a layer that transmits light emitted from the light-emitting device 190. Examples of materials for the resin layer 159 include an acrylic resin, a polyimide resin, an epoxy resin, a polyamide resin, a polyimide-amide resin, a siloxane resin, a benzocyclobutene-based resin, a phenol resin, and precursors of these resins. Note that a component provided between the substrate 152 and the light shielding layer 158 is not limited to the resin layer and may be an inorganic insulating film or the like. As the component becomes thicker, a larger difference occurs between the distance from the light shielding layer to the light-receiving device and the distance from the light shielding layer to the light-emitting device. An organic insulating film made of a resin or the like is suitable for the component because it is easily formed to have a large thickness.

In order to compare the distance from the light shielding layer 158 to the light-receiving device 110 and the distance from the light shielding layer 158 to the light-emitting device 190, it is possible to use, for example, the shortest distance L1 from an end portion of the light shielding layer 158 on the light-receiving device 110 side to the common electrode 115 and the shortest distance L2 from an end portion of the light shielding layer 158 on the light-emitting device 190 side to the common electrode 115. With the shortest distance L2 smaller than the shortest distance L1, stray light from the light-emitting device 190 can be inhibited, and the sensitivity of the sensor using the light-receiving device 110 can be increased. Furthermore, viewing angle dependence of display can be inhibited. With the shortest distance L1 larger than the shortest distance L2, the image-capturing range of the light-receiving device 110 can be narrowed, and the image-capturing resolution can be increased.

When the adhesive layer 142 is provided such that a portion overlapping with the light-receiving device 110 is made thicker than a portion overlapping with the light-emitting device 190, a difference also can be made between the distance from the light shielding layer 158 to the light-receiving device 110 and the distance from the light shielding layer 158 to the light-emitting device 190.

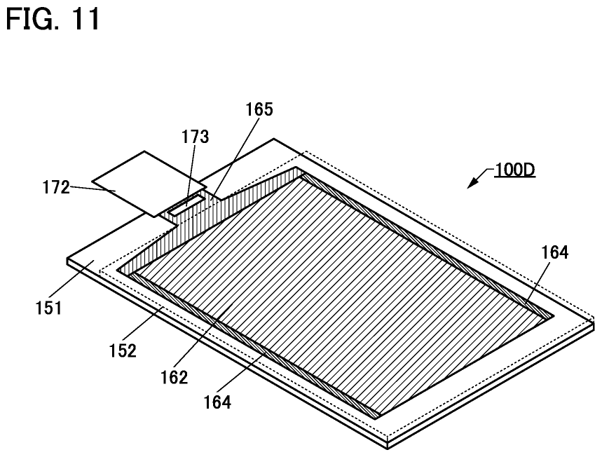

A more detailed structure of the display apparatus of one embodiment of the present invention is described below with reference to FIG. 11 to FIG. 14.

### [Structure Example 2-4 of Display Apparatus]

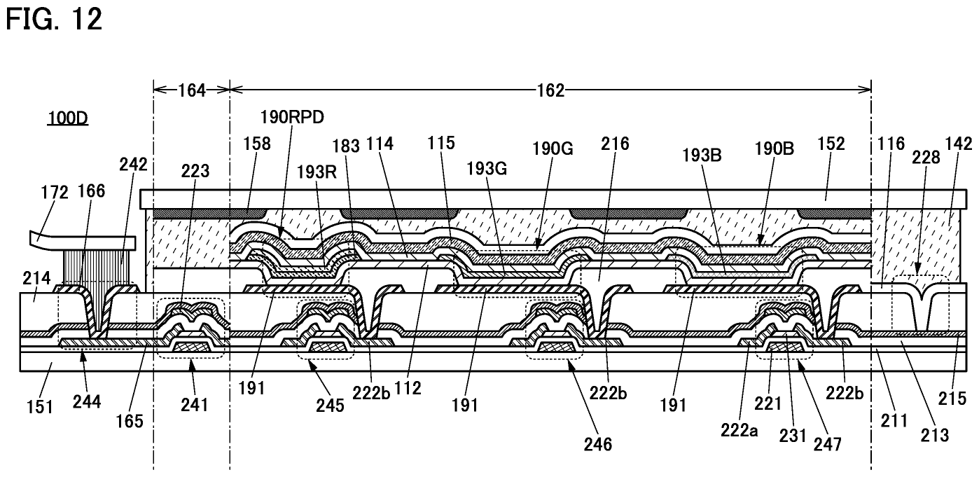

FIG. 11 illustrates a perspective view of a display apparatus 100D, and FIG. 12 illustrates a cross-sectional view of the display apparatus 100D.

The display apparatus 100D has a structure in which the substrate 152 and the substrate 151 are bonded to each other. In FIG. 11, the substrate 152 is denoted by a dashed line.

The display apparatus 100D includes a display portion 162, a circuit 164, a wiring 165, and the like. FIG. 11 illustrates an example in which an IC (integrated circuit) 173 and an FPC 172 are integrated on the display apparatus 100D. Thus, the structure illustrated in FIG. 11 can be regarded as a display module including the display apparatus 100D, the IC, and the FPC.

As the circuit 164, for example, a scan line driver circuit can be used.

The wiring 165 has a function of supplying a signal and power to the display portion 162 and the circuit 164. The signal and power are input to the wiring 165 from the outside through the FPC 172 or from the IC 173.

FIG. 11 illustrates an example in which the IC 173 is provided over the substrate 151 by a COG (Chip On Glass) method, a COF (Chip on Film) method, or the like. An IC including a scan line driver circuit, a signal line driver circuit, or the like can be used as the IC 173, for example. Note that the display apparatus 100D and the display module may have a structure that is not provided with an IC. The IC may be provided over the FPC by a COF method or the like.

FIG. 12 illustrates an example of cross sections of part of a region including the FPC 172, part of a region including the circuit 164, part of a region including the display portion 162, and part of a region including an end portion of the display apparatus 100D illustrated in FIG. 11.

The display apparatus 100D illustrated in FIG. 12 includes a transistor 241, a transistor 245, a transistor 246, a transistor 247, the light-emitting device 190B, the light-emitting device 190G, the light-emitting and light-receiving device 190RPD, and the like between the substrate 151 and the substrate 152.

The substrate 152 and the protective layer 116 are bonded to each other with the adhesive layer 142. A solid sealing structure, a hollow sealing structure, or the like can be employed to seal the light-emitting device 190B, the light-emitting device 190G, and the light-emitting and light-receiving device 190RPD. In FIG. 12, a space surrounded by the substrate 152, the adhesive layer 142, and the insulating layer 214 is sealed with the adhesive layer 142, and the solid sealing structure is employed.

The light-emitting device 190B has a stacked-layer structure in which the pixel electrode 191, the common layer 112, the light-emitting layer 193B, the common layer 114, and the common electrode 115 are stacked in this order from the insulating layer 214 side. The pixel electrode 191 is connected to a conductive layer 222b included in the transistor 247 through an opening provided in the insulating layer 214. The transistor 247 has a function of controlling the driving of the light-emitting device 190B. The end portion of the pixel electrode 191 is covered with the partition 216. The pixel electrode 191 contains a material that reflects visible light, and the common electrode 115 contains a material that transmits visible light.

The light-emitting device 190G has a stacked-layer structure in which the pixel electrode 191, the common layer 112, the light-emitting layer 193G, the common layer 114, and the common electrode 115 are stacked in this order from the insulating layer 214 side. The pixel electrode 191 is connected to the conductive layer 222b included in the transistor 246 through an opening provided in the insulating layer 214. The transistor 246 has a function of controlling the driving of the light-emitting device 190G.

The light-emitting and light-receiving device 190RPD has a stacked-layer structure in which the pixel electrode 191, the common layer 112, the active layer 183, the light-emitting layer 193R, the common layer 114, and the common electrode 115 are stacked in this order from the insulating layer 214 side. The pixel electrode 191 is electrically connected to the conductive layer 222b included in the transistor 245 through an opening provided in the insulating layer 214. The transistor 245 has a function of controlling the driving of the light-emitting and light-receiving device 190RPD.

Light emitted from the light-emitting device 190B, the light-emitting device 190G, and the light-emitting and light-receiving device 190RPD is emitted toward the substrate 152 side. Light enters the light-emitting and light-receiving device 190RPD through the substrate 152 and the adhesive layer 142. For the substrate 152 and the adhesive layer 142, a material having a high visible-light-transmitting property is preferably used.

The pixel electrodes 191 included in the light-emitting device 190B, the light-emitting device 190G, and the light-emitting and light-receiving device 190RPD can be formed using the same material in the same step. The common layer 112, the common layer 114, and the common electrode 115 are used in common in the light-emitting device 190B, the light-emitting device 190G, and the light-emitting and light-receiving device 190RPD. The light-emitting and light-receiving device 190RPD has the structure of the red-light-emitting device to which the active layer 183 is added. The light-emitting device 190B, the light-emitting device 190G, and the light-emitting and light-receiving device 190RPD can have a common structure except for the active layer 183 and the light-emitting layer 193 of each color. Thus, the display portion 162 of the display apparatus 100D can have a light-receiving function without a significant increase in the number of manufacturing steps.

The light shielding layer 158 is provided on the surface of the substrate 152 on the substrate 151 side. The light shielding layer 158 includes openings in positions overlapping with the light-emitting device 190B, the light-emitting device 190G, and the light-emitting and light-receiving device 190RPD. Providing the light shielding layer 158 can control the range where the light-emitting and light-receiving device 190RPD detects light. As described above, it is preferable to control light entering the light-emitting and light-receiving device by adjusting the position of the opening of the light shielding layer provided in a position overlapping with the light-emitting and light-receiving device 190RPD. Furthermore, with the light shielding layer 158, light can be inhibited from directly entering the light-emitting and light-receiving device 190RPD from the light-emitting device 190 without through an object. Hence, a sensor with less noise and high sensitivity can be obtained.

The transistor 241, the transistor 245, the transistor 246, and the transistor 247 are formed over the substrate 151. These transistors can be formed using the same materials in the same steps.

An insulating layer 211, an insulating layer 213, an insulating layer 215, and the insulating layer 214 are provided in this order over the substrate 151. Parts of the insulating layer 211 function as gate insulating layers of the transistors. Parts of the insulating layer 213 function as gate insulating layers of the transistors. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may have either a single layer or two or more layers.

A material into which impurities such as water and hydrogen do not easily diffuse is preferably used for at least one of the insulating layers that cover the transistors. This allows the insulating layer to serve as a barrier layer. Such a structure can effectively inhibit diffusion of impurities into the transistors from the outside and increase the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, a hafnium oxynitride film, a hafnium nitride oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used. Note that a base film may be provided between the substrate 151 and the transistors. Any of the above-described inorganic insulating films can be used as the base film.

Here, an organic insulating film often has a lower barrier property than an inorganic insulating film. Therefore, the organic insulating film preferably has an opening in the vicinity of the end portion of the display apparatus 100D. This can inhibit entry of impurities from the end portion of the display apparatus 100D through the organic insulating film. Alternatively, the organic insulating film may be formed such that an end portion of the organic insulating film is positioned on the inner side compared to the end portion of the display apparatus 100D, to prevent the organic insulating film from being exposed at the end portion of the display apparatus 100D.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

By provision of the protective layer 116 that covers the light-emitting device 190B, the light-emitting device 190G, and the light-emitting and light-receiving device 190RPD, impurities such as water can be inhibited from entering the light-emitting device 190B, the light-emitting device 190G, and the light-emitting and light-receiving device 190RPD, leading to an increase in the reliability of the light-emitting device 190B, the light-emitting device 190G, and the light-emitting and light-receiving device 190RPD.

In a region 228 illustrated in FIG. 12, an opening is formed in the insulating layer 214. This can inhibit entry of impurities into the display portion 162 from the outside through the insulating layer 214 even when an organic insulating film is used as the insulating layer 214. Thus, the reliability of the display apparatus 100D can be increased.

In the region 228 in the vicinity of the end portion of the display apparatus 100D, the insulating layer 215 and the protective layer 116 are preferably in contact with each other through the opening in the insulating layer 214. In particular, the inorganic insulating film included in the insulating layer 215 and the inorganic insulating film included in the protective layer 116 are preferably in contact with each other. Thus, entry of impurities from the outside into the display portion 162 through the organic insulating film can be inhibited. Thus, the reliability of the display apparatus 100D can be increased.

The protective layer 116 may have a single-layer structure or a stacked-layer structure. For example, the protective layer 116 may have a stacked-layer structure of an organic insulating film and an inorganic insulating film. In that case, an end portion of the inorganic insulating film preferably extends beyond an end portion of the organic insulating film.

Each of the transistor 241, the transistor 245, the transistor 246, and the transistor 247 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are illustrated with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. A top-gate or a bottom-gate transistor structure may be employed. Alternatively, gates may be provided above and below a semiconductor layer in which a channel is formed.

The structure in which the semiconductor layer where a channel is formed is provided between two gates is used for the transistor 241, the transistor 245, the transistor 246, and the transistor 247. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used in the transistor, and any of an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

A semiconductor layer of a transistor preferably includes a metal oxide (also referred to as an oxide semiconductor). Alternatively, the semiconductor layer of the transistor may include silicon. Examples of silicon include amorphous silicon and crystalline silicon (e.g., low-temperature polysilicon or single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

When the semiconductor layer is an In-M-Zn oxide, the atomic ratio of In is preferably greater than or equal to the atomic ratio of Min the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistor included in the circuit 164 and the transistor included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures.

A connection portion 244 is provided in a region of the substrate 151 that does not overlap with the substrate 152. In the connection portion 244, the wiring 165 is electrically connected to the FPC 172 via a conductive layer 166 and a connection layer 242. On the top surface of the connection portion 244, the conductive layer 166 obtained by processing the same conductive film as the pixel electrode 191 is exposed. Thus, the connection portion 244 and the FPC 172 can be electrically connected to each other through the connection layer 242.

A variety of optical members can be arranged on an outer surface of the substrate 152. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film suppressing the attachment of stain, a hard coat film inhibiting generation of a scratch caused by the use, a shock absorbing layer, or the like may be provided on the outer surface of the substrate 152.

For each of the substrate 151 and the substrate 152, glass, quartz, ceramic, sapphire, resin, or the like can be used. When a flexible material is used for the substrate 151 and the substrate 152, the flexibility of the display apparatus can be increased.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. An adhesive sheet or the like may be used.

As the connection layer, an anisotropic conductive film (ACF), an anisotropic conductive paste (ACP), or the like can be used.

For the structures, materials, and the like of the light-emitting devices 190G and 190B and the light-emitting and light-receiving device 190RPD, the above description can be referred to.

As materials that can be used for a gate, a source, and a drain of a transistor and conductive layers such as a variety of wirings and electrodes included in a display apparatus, metals such as aluminum, titanium, chromium, nickel, copper, yttrium, zirconium, molybdenum, silver, tantalum, and tungsten, an alloy containing any of these metals as its main component, and the like can be given. A film containing any of these materials can be used in a single layer or as a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to be able to transmit light. A stacked-layer film of any of the above materials can be used as a conductive layer. For example, a stacked-layer film of indium tin oxide and an alloy of silver and magnesium, or the like is preferably used for increased conductivity. These materials can also be used for conductive layers such as a variety of wirings and electrodes that constitute a display apparatus, and conductive layers (conductive layers functioning as a pixel electrode or a common electrode) included in a light-emitting device and a light-receiving device (or a light-emitting and light-receiving device).

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### [Structure Example 2-5 of Display Apparatus]

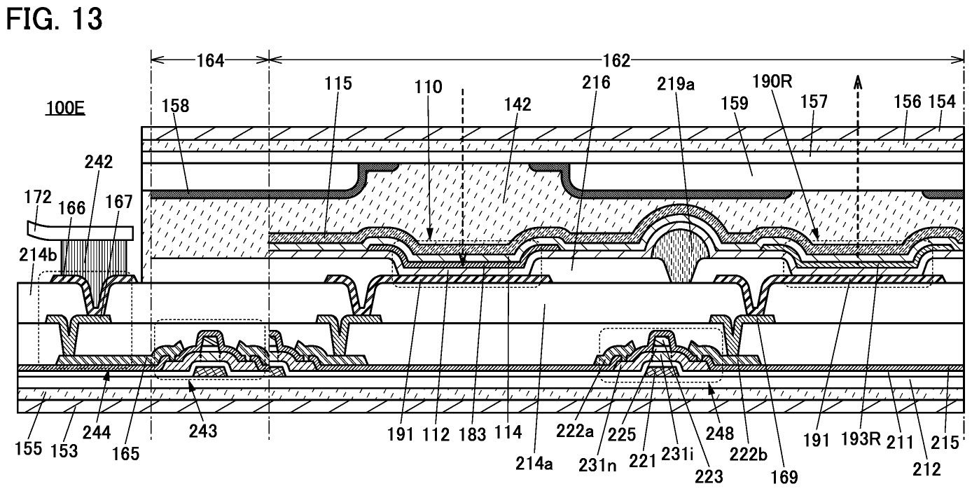

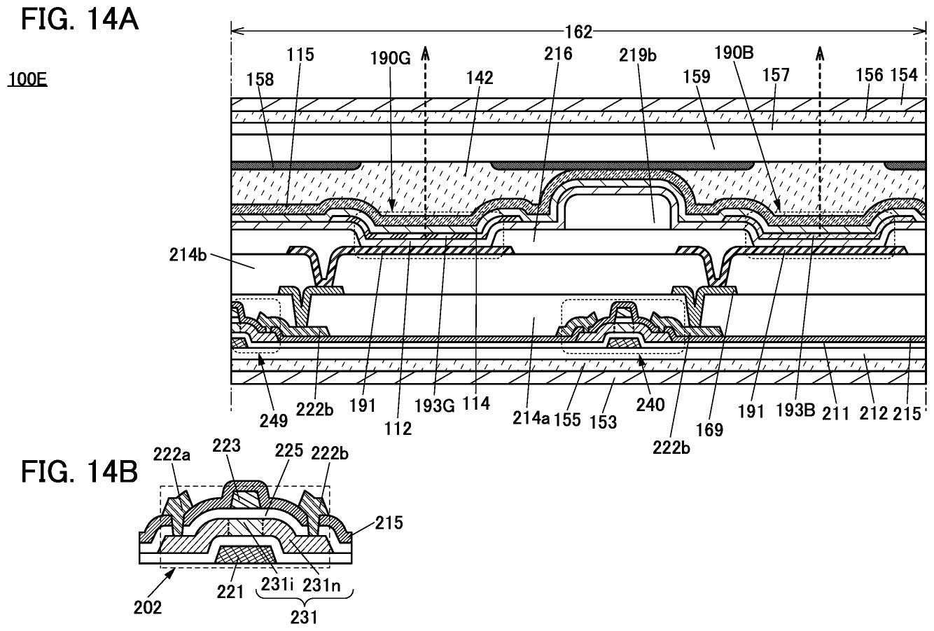

FIG. 13 and FIG. 14A illustrate cross-sectional views of a display apparatus 100E. A perspective view of the display apparatus 100E is similar to that of the display apparatus 100D (FIG. 6). FIG. 13 illustrates an example of cross sections of part of a region including the FPC 172, part of the circuit 164, and part of the display portion 162 in the display apparatus 100E. FIG. 14A illustrates an example of a cross section of part of the display portion 162 in the display apparatus 100E. FIG. 13 specifically illustrates an example of a cross section of a region including the light-receiving device 110 and the light-emitting device 190R that emits red light in the display portion 162. FIG. 14A specifically illustrates an example of a cross section of a region including the light-emitting device 190G that emits green light and the light-emitting device 190B that emits blue light in the display portion 162.

The display apparatus 100E illustrated in FIG. 13 and FIG. 14A includes a transistor 243, a transistor 248, a transistor 249, a transistor 240, the light-emitting device 190R, the light-emitting device 190G, the light-emitting device 190B, the light-receiving device 110, and the like between a substrate 153 and a substrate 154.

The resin layer 159 and the common electrode 115 are bonded to each other with the adhesive layer 142, and the display apparatus 100E employs a solid sealing structure.

The substrate 153 and the insulating layer 212 are bonded to each other with an adhesive layer 155. The substrate 154 and an insulating layer 157 are bonded to each other with an adhesive layer 156.

To fabricate the display apparatus 100E, first, a first formation substrate provided with the insulating layer 212, the transistors, the light-receiving device 110, the light-emitting devices, and the like and a second formation substrate provided with the insulating layer 157, the resin layer 159, the light shielding layer 158, and the like are bonded to each other with the adhesive layer 142. Then, the substrate 153 is bonded to a surface exposed by separation of the first formation substrate, and the substrate 154 is bonded to a surface exposed by separation of the second formation substrate, whereby the components formed over the first formation substrate and the second formation substrate are transferred to the substrate 153 and the substrate 154. The substrate 153 and the substrate 154 preferably have flexibility. Accordingly, the flexibility of the display apparatus 100E can be increased.

The inorganic insulating film that can be used as the insulating layer 211, the insulating layer 213, and the insulating layer 215 can be used as the insulating layer 212 and the insulating layer 157.

The light-emitting device 190R has a stacked-layer structure in which the pixel electrode 191, the common layer 112, the light-emitting layer 193R, the common layer 114, and the common electrode 115 are stacked in this order from an insulating layer 214b side. The pixel electrode 191 is connected to a conductive layer 169 through an opening provided in the insulating layer 214b. The conductive layer 169 is connected to the conductive layer 222b included in the transistor 248 through an opening provided in an insulating layer 214a. The conductive layer 222b is connected to a low-resistance region 231n through an opening provided in the insulating layer 215. That is, the pixel electrode 191 is electrically connected to the transistor 248. The transistor 248 has a function of controlling the driving of the light-emitting device 190R.

Similarly, the light-emitting device 190G has a stacked-layer structure in which the pixel electrode 191, the common layer 112, the light-emitting layer 193G, the common layer 114, and the common electrode 115 are stacked in this order from the insulating layer 214b side. The pixel electrode 191 is electrically connected to the low-resistance region 231n of the transistor 249 through the conductive layer 169 and the conductive layer 222b of the transistor 249. That is, the pixel electrode 191 is electrically connected to the transistor 249. The transistor 249 has a function of controlling the driving of the light-emitting device 190G.

In addition, the light-emitting device 190B has a stacked-layer structure in which the pixel electrode 191, the common layer 112, the light-emitting layer 193B, the common layer 114, and the common electrode 115 are stacked in this order from the insulating layer 214b side. The pixel electrode 191 is electrically connected to the low-resistance region 231n of the transistor 240 through the conductive layer 169 and the conductive layer 222b of the transistor 240. That is, the pixel electrode 191 is electrically connected to the transistor 240. The transistor 240 has a function of controlling the driving of the light-emitting device 190B.

The light-receiving device 110 has a stacked-layer structure in which the pixel electrode 191, the common layer 112, the active layer 183, the common layer 114, and the common electrode 115 are stacked in this order from the insulating layer 214b side.

The end portion of the pixel electrode 191 is covered with the partition 216. The pixel electrode 191 contains a material that reflects visible light, and the common electrode 115 contains a material that transmits visible light.

Light emitted from the light-emitting devices 190R, 190G, and 190B is emitted toward the substrate 154 side. Light enters the light-receiving device 110 through the substrate 154 and the adhesive layer 142. For the substrate 154, a material having a high visible-light-transmitting property is preferably used.

The pixel electrodes 191 can be formed using the same material in the same step. The common layer 112, the common layer 114, and the common electrode 115 are used in common in the light-receiving device 110 and the light-emitting devices 190R, 190G, and 190B. The light-receiving device 110 and the light-emitting device of each color can have a common structure except for the active layer 183 and the light-emitting layer. Thus, the light-receiving device 110 can be incorporated into the display apparatus 100E without a significant increase in the number of manufacturing steps.

The resin layer 159 and the light shielding layer 158 are provided on a surface of the insulating layer 157 on the substrate 153 side. The resin layer 159 is provided in positions overlapping with the light-emitting devices 190R, 190G, and 190B and is not provided in a position overlapping with the light-receiving device 110. The light shielding layer 158 is provided to cover the surface of the insulating layer 157 on the substrate 153 side, a side surface of the resin layer 159, and a surface of the resin layer 159 on the substrate 153 side. The light shielding layer 158 has openings in a position overlapping with the light-receiving device 110 and in positions overlapping with the light-emitting devices 190R, 190G, and 190B. Providing the light shielding layer 158 can control the range where the light-receiving device 110 detects light. Furthermore, with the light shielding layer 158, light can be inhibited from directly entering the light-receiving device 110 from the light-emitting devices 190R, 190G, and 190B without through an object. Hence, a sensor with less noise and high sensitivity can be obtained. Providing the resin layer 159 allows the distance from the light shielding layer 158 to the light-emitting device of each color to be shorter than the distance from the light shielding layer 158 to the light-receiving device 110. Accordingly, viewing angle dependence of display can be inhibited while noise of the sensor is reduced. Thus, both the display quality and the imaging quality can be increased.

As illustrated in FIG. 13, the partition 216 has an opening between the light-receiving device 110 and the light-emitting device 190R. A light shielding layer 219a is provided to fill the opening. The light shielding layer 219a is positioned between the light-receiving device 110 and the light-emitting device 190R. The light shielding layer 219a absorbs light emitted from the light-emitting device 190R. This can inhibit stray light from entering the light-receiving device 110.

A spacer 219b is provided over the partition 216 and positioned between the light-emitting device 190G and the light-emitting device 190B. A top surface of the spacer 219b is preferably closer to the light shielding layer 158 than a top surface of the light shielding layer 219a is. For example, the sum of the height (thickness) of the partition 216 and the height (thickness) of the spacer 219b is preferably larger than the height (thickness) of the light shielding layer 219a. Thus, filling with the adhesive layer 142 can be facilitated. As illustrated in FIG. 14A, the light shielding layer 158 may be in contact with the common electrode 115 (or the protective layer) in a portion where the spacer 219b and the light shielding layer 158 overlap with each other.

The connection portion 244 is provided in a region of the substrate 153 that does not overlap with the substrate 154. In the connection portion 244, the wiring 165 is electrically connected to the FPC 172 through a conductive layer 167, the conductive layer 166, and the connection layer 242. The conductive layer 167 can be obtained by processing the same conductive film as the conductive layer 169. On the top surface of the connection portion 244, the conductive layer 166 obtained by processing the same conductive film as the pixel electrode 191 is exposed. Thus, the connection portion 244 and the FPC 172 can be electrically connected to each other through the connection layer 242.

Each of the transistor 243, the transistor 248, the transistor 249, and the transistor 240 includes the conductive layer 221 functioning as a gate, the insulating layer 211 functioning as a gate insulating layer, a semiconductor layer including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through openings provided in the insulating layer 215. One of the conductive layer 222a and the conductive layer 222b functions as a source, and the other functions as a drain.

In FIG. 13 and FIG. 14A, the insulating layer 225 overlaps with the channel formation region 231i of the semiconductor layer 231 and does not overlap with the low-resistance regions 231n. The structure illustrated in FIG. 13 and FIG. 14A can be formed by processing the insulating layer 225 using the conductive layer 223 as a mask, for example. In FIG. 13 and FIG. 14A, the insulating layer 215 is provided to cover the insulating layer 225 and the conductive layer 223, and the conductive layer 222a and the conductive layer 222b are connected to the low-resistance regions 231n through the openings in the insulating layer 215. Furthermore, an insulating layer that covers the transistor may be provided.

Meanwhile, in FIG. 14B, an example in which the insulating layer 225 covers a top surface and a side surface of the semiconductor layer is illustrated. The conductive layer 222a and the conductive layer 222b are connected to the corresponding low-resistance regions 231n through openings provided in the insulating layer 225 and the insulating layer 215.

As described above, in the display apparatus of one embodiment of the present invention, the distances between the two light-emitting devices and the light-receiving device (or the light-emitting and light-receiving device) differ from each other, and the distances from the two light-emitting devices to the opening of the light shielding layer overlapping with the light-receiving device (or the light-emitting and light-receiving device) differ from each other. With this structure, the light-receiving device or the light-emitting and light-receiving device can receive light coming from one of the two light-emitting devices more than light coming from the other. Accordingly, much light coming from the light-emitting device used as a light source can be made to enter the light-receiving device or the light-emitting and light-receiving device in the display apparatus of one embodiment of the present invention, for example.

### <Example of Pixel Circuit>

The display apparatus of one embodiment of the present invention includes, in the display portion, first pixel circuits each including a light-receiving device and second pixel circuits each including a light-emitting device. The first pixel circuits and the second pixel circuits are each arranged in a matrix.

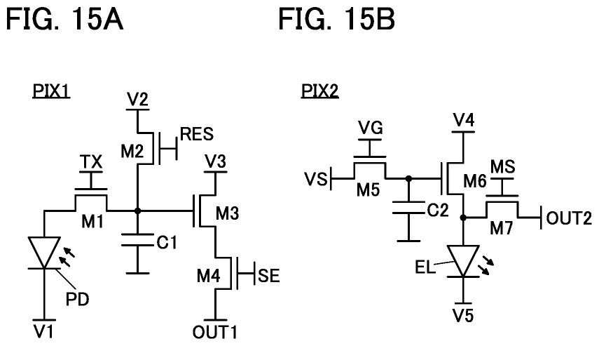

FIG. 15A illustrates an example of the first pixel circuit including a light-receiving device, and FIG. 15B illustrates an example of the second pixel circuit including a light-emitting device.

A pixel circuit PIX1 illustrated in FIG. 15A includes a light-receiving device PD, a transistor M1, a transistor M2, a transistor M3, a transistor M4, and a capacitor C1. Here, an example in which a photodiode is used as the light-receiving device PD is illustrated.

A cathode of the light-receiving device PD is electrically connected to a wiring V1, and an anode thereof is electrically connected to one of a source and a drain of the transistor M1. A gate of the transistor M1 is electrically connected to a wiring TX, and the other of the source and the drain thereof is electrically connected to one electrode of the capacitor C1, one of a source and a drain of the transistor M2, and a gate of the transistor M3. A gate of the transistor M2 is electrically connected to a wiring RES, and the other of the source and the drain thereof is electrically connected to a wiring V2. One of a source and a drain of the transistor M3 is electrically connected to a wiring V3, and the other of the source and the drain thereof is electrically connected to one of a source and a drain of the transistor M4. A gate of the transistor M4 is electrically connected to a wiring SE, and the other of the source and the drain thereof is electrically connected to a wiring OUT1.

A constant potential is supplied to the wiring V1, the wiring V2, and the wiring V3. When the light-receiving device PD is driven with a reverse bias, a potential lower than the potential of the wiring V1 is supplied to the wiring V2. The transistor M2 is controlled by a signal supplied to the wiring RES and has a function of resetting the potential of a node connected to the gate of the transistor M3 to a potential supplied to the wiring V2. The transistor M1 is controlled by a signal supplied to the wiring TX and has a function of controlling the timing at which the potential of the node changes, in accordance with current flowing through the light-receiving device PD. The transistor M3 functions as an amplifier transistor for performing output in response to the potential of the node. The transistor M4 is controlled by a signal supplied to the wiring SE and functions as a selection transistor for reading an output corresponding to the potential of the node by an external circuit connected to the wiring OUT1.

A pixel circuit PIX2 illustrated in FIG. 15B includes a light-emitting device EL, a transistor M5, a transistor M6, a transistor M7, and a capacitor C2. Here, an example in which a light-emitting diode is used as the light-emitting device EL is illustrated. In particular, an organic EL element is preferably used as the light-emitting device EL.

A gate of the transistor M5 is electrically connected to a wiring VG, one of a source and a drain thereof is electrically connected to a wiring VS, and the other of the source and the drain thereof is electrically connected to one electrode of the capacitor C2 and a gate of the transistor M6. One of a source and a drain of the transistor M6 is electrically connected to a wiring V4, and the other of the source and the drain thereof is electrically connected to an anode of the light-emitting device EL and one of a source and a drain of the transistor M7. A gate of the transistor M7 is electrically connected to a wiring MS, and the other of the source and the drain thereof is electrically connected to a wiring OUT2. A cathode of the light-emitting device EL is electrically connected to a wiring V5.

A constant potential is supplied to the wiring V4 and the wiring V5. In the light-emitting device EL, the anode side can have a high potential and the cathode side can have a lower potential than the anode side. The transistor M5 is controlled by a signal supplied to the wiring VG and functions as a selection transistor for controlling a selection state of the pixel circuit PIX2. The transistor M6 functions as a driving transistor that controls current flowing through the light-emitting device EL, in accordance with a potential supplied to the gate. When the transistor M5 is in an on state, a potential supplied to the wiring VS is supplied to the gate of the transistor M6, and the emission luminance of the light-emitting device EL can be controlled in accordance with the potential. The transistor M7 is controlled by a signal supplied to the wiring MS and has a function of outputting a potential between the transistor M6 and the light-emitting device EL to the outside through the wiring OUT2.

The wiring V1, to which the cathode of the light-receiving device PD is electrically connected, and the wiring V5, to which the cathode of the light-emitting device EL is electrically connected, can be provided in the same layer and have the same level of potential.

In the display apparatus of one embodiment of the present invention, it is preferable to use transistors including a metal oxide (also referred to as an oxide semiconductor) in their semiconductor layers where channels are formed (such transistors are also referred to as OS transistors below) as all the transistors included in the pixel circuit PIX1 and the pixel circuit PIX2. An OS transistor has extremely low off-state current and enables electric charge stored in a capacitor that is series-connected to the transistor to be retained for a long time. Furthermore, power consumption of the display apparatus can be reduced with an OS transistor.

Alternatively, in the display apparatus of one embodiment of the present invention, it is preferable to use transistors including silicon in their semiconductor layers where channels are formed (such transistors are also referred to as Si transistors below) as all the transistors included in the pixel circuit PIX1 and the pixel circuit PIX2. As silicon, single crystal silicon, polycrystalline silicon, amorphous silicon, and the like can be given. It is particularly preferable to use transistors including low-temperature polysilicon (LTPS) (hereinafter also referred to as LTPS transistors) in their semiconductor layers. An LTPS transistor has high field-effect mobility and can operate at high speed.

With the use of Si transistors such as LTPS transistors, a variety of circuits formed using a CMOS circuit and a display portion can be easily formed on the same substrate. Thus, external circuits mounted on the display apparatus can be simplified, and costs of parts and mounting costs can be reduced.

In the display apparatus of one embodiment of the present invention, two kinds of transistors are preferably used in the pixel circuit PIX1. Specifically, the pixel circuit PIX1 preferably includes an OS transistor and an LTPS transistor. Changing the material of the semiconductor layer depending on the desired function of the transistor can increase the quality of the pixel circuit PIX1 and the accuracy of sensing and image capturing. In that case, in the pixel circuit PIX2, one or both of an OS transistor and an LTPS transistor may be used.

Furthermore, even when two kinds of transistors (e.g., OS transistors and LTPS transistors) are used in the pixels, using the LTPS transistors facilitates formation of a variety of circuits formed using a CMOS circuit and a display portion on the same substrate. Thus, external circuits mounted on the display apparatus can be simplified, and costs of parts and mounting costs can be reduced.

A transistor using a metal oxide having a wider band gap and a lower carrier density than silicon can achieve extremely low off-state current. Thus, such low off-state current enables retention of electric charge accumulated in a capacitor that is series-connected to the transistor for a long time. Therefore, it is particularly preferable to use OS transistors as the transistor M1, the transistor M2, and the transistor M5 each of which is series-connected to the capacitor C1 or the capacitor C2.

A Si transistor is preferably used as the transistor M3. This enables high-speed reading operation of imaging data.

Note that the display apparatus which includes, in the display portion, the first pixel circuits each including a light-receiving device and the second pixel circuits each including a light-emitting device can be driven in any of an image display mode, an image capture mode, and a mode of simultaneously performing image display and image capturing. In the image display mode, a full-color image can be displayed using the light-emitting devices, for example. In the image capture mode, an image for image capturing (e.g., a green monochromatic image or a blue monochromatic image) can be displayed using the light-emitting devices and image capturing can be performed using the light-receiving devices, for example. Fingerprint authentication can be performed in the image capture mode, for example. In the mode of simultaneously performing image display and image capturing, an image for image capturing can be displayed using the light-emitting devices and image capturing can be performed using the light-receiving devices in some pixels, and a full-color image can be displayed using the light-emitting devices in the other pixels, for example.

Although the transistors are illustrated as n-channel transistors in FIG. 15A and FIG. 15B, p-channel transistors can alternatively be used. The transistors are not limited to single-gate transistors and may further include a back gate.

One or more layers including one or both of the transistor and the capacitor are preferably provided to overlap with the light-receiving device PD or the light-emitting device EL. Thus, the effective area of each pixel circuit can be reduced, and a high-resolution display portion can be achieved.

This embodiment can be combined with the other embodiments as appropriate.

### EMBODIMENT 4

In this embodiment, a metal oxide (also referred to as an oxide semiconductor) that can be used in the OS transistor described in the above embodiment is described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including a completely amorphous structure), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of the quartz glass substrate shows a peak with a substantially bilaterally symmetrical shape. On the other hand, the peak of the XRD spectrum of the IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <Structure of Oxide Semiconductor>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

### <Structure of Oxide Semiconductor>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region contains indium oxide, indium zinc oxide, or the like as its main component. The second region contains gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and less than 30%, further preferably higher than or equal to 0% and less than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

This embodiment can be combined with the other embodiments as appropriate.

### EMBODIMENT 5

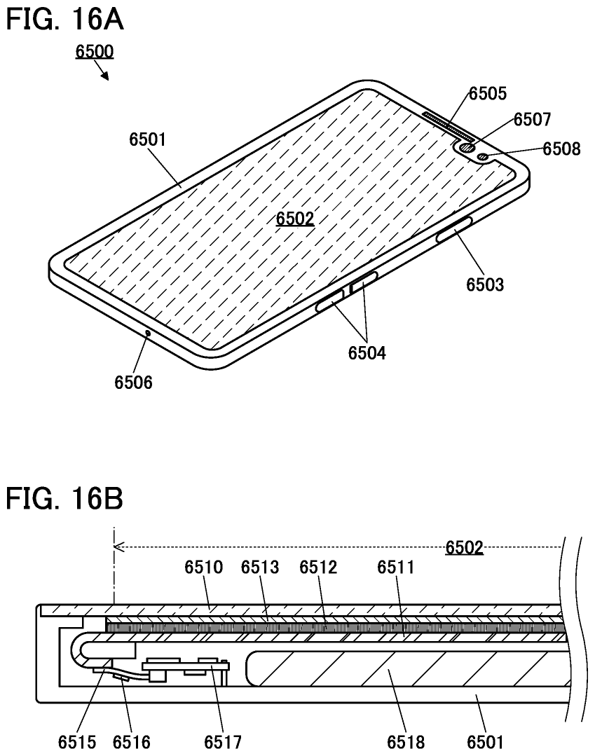

In this embodiment, electronic devices of embodiments of the present invention will be described with reference to FIG. 16 to FIG. 18.

An electronic device of one embodiment of the present invention can perform image capturing or detect touch operation in a display portion. Thus, the electronic device can have improved functionality and convenience.

Examples of the electronic devices of embodiments of the present invention include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 16A is a portable information terminal that can be used as a smartphone.

The electronic device 6500 includes a housing 6501, a display portion 6502, a power button 6503, operation buttons 6504, a speaker 6505, a microphone 6506, a camera 6507, a light source 6508, and the like. The display portion 6502 has a touch panel function.

The display apparatus described in Embodiment 2 or the display apparatus described in Embodiment 3 can be used in the display portion 6502.

FIG. 16B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be provided. Since the display panel 6511 is extremely thin, the battery 6518 with high capacity can be mounted with the thickness of the electronic device controlled. An electronic device with a narrow frame can be obtained when part of the display panel 6511 is folded back so that the portion connected to the FPC 6515 is positioned on the rear side of a pixel portion.

Using the display apparatus described in Embodiment 2 as the display panel 6511 allows image capturing on the display portion 6502. For example, an image of a fingerprint is captured by the display panel 6511; thus, fingerprint authentication can be performed.

By further including the touch sensor panel 6513, the display portion 6502 can have a touch panel function. A variety of types such as a capacitive type, a resistive type, a surface acoustic wave type, an infrared type, an optical type, and a pressure-sensitive type can be used for the touch sensor panel 6513. Alternatively, the display panel 6511 may function as a touch sensor; in such a case, the touch sensor panel 6513 is not necessarily provided.

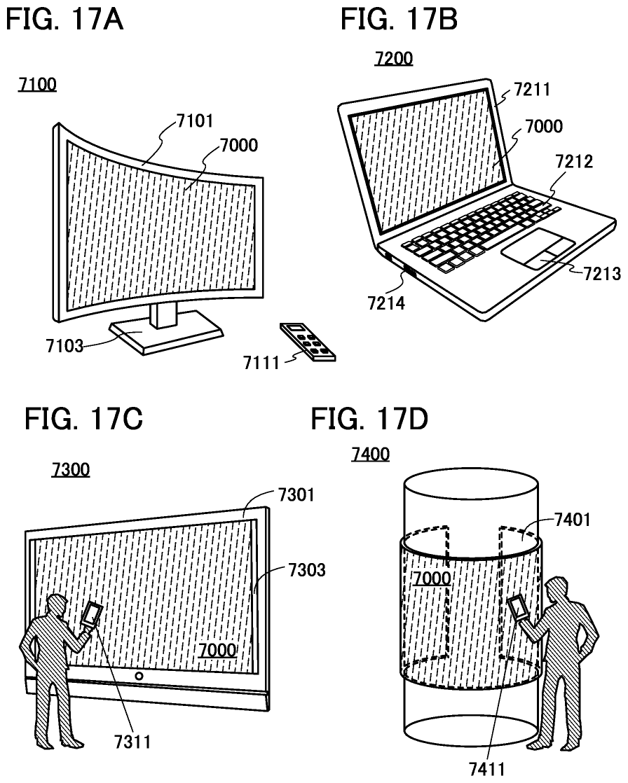

FIG. 17A illustrates an example of a television device. In a television device 7100, a display portion 7000 is incorporated in a housing 7101. Here, a structure in which the housing 7101 is supported by a stand 7103 is illustrated.

The display apparatus described in Embodiment 2 can be used in the display portion 7000.

Operation of the television device 7100 illustrated in FIG. 17A can be performed with an operation switch provided in the housing 7101 or a separate remote controller 7111. Alternatively, the display portion 7000 may include a touch sensor, and the television device 7100 may be operated by touch on the display portion 7000 with a finger or the like. The remote controller 7111 may be provided with a display portion for displaying data output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 17B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus described in Embodiment 2 can be used in the display portion 7000.

FIG. 17C and FIG. 17D illustrate examples of digital signage.

Digital signage 7300 illustrated in FIG. 17C includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 17D is digital signage 7400 attached to a cylindrical pillar 7401. The digital signage 7400 includes the display portion 7000 provided along a curved surface of the pillar 7401.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 17C and FIG. 17D, it is preferable that the digital signage 7300 or the digital signage 7400 can work with an information terminal 7311 or an information terminal 7411 such as a user's smartphone through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

The display apparatus described in Embodiment 2 can be used for the display portion of the information terminal 7311 in FIG. 17C or the information terminal 7411 in FIG. 17D.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

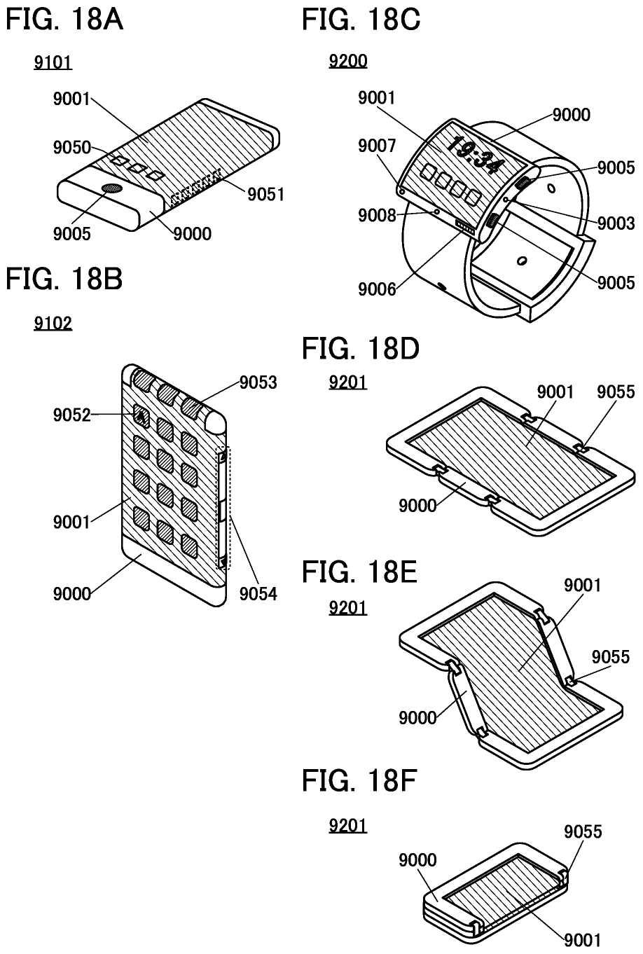

Electronic devices illustrated in FIG. 18A to FIG. 18F include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 18A to FIG. 18F have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 18A to FIG. 18F are described below.

FIG. 18A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image data on its plurality of surfaces. FIG. 18A illustrates an example where three icons 9050 are displayed. Information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the reception strength of an antenna. Alternatively, the icon 9050 or the like may be displayed in the position where the information 9051 is displayed.

FIG. 18B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed in a position that can be observed from above the portable information terminal 9102, with the portable information terminal 9102 put in a breast pocket of his/her clothes. The user can seethe display without taking out the portable information terminal 9102 from the pocket and decide whether to answer the call, for example.

FIG. 18C is a perspective view illustrating a watch-type portable information terminal 9200. For example, the portable information terminal 9200 can be used as a smartwatch (registered trademark). The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 18D to FIG. 18F are perspective views illustrating a foldable portable information terminal 9201. FIG. 18D is a perspective view of an opened state of the portable information terminal 9201, FIG. 18F is a perspective view of a folded state thereof, and FIG. 18E is a perspective view of a state in the middle of change from one of FIG. 18D and FIG. 18F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

This embodiment can be combined with the other embodiments as appropriate.

### EXAMPLE 1

In this example, evaluation results of the characteristics of fabricated light-receiving devices will be described. Note that structures of light-receiving devices fabricated in examples below are in common with that of a light-emitting device, each of which is a stacked-layer structure that can be fabricated by replacing a light-emitting layer of the light-emitting device with an active layer of the light-receiving device. Furthermore, the light-receiving devices each have a stacked-layer structure that can function as a light-emitting and light-receiving device by adding the light-emitting layer of the light-emitting device.

In this example, a light-receiving device (a device A) of one embodiment of the present invention and a light-receiving device (a comparative device B) of a comparative example were fabricated.

Chemical formulae of materials used in this example are shown below.

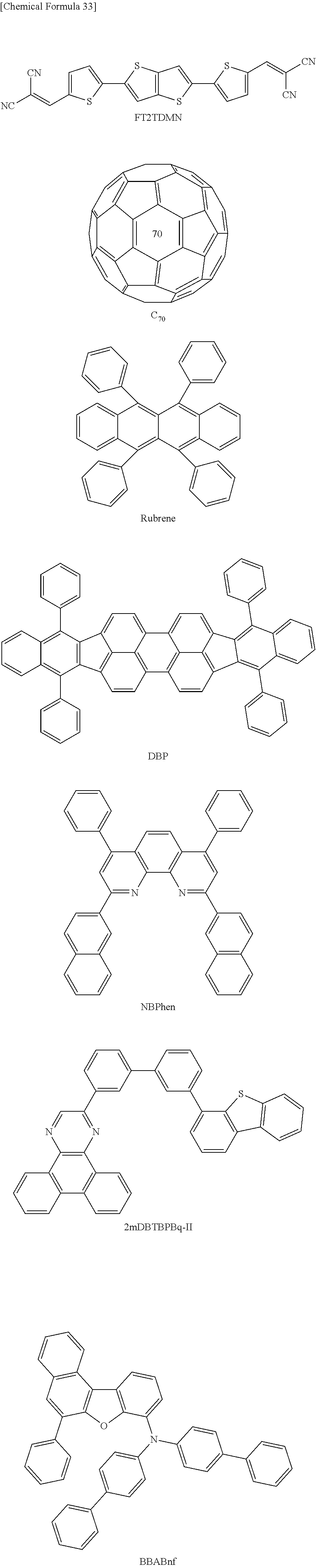

Specific structures of the light-receiving devices fabricated in this example are shown in Table 1 and Table 2. For the structures of the light-receiving devices, the light-receiving device 10 illustrated in FIG. 1E as an example can be referred to. The light-receiving devices fabricated in this example had similar structures except for the structure of the active layer 23.

TABLE 1

| | | Weight | |
|---|---|---|---|
| | Component material | ratio | Film thickness |
| Second electrode 13 | Ag:Mg (10:1)\ITO | — | 10 nm\40 nm |
| Layer 25b | LiF | — | 1 nm |
| Layer 25a | NBPhen | — | 10 nm |
| | 2mDBTBPDBq-II | — | 10 nm |
| Active layer 23 | * | * | 60 nm |
| Layer 21b | BBABnf | — | 40 nm |
| Layer 21a | BBABnf:OCHD-003 | 1:0.1 | 10 nm |
| First electrode 11 | APC\ITSO | — | 100 nm\100 nm |

TABLE 2

| | |
|---|---|
| | Active layer 23 |
| Sample name | * |

| | | |
|---|---|---|
| Device A | FT2TDMN:Rubrene | 5:5 |
| Comparison device B | C70:DBP | 9:1 |

The first electrode 11 was formed in such a manner that an alloy film of silver, palladium, and copper (APC: Ag—Pd—Cu) was formed to a thickness of 100 nm by a sputtering method, and a film of indium tin oxide containing silicon oxide (ITSO) was formed to a thickness of 100 nm by a sputtering method.

Next, a base material over which the first electrode 11 was formed was washed with water, baked at 200° C. for an hour, and then subjected to UV ozone treatment for 370 seconds. After that, the substrate was transferred into a vacuum evaporation apparatus where the pressure was reduced to approximately 10⁻⁴ Pa, and vacuum baking was performed at 170° C. for 30 minutes in a heating chamber of the vacuum evaporation apparatus. Then, the substrate was cooled down for approximately 30 minutes.

The layer 21a functioning as a hole-transport layer was formed by depositing N,N-bis(4-biphenyl)-6-phenylbenzo[b]naphtho[1,2-d]furan-8-amine (abbreviation: BBABnf) and an electron acceptor material containing fluorine with a molecular weight of 672 (OCHD-003) by co-evaporation at a weight ratio of BBABnf: OCHD-001=1:0.1. The layer 21a was formed to a thickness of 10 nm.

The layer 21b functioning as a hole-transport layer was formed by depositing BBABnf by evaporation to a thickness of 40 nm.

The active layer 23 of the device A of one embodiment of the present invention was formed by depositing 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN) represented by Structural Formula (126) above and Rubrene represented by Structural Formula (201) above by co-evaporation at a weight ratio of 5:5. The active layer 23 was formed to a thickness of 60 nm.

The active layer 23 of the comparative device B of the comparative example was formed by depositing fullerene C₇₀ and tetraphenyldibenzoperiflanthene (abbreviation: DBP) by co-evaporation at a weight ratio of C₇₀: DBP=9:1. The active layer 23 was formed to a thickness of 60 nm.

Note that the evaporation temperature of fullerene C₇₀ used for the active layer 23 of the comparative device B was approximately 600° C., and the evaporation temperature of DBP was approximately 400° C. In contrast, the evaporation temperature of FT2TDMN used for the active layer 23 of the device A of one embodiment of the present invention was approximately 250° C., and the evaporation temperature of Rubrene was approximately 200° C., which were low. Therefore, when the structure of the optical device of one embodiment of the present invention is used, an optical device with high productivity can be fabricated.

The layer 25a functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation to a thickness of 10 nm and subsequently depositing 2,9-bis(naphthalen-2-yl)-4,7-diphenyl-1,10-phenanthroline (abbreviation: NBPhen) by evaporation to a thickness of 10 nm.

The layer 25b functioning as an electron-transport layer was formed by depositing lithium fluoride (LiF) by evaporation to a thickness of 1 nm.

The second electrode 13 was formed in such a manner that silver (Ag) and magnesium (Mg) were deposited by co-evaporation at a volume ratio of 10:1 to have a thickness of 10 nm; then, indium tin oxide (ITO) was deposited by a sputtering method to have a thickness of 40 nm.

From the above, the device A and the comparative device B that differed in the structure of the active layer 23 were each fabricated.

### <Current-Voltage Characteristics>

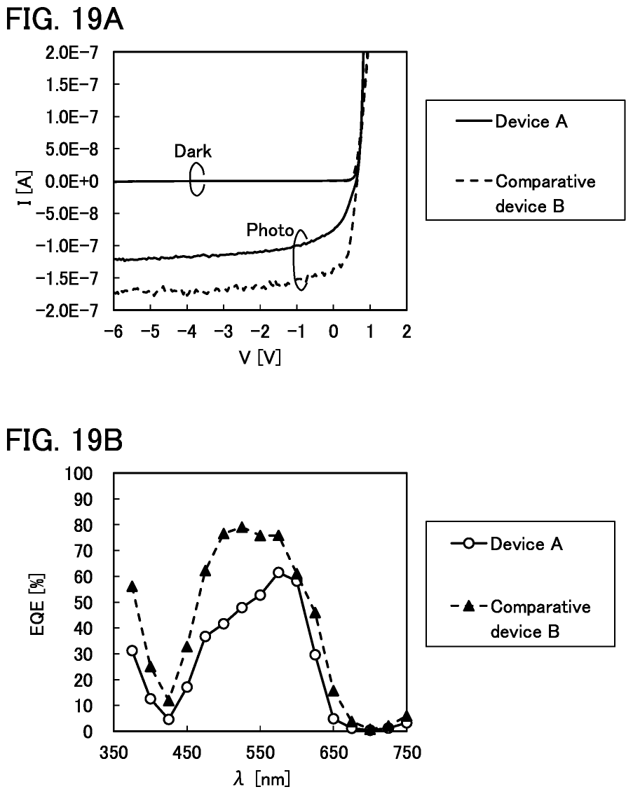

Next, the current-voltage characteristics of each light-receiving device were measured. The measurement was performed in each of a state with irradiation with monochromatic light having a wavelength of 525 nm at an irradiance of 12.5 μW/cm² (denoted by Photo) and a dark state (denoted by Dark). The current-voltage characteristics of the device A and the comparative device B are shown in FIG. 19A. In FIG. 19A, the horizontal axis represents voltage V and the vertical axis represents current I.

As shown in FIG. 19A, it was confirmed that the light-receiving devices each exhibited favorable saturation characteristics.

FIG. 19B shows wavelength dependence of external quantum efficiency (EQE). The EQE was measured at a voltage of −4V and an irradiance of 12.5 μW/cm² with various wavelengths. In FIG. 19B, the horizontal axis represents wavelength λ and the vertical axis represents EQE.

As shown in FIG. 19B, it was confirmed that the light-receiving devices each had light-receiving sensitivity in a wavelength region greater than or equal to 450 nm and less than or equal to 650 nm.

### EXAMPLE 2

In this example, evaluation results of the characteristics of fabricated light-receiving devices will be described.

In this example, light-receiving devices (a device 1a to a device id and a device 2a to a device 2d) of one embodiment of the present invention and light-receiving devices (a comparative device 1A to a comparative device 1C and a comparative device 2A to a comparative device 2C) of comparative examples were fabricated.

Chemical formulae of materials used in this example are shown below.

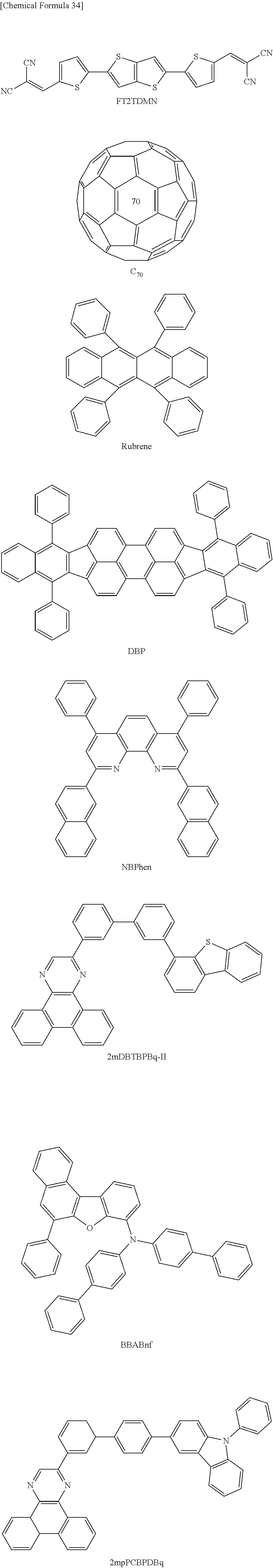

Specific structures of the light-receiving devices fabricated in this example are shown in Table 3 and Table 4. For the structures of the light-receiving devices, the light-receiving device 10 illustrated in FIG. 1E as an example can be referred to. The light-receiving devices fabricated in this example had similar structures except for the structures of the active layer 23 and the layer 25a.

Note that the light-receiving devices in this example are the same as the light-receiving devices in Example 1 except for change in the structures of the active layer 23 and the layer 25a. Therefore, as for the methods for fabricating the light-receiving devices in this example, Example 1 can be referred to for portions similar to those of the light-receiving devices in Example 1.

TABLE 3

| | | Weight | |
|---|---|---|---|
| | Component material | ratio | Film thickness |
| Second electrode 13 | Ag:Mg (10:1)\ITO | — | 10 nm\40 nm |
| Layer 25b | LiF | — | 1 nm |
| Layer 25a | NBPhen | — | 10 nm |
| | ** | — | ** |
| Active layer 23 | * | 9:1 | 60 nm |
| Layer 21b | BBABnf | — | 40 nm |
| Layer 21a | BBABnf:OCHD-003 | 1:0.1 | 10 nm |
| First electrode 11 | APC\ITSO | — | 100 nm\100 nm |

TABLE 4

| | Active layer 23 | Layer 25a | |
|---|---|---|---|
| Sample name | * | ** | |
| Device 1a | FT2TDMN:Rubrene | 2mDBTBPDBq-II | 10 nm |
| Device 1b | | | 30 nm |
| Device 1c | | | 50 nm |
| Device 1d | | | 70 nm |
| Device 2a | | 2mpPCBPDBq | 10 nm |
| Device 2b | | | 30 nm |
| Device 2c | | | 50 nm |
| Device 2d | | | 70 nm |
| Comparison device 1A | C70:DBP | 2mDBTBPDBq-II | 10 nm |
| Comparison device 1B | | | 40 nm |
| Comparison device 1C | | | 70 nm |
| Comparison device 2A | | 2mpPCBPDBq | 10 nm |
| Comparison device 2B | | | 40 nm |
| Comparison device 2C | | | 70 nm |

The first electrode 11, the layer 21a, and the layer 21b were formed. Since the description in Example 1 can be referred to for the formation of the first electrode 11, the layer 21a, and the layer 21b, the detailed description is omitted.

The active layer 23 of each of the device 1a to the device id and the device 2a to the device 2d of one embodiment of the present invention was formed by depositing FT2TDMN represented by Structural Formula (126) above and Rubrene represented by Structural Formula (201) above by co-evaporation at a weight ratio of 9:1. The active layer 23 was formed to a thickness of 60 nm.

The active layer 23 of each of the comparative device 1A to the comparative device 1C and the comparative device 2A to the comparative device 2C of the comparative examples was formed by depositing fullerene C₇₀ and tetraphenyldibenzoperiflanthene (abbreviation: DBP) by co-evaporation at a weight ratio of C₇₀: DBP=9:1. The active layer 23 was formed to a thickness of 60 nm.

In each of the device 1a to the device Id of one embodiment of the present invention and the comparative device 1A to the comparative device 1C of the comparative examples, the layer 25a functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation and subsequently depositing 2,9-bis(naphthalen-2-yl)-4,7-diphenyl-1,10-phenanthroline (abbreviation: NBPhen) by evaporation to a thickness of 10 nm.

In each of the device 2a to the device 2d of one embodiment of the present invention and the comparative device 2A to the comparative device 2C of the comparative examples, the layer 25a functioning as an electron-transport layer was formed by depositing 2-[4′-(9-phenyl-9H-carbazole-3-yl)-3,1′-biphenyl-1-yl]dibenzo[f,h]quinoxaline (abbreviation: 2mpPCBPDBq) by evaporation and subsequently depositing 2,9-bis(naphthalen-2-yl)-4,7-diphenyl-1,10-phenanthroline (abbreviation: NBPhen) by evaporation to a thickness of 10 nm.

The layer 25b functioning as an electron-transport layer and the second electrode 13 were formed. Since the description in Example 1 can be referred to for the formation of the layer 25b and the second electrode 13, the detailed description is omitted.

From the above, the device 1a to the device id, the device 2a to the device 2d, the comparative device 1A to the comparative device 1C, and the comparative device 2A to the comparative device 2C that differed in the structures of the active layer 23 and the layer 25a were each fabricated.

### <Current-Voltage Characteristics>

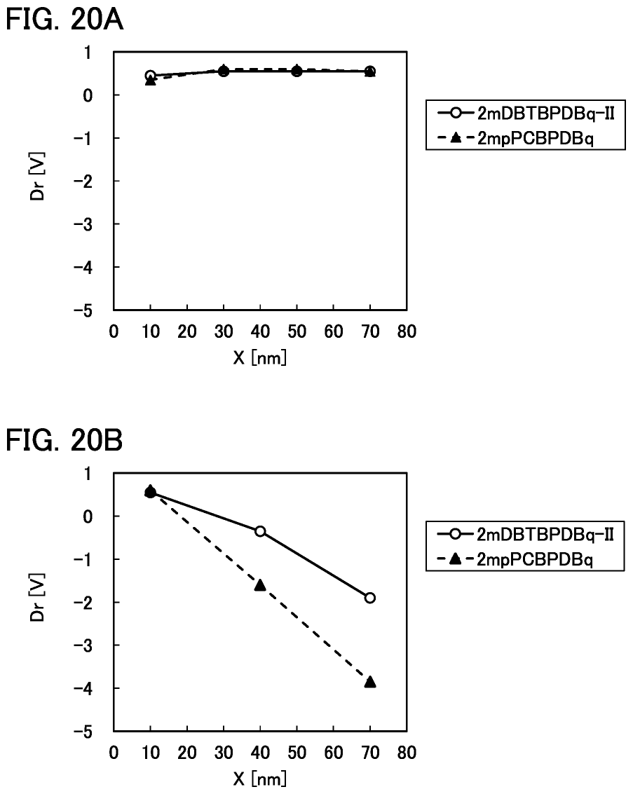

Next, the current-voltage characteristics of each light-receiving device were measured. The measurement was performed in a state where irradiation with monochromatic light having a wavelength of 525 nm was performed at an irradiance of 12.5 μW/cm². FIG. 20A and FIG. 20B show the relationship of voltage at the time when current becomes greater than or equal to 20 nA and the thickness of the layer 25a in the current-voltage characteristics. The voltage at the time when current becomes greater than or equal to 20 nA is a value corresponding to the driving voltage of the light-receiving devices.

FIG. 20A shows data on the device 1a to the device 1d and the device 2a to the device 2d of one embodiment of the present invention, and FIG. 20B shows data on the comparative device 1A to a comparative device 1D and the comparative device 2A to a comparative device 2D of the comparative examples. In FIG. 20A and FIG. 20B, the horizontal axis represents thickness X of the layer 25a and the vertical axis represents voltage Dr at the time current becomes greater than or equal to 20 nA.

As shown FIG. 20A, it was confirmed that the light-receiving devices of one embodiment of the present invention had a small change in the voltage Dr with respect to the material and thickness of the layer 25a. In contrast, as shown in FIG. 20B, it was confirmed that the light-receiving devices of the comparative examples had a large change in the voltage Dr with respect to the material and thickness of the layer 25a. In addition, it was confirmed that in the light-receiving devices of one embodiment of the present invention, the absolute value of the voltage Dr was small, approximately from 0.35 V to 0.6 V, and the driving voltage was low, as compared with the case of the light-receiving devices of the comparative examples.

### EXAMPLE 3

In this example, evaluation results of the characteristics of fabricated light-receiving devices will be described.

In this example, light-receiving devices (a device 3a to a device 3d, a device 4a to a device 4d, a device 5a to a device 5d, and a device 6a to a device 6d) of one embodiment of the present invention were fabricated.

Note that the light-receiving devices in this example are the same as the light-receiving devices in Example 1 except for change in the structures of the active layer 23 and the layer 25a. Therefore, as for the methods for fabricating the light-receiving devices in this example, Example 1 can be referred to for portions similar to those of the light-receiving devices in Example 1.

Chemical formulae of materials used in this example are shown below.

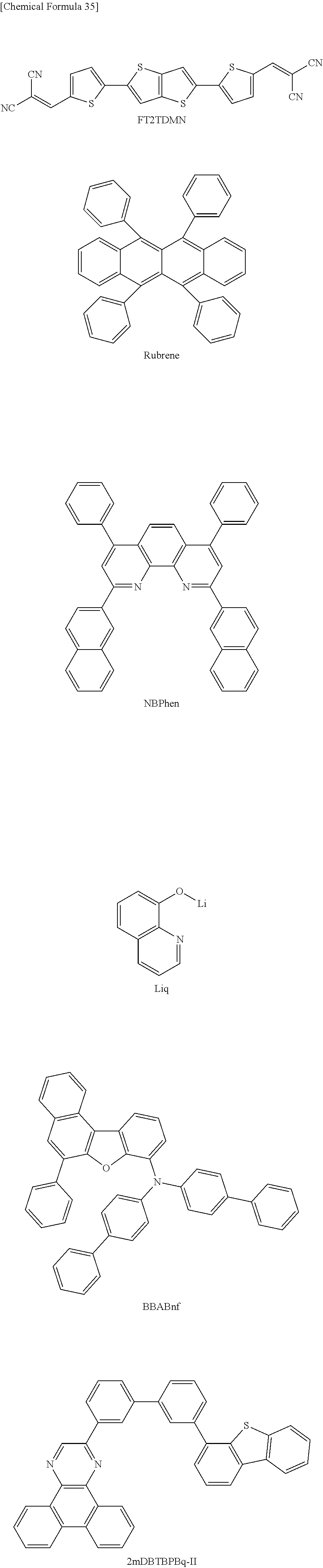

Specific structures of the light-receiving devices fabricated in this example are shown in Table 5 and Table 6. For the structures of the light-receiving devices, the light-receiving device 10 illustrated in FIG. 1E as an example can be referred to. The light-receiving devices fabricated in this example had similar structures except for the structures of the active layer 23 and the layer 25a.

TABLE 5

| | | Weight | |
|---|---|---|---|
| | Component material | ratio | Film thickness |
| Second electrode 13 | Ag:Mg (10:1) | — | 10 nm |
| Layer 25a | NBPhen:Liq | 1:.1 | 10 nm |
| | 2mDBTBPDBq-II | — | ** |
| Active layer 23 | FT2TDMN:Rubrene | 7:3 | * |
| Layer 21b | BBABnf | — | 40 nm |
| Layer 21a | BBABnf:OCHD-003 | 1:0.1 | 10 nm |
| First electrode 11 | APC\ITSO | — | 100 nm\100 nm |

TABLE 6

| | Active layer 23 | Layer 25a | |
|---|---|---|---|
| Sample name | * | ** | |
| Device 3a | 30 nm | 10 | nm |
| Device 3b | | 40 | nm |
| Device 3c | | 70 | nm |
| Device 3d | | 100 | nm |
| Device 4a | 60 nm | 10 | nm |
| Device 4b | | 40 | nm |
| Device 4c | | 70 | nm |
| Device 4d | | 100 | nm |
| Device 5a | 90 nm | 10 | nm |
| Device 5b | | 40 | nm |
| Device 5c | | 70 | nm |
| Device 5d | | 100 | nm |
| Device 6a | 120 nm | 10 | nm |
| Device 6b | | 40 | nm |
| Device 6c | | 70 | nm |
| Device 6d | | 100 | nm |

The first electrode 11, the layer 21a, and the layer 21b were formed. Since the description in Example 1 can be referred to for the formation of the first electrode 11, the layer 21a, and the layer 21b, the detailed description is omitted.

The active layer 23 was formed by depositing FT2TDMN represented by Structural Formula (126) above and Rubrene represented by Structural Formula (201) above by co-evaporation at a weight ratio of 7:3. The thickness of the active layer 23 differed between the samples.

The layer 25a functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation and subsequently depositing 2,9-bis(naphthalen-2-yl)-4,7-diphenyl-1,10-phenanthroline (abbreviation: NBPhen) and Liq by co-evaporation to a thickness of 10 nm at a weight ratio of 1:1. The thickness of 2-[3′-(dibenzothiophen-4-yl)biphenyl-3-yl]dibenzo[f,h]quinoxaline (abbreviation: 2mDBTBPDBq-II) differed between the samples.

The second electrode 13 was formed by depositing silver (Ag) and magnesium (Mg) by co-evaporation at a volume ratio of 10:1 to a thickness of 10 nm.

From the above, the device 3a to the device 3d, the device 4a to the device 4d, the device 5a to the device 5d, and the device 6a to the device 6d that differed in the structures of the active layer 23 and the layer 25a were each fabricated.

### <Current Density-Voltage Characteristics>

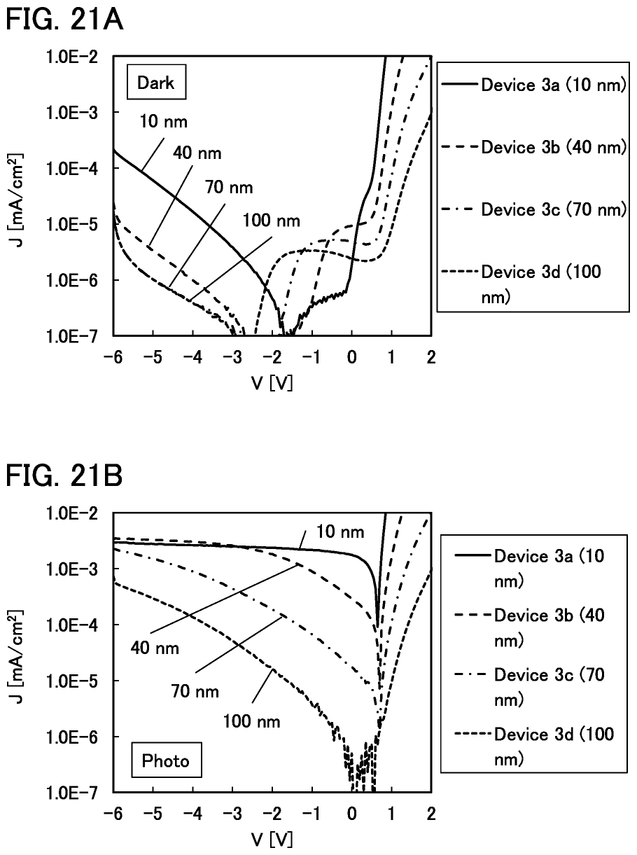

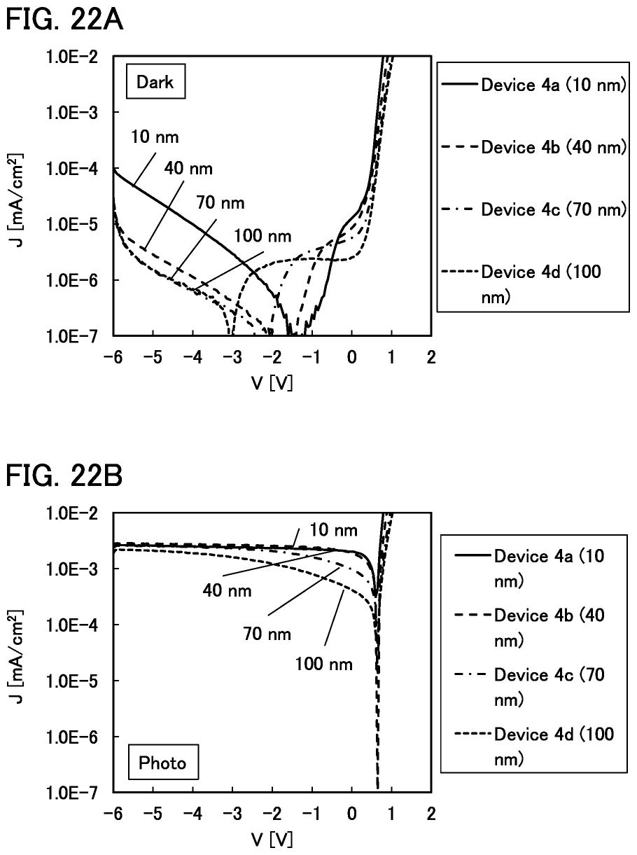

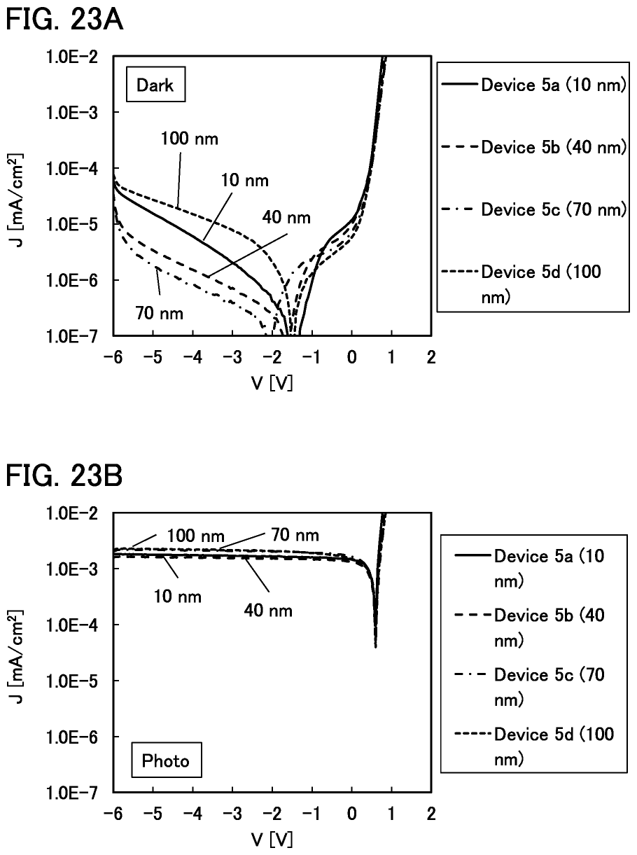

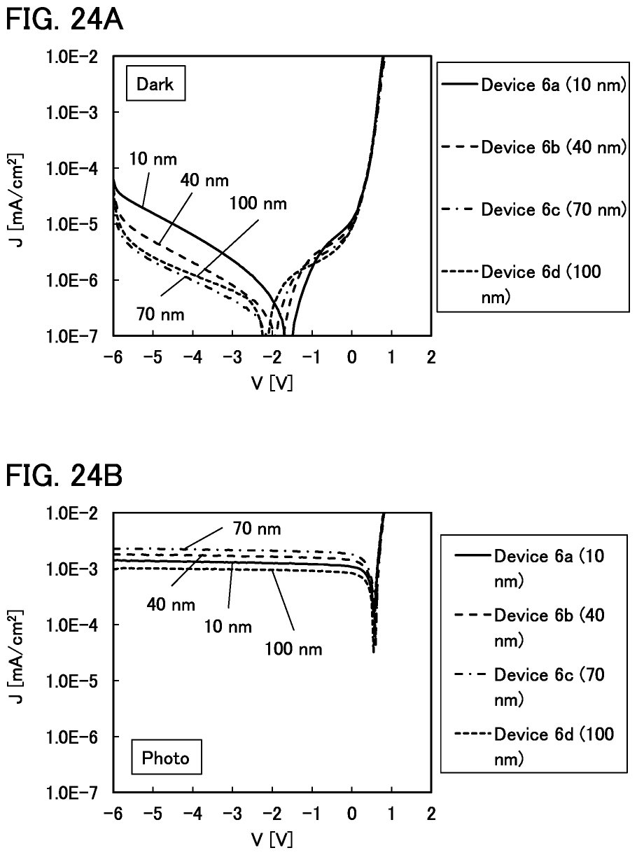

Next, the current density-voltage characteristics of each light-receiving device were measured. The measurement was performed in each of a state with irradiation with monochromatic light having a wavelength of 525 nm at an irradiance of 12.5 μW/cm² (denoted by Photo) and a dark state (denoted by Dark). FIG. 21A and FIG. 21B show the current density-voltage characteristics of the device 3a to the device 3d. FIG. 22A and FIG. 22B show the current density-voltage characteristics of the device 4a to the device 4d. FIG. 23A and FIG. 23B show the current density-voltage characteristics of the device 5a to the device 5d. FIG. 24A and FIG. 24B show the current density-voltage characteristics of the device 6a to the device 6d. In each of FIG. 21A to FIG. 24B, the horizontal axis represents voltage V and the vertical axis represents current density J.

As shown in FIG. 21A to FIG. 24B, it was confirmed that the light-receiving devices each exhibited favorable saturation characteristics.

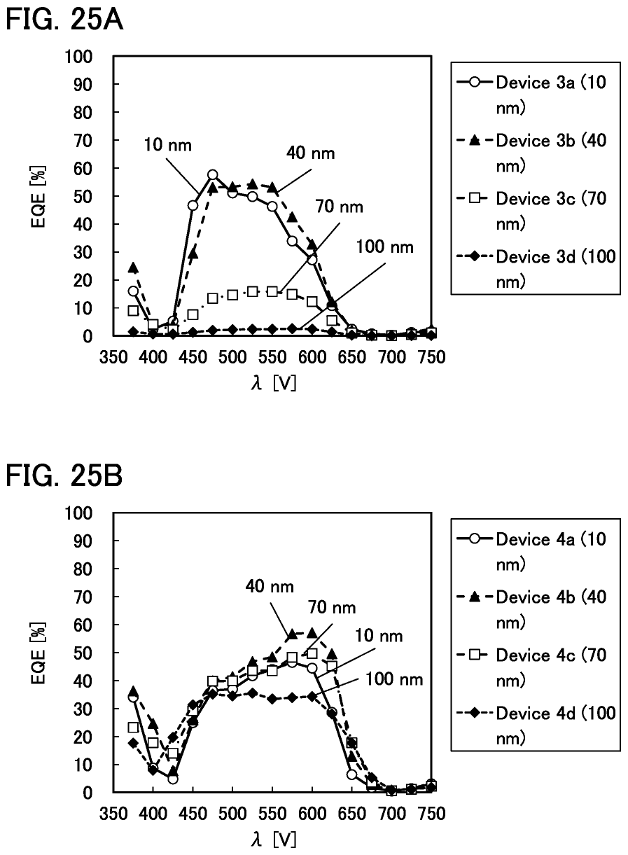

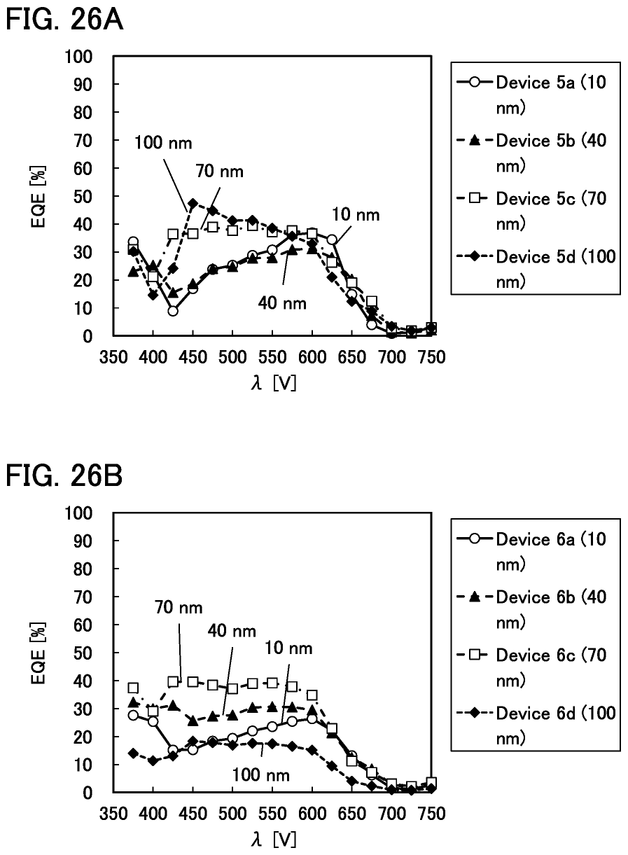

FIG. 25A shows wavelength dependence of external quantum efficiency (EQE) of the device 3a to the device 3d. FIG. 25B shows wavelength dependence of external quantum efficiency (EQE) of the device 4a to the device 4d. FIG. 26A shows wavelength dependence of external quantum efficiency (EQE) of the device 5a to the device 5d. FIG. 26B shows wavelength dependence of external quantum efficiency (EQE) of the device 6a to the device 6d. The EQE was measured at a voltage of −4V and an irradiance of 12.5 μW/cm² with various wavelengths. In each of FIG. 25A to FIG. 26B, the horizontal axis represents wavelength k and the vertical axis represents EQE.

As shown in FIG. 25A to FIG. 26B, it was confirmed that in the case where the thickness of the active layer 23 was greater than or equal to 60 nm, change in light-receiving sensitivity was small with respect to the thickness of the layer 25a.

### EXAMPLE 4

In this example, evaluation results of the characteristics of fabricated light-receiving devices will be described.

In this example, light-receiving devices (a device 7a to a device 7d, a device 8a to a device 8d, a device 9a to a device 9d, and a device 10a to a device 10d) of one embodiment of the present invention were fabricated.

Chemical formulae of materials used in this example are shown below.

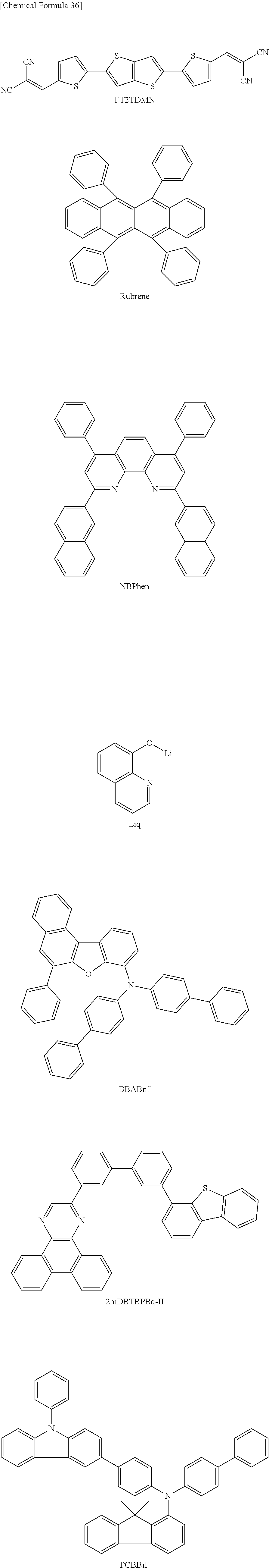

Specific structures of the light-receiving devices fabricated in this example are shown in Table 7 and Table 8. For the structures of the light-receiving devices, the light-receiving device 10 illustrated in FIG. 1E as an example can be referred to. The light-receiving devices fabricated in this example had similar structures except for the structures of the active layer 23 and the layer 21b.

TABLE 7

| | | Weight | |
|---|---|---|---|
| | Component material | ratio | Film thickness |
| Second electrode 13 | Ag:Mg (10:1) | — | 10 nm |
| Layer 25a | NBPhen:Liq | 1:.1 | 25 nm |
| | 2mDBTBPDBq-II | — | 15 nm |
| Active layer 23 | FT2TDMN:Rubrene | 7:3 | ** |
| Layer 21b | ** | — | * |
| Layer 21a | BBABnf:OCHD-003 | 1:0.1 | 10 nm |
| First electrode 11 | APC\ITSO | — | 100 nm\100 nm |

TABLE 8

| | | |
|---|---|---|
| | Active layer 23 | Layer 21b |
| Sample name | * | ** |

| | | | | |
|---|---|---|---|---|
| Device 7a | 60 nm | PCBBiF | 10 | nm |
| Device 7b | | | 40 | nm |
| Device 7c | | | 70 | nm |
| Device 7d | | | 100 | nm |
| Device 8a | 90 nm | | 10 | nm |
| Device 8b | | | 40 | nm |
| Device 8c | | | 70 | nm |
| Device 8d | | | 100 | nm |
| Device 9a | 60 nm | BBABnf | 10 | nm |
| Device 9b | | | 40 | nm |
| Device 9c | | | 70 | nm |
| Device 9d | | | 100 | nm |
| Device 10a | 90 nm | | 10 | nm |
| Device 10b | | | 40 | nm |
| Device 10c | | | 70 | nm |
| Device 10d | | | 100 | nm |

The first electrode 11 and the layer 21a were formed. Since the description in Example 1 can be referred to for the formation of the first electrode 11 and the layer 21a, the detailed description is omitted.

In each of the device 6a to the device 6d and the device 7a to the device 7d, the layer 21b functioning as a hole-transport layer was formed by depositing N-(1,1′-biphenyl-4-yl)-N-[4-(9-phenyl-9H-carbazol-3-yl)phenyl]-9,9-dimethyl-9H-fluoren-2-amine (abbreviation: PCBBiF) by evaporation. The thickness of the active layer 21b differed between the samples.

In each of the device 8a to the device 8d and the device 9a to the device 9d, the layer 21b functioning as a hole-transport layer were formed by depositing BBABnf by evaporation. The thickness of the active layer 21b differed between the samples.

The active layer 23 was formed by depositing FT2TDMN represented by Structural Formula (126) above and Rubrene represented by Structural Formula (201) above by co-evaporation at a weight ratio of 7:3. The thickness of the active layer 23 differed between the samples.

The layer 25a functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation to a thickness of 15 nm and subsequently depositing 2,9-bis(naphthalen-2-yl)-4,7-diphenyl-1,10-phenanthroline (abbreviation: NBPhen) and Liq by co-evaporation to a thickness of 25 nm at a weight ratio of 1:1.

The second electrode 13 was formed by depositing silver (Ag) and magnesium (Mg) by co-evaporation at a volume ratio of 10:1 to a thickness of 10 nm.

From the above, the device 6a to the device 6d, the device 7a to the device 7d, the device 8a to the device 8d, and the device 9a to the device 9d that differed in the structures of the active layer 23 and the layer 21b were each fabricated.

### <Current Density-Voltage Characteristics>

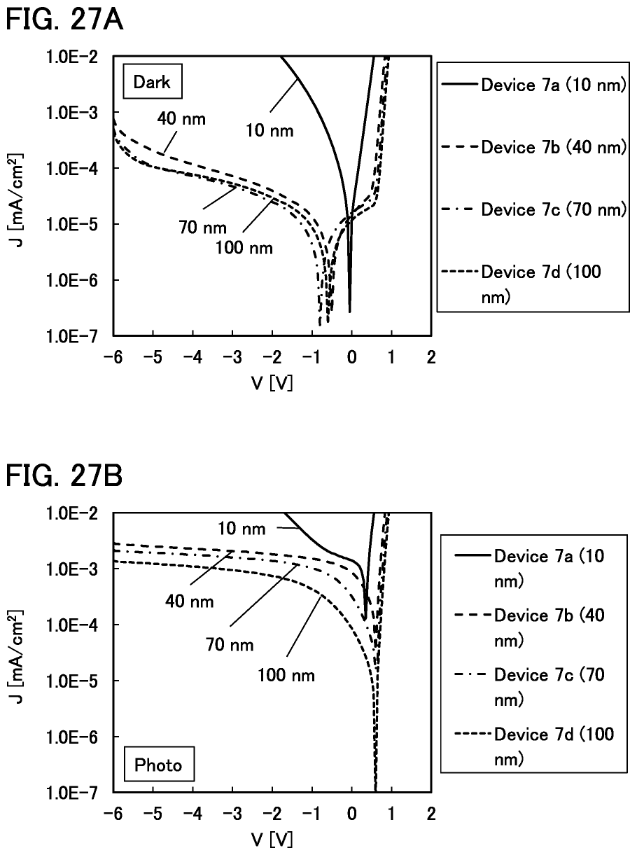

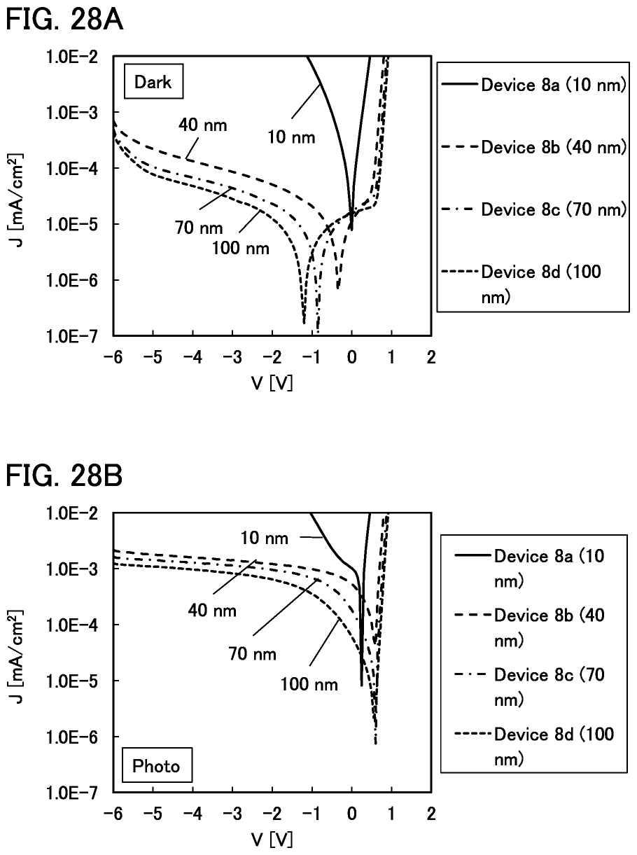

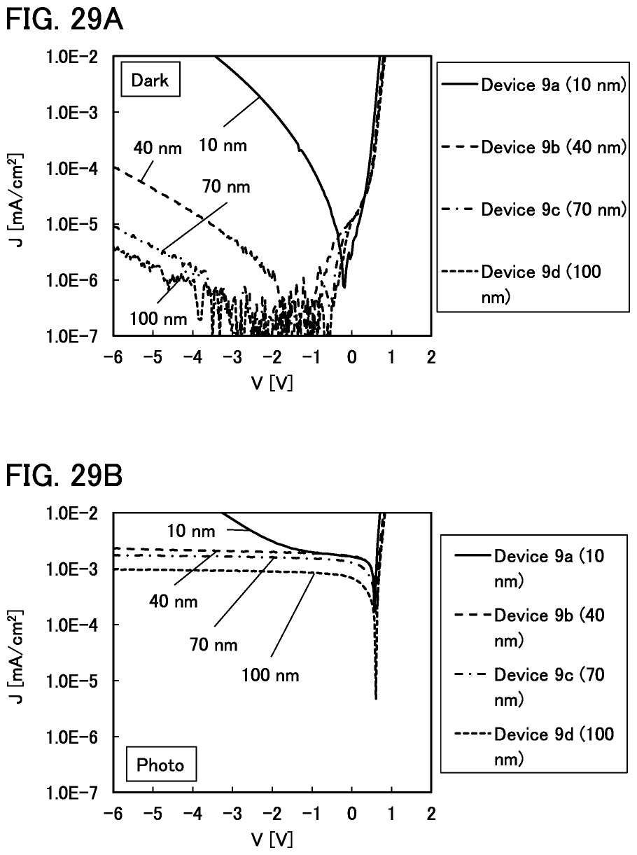

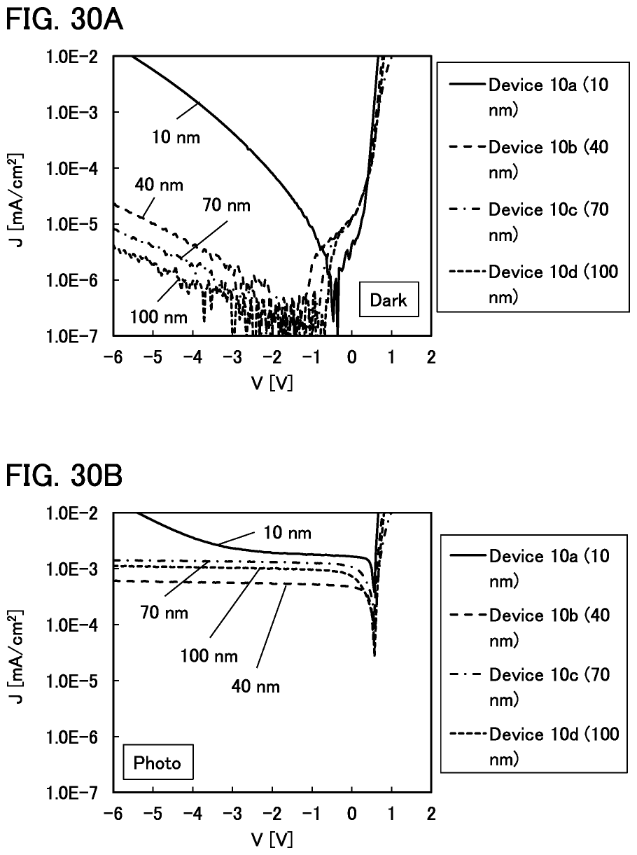

Next, the current density-voltage characteristics of each light-receiving device were measured. The measurement was performed in each of a state with irradiation with monochromatic light having a wavelength of 525 nm at an irradiance of 12.5 μW/cm² (denoted by Photo) and a dark state (denoted by Dark). FIG. 27A and FIG. 27B show the current density-voltage characteristics of the device 7a to the device 7d. FIG. 28A and FIG. 28B show the current density-voltage characteristics of the device 8a to the device 8d. FIG. 29A and FIG. 29B show the current density-voltage characteristics of the device 9a to the device 9d. FIG. 30A and FIG. 30B show the current density-voltage characteristics of the device 10a to the device 10d. In each of FIG. 27A to FIG. 30B, the horizontal axis represents voltage V and the vertical axis represents current density J.

As shown in FIG. 27A to FIG. 30B, it was confirmed that the light-receiving devices each exhibited favorable saturation characteristics.

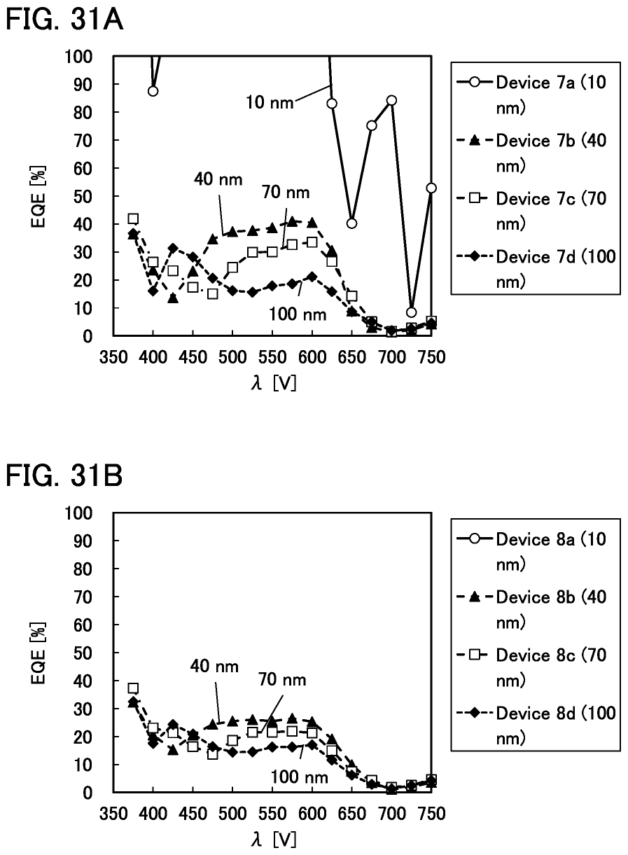

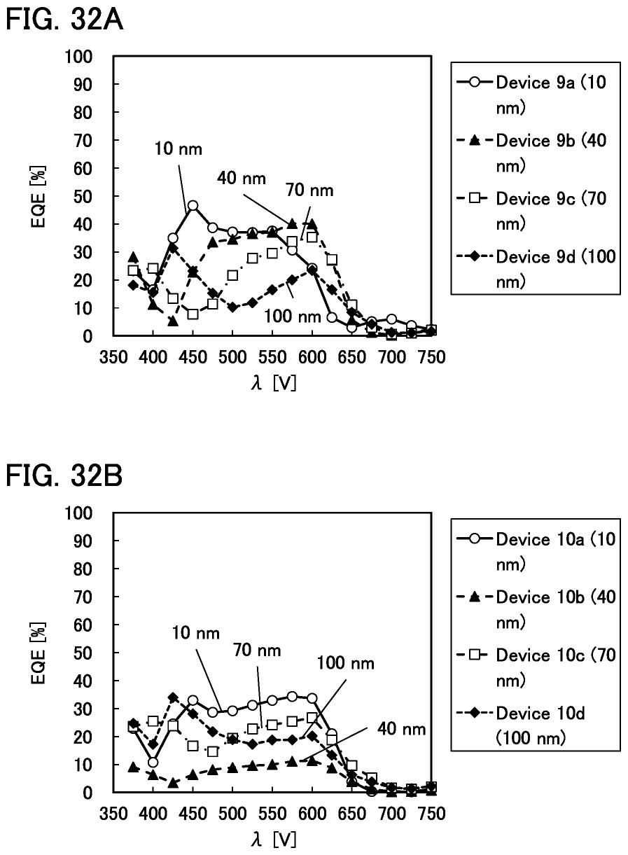

FIG. 31A shows wavelength dependence of external quantum efficiency (EQE) of the device 7a to the device 7d. FIG. 31B shows wavelength dependence of external quantum efficiency (EQE) of the device 8a to the device 8d. FIG. 32A shows wavelength dependence of external quantum efficiency (EQE) of the device 9a to the device 9d. FIG. 32B shows wavelength dependence of external quantum efficiency (EQE) of the device 10a to the device 10d. The EQE was measured at a voltage of −4V and an irradiance of 12.5 μW/cm² with various wavelengths. In each of FIG. 31A to FIG. 32B, the horizontal axis represents wavelength k and the vertical axis represents EQE.

As shown in FIG. 31A to FIG. 32B, it was confirmed that favorable light-receiving sensitivity was obtained when the thickness of the layer 21b was greater than or equal to 40 nm.

### EXAMPLE 5

In this example, evaluation results of the reliability of fabricated light-receiving devices will be described.

In this example, light-receiving devices (a device 11a to a device 11d) of one embodiment of the present invention were fabricated.

Chemical formulae of materials used in this example are shown below.

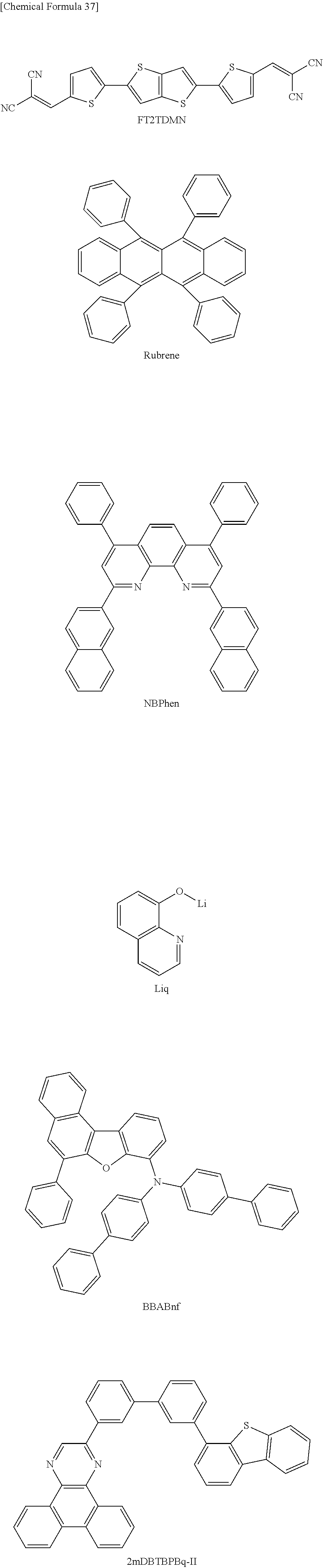

Specific structures of the light-receiving devices fabricated in this example are shown in Table 9 and Table 10. For the structures of the light-receiving devices, the light-receiving device 10 illustrated in FIG. 1E as an example can be referred to. The light-receiving devices fabricated in this example had similar structures except for the structure of the layer 25a.

TABLE 9

| | | Weight | |
|---|---|---|---|
| | Component material | ratio | Film thickness |
| Second electrode 13 | Ag:Mg (10:1) | — | 10 nm |
| Layer 25a | NBPhen:Liq | 1:1 | 25 nm |
| | 2mDBTBPDBq-II | — | * |
| Activelayer 23 | FT2TDMN:Rubrene | 9:1 | 60 nm |
| Layer 21b | BBABnf | — | 40 nm |
| Layer 21a | BBABnf OCHD-003 | 1:0.1 | 10 nm |
| First electrode 11 | APC\ITSO | — | 100 nm\100 nm |

TABLE 10

| | Layer 25a |
|---|---|
| Sample name | * |
| Device 11a | 10 nm |
| Device 11b | 40 nm |
| Device 11c | 70 nm |
| Device 11d | 100 nm |

The first electrode 11 and the layer 21a were formed. Since the description in Example 1 can be referred to for the formation of the first electrode 11 and the layer 21a, the detailed description is omitted.

The layer 21b functioning as a hole-transport layer was formed by depositing BBABnf by evaporation. The layer 21b was formed to a thickness of 40 nm.

The active layer 23 was formed by depositing FT2TDMN represented by Structural Formula (126) above and Rubrene represented by Structural Formula (201) above by co-evaporation at a weight ratio of 9:1. The active layer 23 was formed to a thickness of 60 nm.

The layer 25a functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation and subsequently depositing 2,9-bis(naphthalen-2-yl)-4,7-diphenyl-1,10-phenanthroline (abbreviation: NBPhen) and Liq by co-evaporation to a thickness of 25 nm at a weight ratio of 1:1. The thickness of 2-[3′-(dibenzothiophen-4-yl)biphenyl-3-yl]dibenzo[f,h]quinoxaline (abbreviation: 2mDBTBPDBq-II) differed between the samples.

The second electrode 13 was formed by depositing silver (Ag) and magnesium (Mg) by co-evaporation at a volume ratio of 10:1 to a thickness of 10 nm.

From the above, the device 11a to the device 11d that differed in the structure of the layer 25a were each fabricated.

### <Reliability>

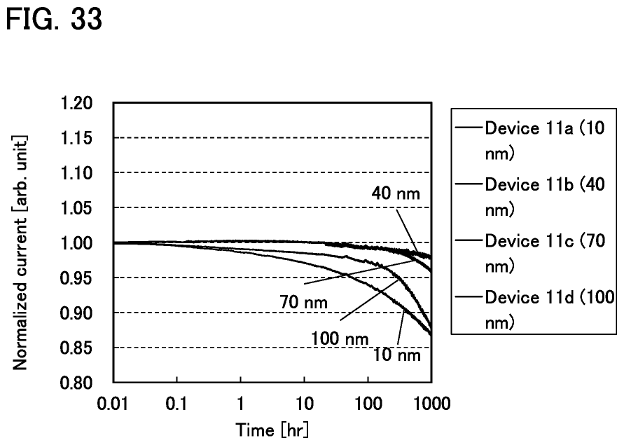

Next, the reliability of each light-receiving device was evaluated. For the evaluation of the reliability, the light-receiving device was irradiated with light of 5000 K at an illuminance of 100 klux using a white LED, and the current was measured with the condition kept at a voltage of −4 V and a temperature of 25° C. FIG. 33 shows the measurement results of each light-receiving device. In FIG. 33, the horizontal axis represents time (Time) and the vertical axis represents a normalized current value (Normalized current). Note that the normalized current value is a value at the time when an initial current value is 1.

As shown in FIG. 33, it was confirmed that the light-receiving devices each had high reliability. In particular, it was confirmed that the device 11b in which the thickness of the layer 25a was 40 nm and the device 11c in which the thickness of the layer 25a was 70 nm each had favorable reliability.

### REFERENCE NUMERALS

MS: wiring, PD: light-receiving device, RES: wiring, SE: wiring, TX: wiring, VG: wiring, VS: wiring, 10a: device, 10A: light-emitting and light-receiving device, 10d: device, 10: light-receiving device, 11: first electrode, 13: second electrode, 15: layer, 21a: layer, 21b: layer, 21: hole-transport layer, 23a: first layer, 23b: second layer, 23: active layer, 25a: layer, 25b: layer, 25: electron-transport layer, 31: hole-injection layer, 35: electron-injection layer, 39: light-emitting layer, 100A: display apparatus, 100B: display apparatus, 100C: display apparatus, 100D: display apparatus, 100E: display apparatus, 110: light-receiving device, 112: common layer, 114: common layer, 115: common electrode, 116: protective layer, 121B: light, 121G: light, 121R: light, 121: visible light, 122: light, 123a: stray light, 123b: stray light, 123: light, 124: reflected light, 131: transistor, 132: transistor, 142: adhesive layer, 151: substrate, 152: substrate, 153: substrate, 154: substrate, 155: adhesive layer, 156: adhesive layer, 157: insulating layer, 158: light shielding layer, 159p: opening, 159: resin layer, 162: display portion, 164: circuit, 165: wiring, 166: conductive layer, 167: conductive layer, 169: conductive layer, 172: FPC, 173: IC, 182: buffer layer, 183: active layer, 184: buffer layer, 190B: light-emitting device, 190G: light-emitting device, 190R: light-emitting device, 190RPD: light-emitting and light-receiving device, 190: light-emitting device, 191: pixel electrode, 192B: buffer layer, 192G: buffer layer, 192R: buffer layer, 192: buffer layer, 193B: light-emitting layer, 193G: light-emitting layer, 193R: light-emitting layer, 193: light-emitting layer, 194B: buffer layer, 194G: buffer layer, 194R: buffer layer, 194: buffer layer, 200A: display apparatus, 200B: display apparatus, 201: substrate, 202: finger, 203: layer, 204: layer, 205: functional layer, 207: layer, 208: stylus, 209: substrate, 211: insulating layer, 212: insulating layer, 213: insulating layer, 214a: insulating layer, 214b: insulating layer, 214: insulating layer, 215: insulating layer, 216: partition, 219a: light shielding layer, 219b: spacer, 221: conductive layer, 222a: conductive layer, 222b: conductive layer, 223: conductive layer, 225: insulating layer, 228: region, 231i: channel formation region, 231n: low-resistance region, 231: semiconductor layer, 240: transistor, 241: transistor, 242: connection layer, 243: transistor, 244: connection portion, 245: transistor, 246: transistor, 247: transistor, 248: transistor, 249: transistor, 261: contact portion, 262: fingerprint, 263: image-capturing range, 266: path, 270B: light-emitting device, 270G: light-emitting device, 270PD: light-receiving device, 270R: light-emitting device, 270RPD: light-emitting and light-receiving device, 270: light-emitting device, 271: first electrode, 273: active layer, 275: second electrode, 280A: display apparatus, 280B: display apparatus, 280C: display apparatus, 280D: display apparatus, 280E: display apparatus, 280F: display apparatus, 280G: display apparatus, 280H: display apparatus, 281: hole-injection layer, 282: hole-transport layer, 283B: light-emitting layer, 283G: light-emitting layer, 283R: light-emitting layer, 283: light-emitting layer, 284a: first electron-transport layer, 284b: second electron-transport layer, 284: electron-transport layer, 285: electron-injection layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9003: speaker, 9005: control key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1-5. (canceled)

6. An optical device comprising:
a first electrode, a second electrode, an active layer, and a carrier-transport layer,
wherein the active layer is positioned between the first electrode and the second electrode,
wherein the active layer contains a first organic compound and a second organic compound,
wherein the first organic compound is represented by General Formula (G1),
wherein the second organic compound is represented by General Formula (G2-2) or Structural Formula (310),
wherein the carrier-transport layer is positioned between the second electrode and the active layer,
wherein thickness of the carrier-transport layer is greater than or equal to 10 nm and less than or equal to 300 nm, 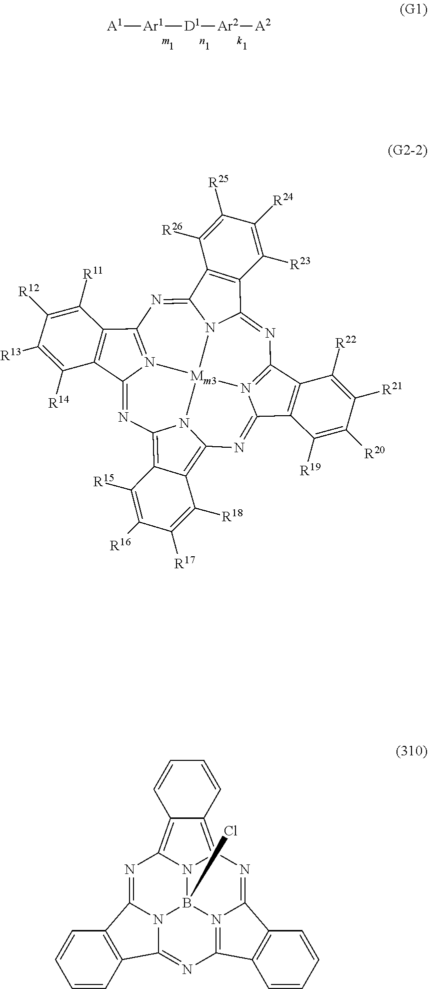
wherein, in General Formula (G1), D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms, A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3, and
wherein, in General Formula (G2-2), M represents a metal, a metal oxide, or a metal halide; m₃ is 1 or 2; R¹¹ to R²⁶ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

7. The optical device according to claim 6,
wherein the second organic compound is represented by any one of Structural Formula (301) to Structural Formula (305).

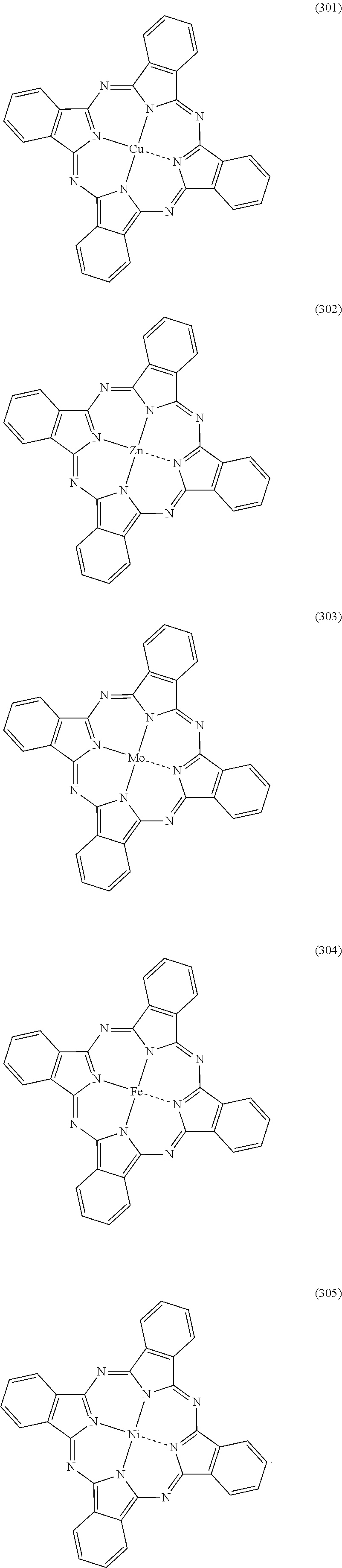

8. An optical device comprising:
a first electrode, a second electrode, an active layer, and a carrier-transport layer,
wherein the active layer is positioned between the first electrode and the second electrode,
wherein the active layer contains a first organic compound and a second organic compound,
wherein the first organic compound is represented by General Formula (G1),
wherein the second organic compound is represented by General Formula (G2-3),
wherein the carrier-transport layer is positioned between the second electrode and the active layer,
wherein thickness of the carrier-transport layer is greater than or equal to 10 nm and less than or equal to 300 nm, 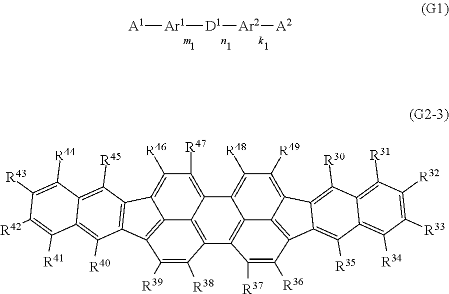
wherein, in General Formula (G1), D¹ represents a substituted or unsubstituted thiophene-diyl group, a substituted or unsubstituted furan-diyl group, a substituted or unsubstituted heteroarylene group having 4 to 30 carbon atoms that contains thiophene, or a substituted or unsubstituted heteroarylene group having 4 to 30 carbon atoms that contains furan; Ar¹ and Ar² each independently represent a substituted or unsubstituted heteroarylene group having 4 to 30 carbon atoms or a substituted or unsubstituted arylene group having 6 to 30 carbon atoms; A¹ and A² each independently represent hydrogen, deuterium, a nitro group, a substituted or unsubstituted alkyl group having 1 to 6 carbon atoms, halogen, a substituted or unsubstituted alkyl halide group having 1 to 6 carbon atoms, a cyano group, a substituted or unsubstituted alkoxy group having 1 to 6 carbon atoms, or a vinyl group having 1 to 3 substituents; the substituent is a cyano group, halogen, a substituted or unsubstituted alkyl halide group having 1 to 6 carbon atoms, a substituted or unsubstituted alkoxy group having 1 to 6 carbon atoms, or a nitro group; m₁, n₁, and k₁ each independently represent an integer of 0 to 3; and at least one of m₁, n₁, and k₁ represents an integer of 1 to 3, and
wherein, in General Formula (G2-3), R³⁰ to R⁴⁹ each independently represent hydrogen, deuterium, a substituted or unsubstituted alkyl group having 1 to 6 carbon atoms, a substituted or unsubstituted cycloalkyl group having 3 to 10 carbon atoms, halogen, a substituted or unsubstituted alkyl halide group having 1 to 6 carbon atoms, a cyano group, a substituted or unsubstituted alkoxy group having 1 to 6 carbon atoms, a substituted or unsubstituted aryl group having 6 to 30 carbon atoms, or a substituted or unsubstituted heteroaryl group having 2 to 30 carbon atoms.

9. The optical device according to claim 8,
wherein the second organic compound is represented by Structural Formula (401)

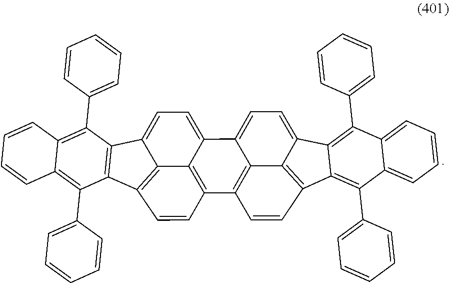 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]

10. The optical device according to claim 6,
wherein the D¹ is represented by any one of General Formula (g1-1-1) to General Formula (g1-1-4),
wherein the Ar¹ and the Ar² each independently represent a substituted or unsubstituted thiophene-diyl group, a substituted or unsubstituted furan-diyl group, a substituted or unsubstituted phenylene group, or a substituted or unsubstituted naphthalene-diyl group,
wherein the A¹ and the A² are each independently represented by General Formula (g1-2), and 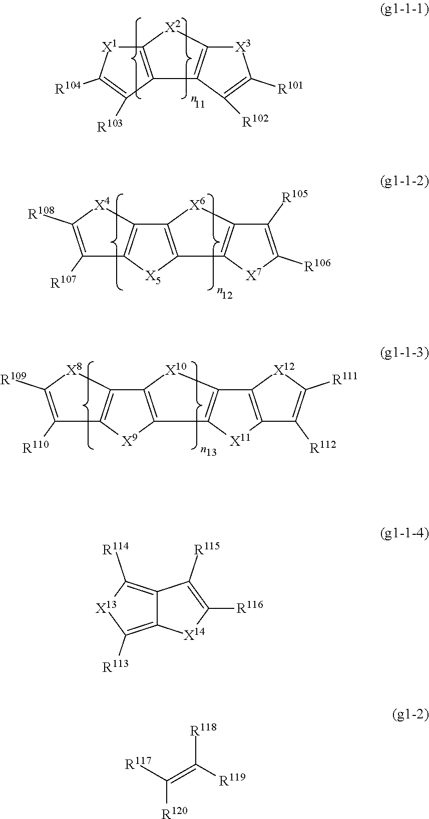
wherein, in General Formula (g1-1-1) to General Formula (g1-1-4) and General Formula (g1-2), one of R¹⁰¹ and R¹⁰² is bonded to one of Ar¹ and Ar²; one of R¹⁰³ and R¹⁰⁴ is bonded to the other of Ar¹ and Ar²; one of R¹⁰⁵ and R¹⁰⁶ is bonded to one of Ar¹ and Ar²; one of R¹⁰⁷ and R¹⁰⁸ is bonded to the other of Ar¹ and Ar²; one of R¹⁰⁹ and R¹¹⁰ is bonded to one of Ar¹ and Ar²; one of R¹¹¹ and R¹¹² is bonded to the other of Ar¹ and Ar²; one of any two of R¹¹³ to R¹¹⁶ is bonded to Ar¹ and the other is bonded to Ar²; the rest of R¹⁰¹ to R¹¹⁶ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹¹⁷ to R¹¹⁹ each independently represent hydrogen, deuterium, a cyano group, fluorine, chlorine, a nitro group, a substituted or unsubstituted alkyl halide group having 1 to 6 carbon atoms, or a substituted or unsubstituted alkoxy group having 1 to 6 carbon atoms; at least one of R¹¹⁷ to R¹¹⁹ represents a cyano group, fluorine, chlorine, a nitro group, a substituted or unsubstituted alkyl halide group having 1 to 6 carbon atoms, or a substituted or unsubstituted alkoxy group having 1 to 6 carbon atoms; R¹²⁰ is bonded to one or both of Ar¹ and Ar²; X¹ to X¹⁴ each independently represent oxygen or sulfur; n₁₁ represents an integer of 0 to 10; and n₁₂ and n₁₃ each independently represent an integer of 0 to 4.

11. The optical device according to claim 6,
wherein the first organic compound is represented by any one of General Formula (G1-1) to General Formula (G1-3), and 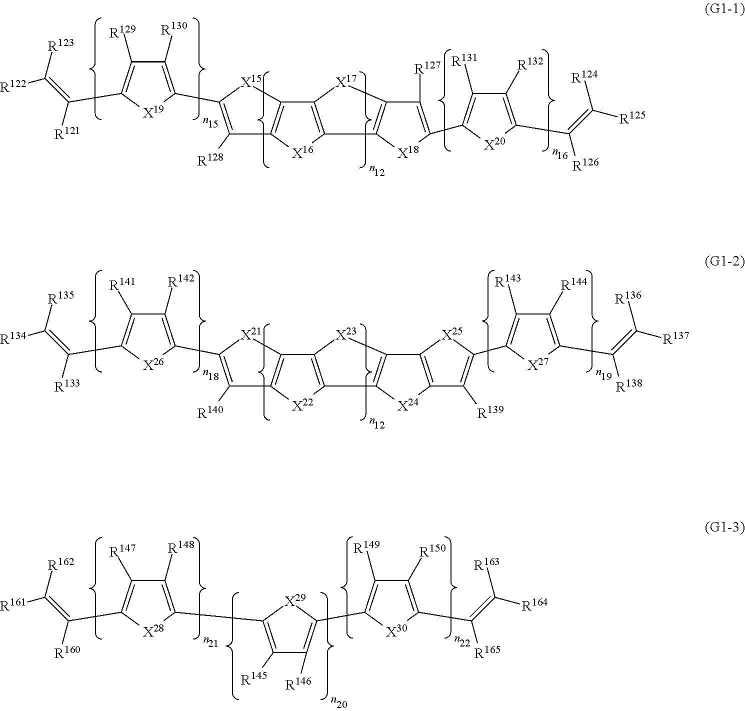
wherein, in General Formula (G1-1) to General Formula (G1-3), X¹⁵ to X³⁰ each independently represent oxygen or sulfur; n₁₄ and n₁₇ each independently represent an integer of 0 to 4; n₁₅, n₁₆, n₁₈, and n₁₉ to n₂₂ each independently represent an integer of 0 to 3;
at least one of n₂₀ to n₂₂ represents an integer of 1 to 3; R¹²⁷ to R¹³² and R¹³⁹ to R¹⁵⁰ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹²¹ to R¹²⁶, R¹³³ to R¹³⁸, and R¹⁶⁰ to R¹⁶⁵ each independently represent hydrogen, deuterium, a cyano group, fluorine, chlorine, a substituted or unsubstituted alkyl halide group having 1 to 6 carbon atoms, or a substituted or unsubstituted alkoxy group having 1 to 6 carbon atoms; at least one of R¹²¹ to R¹²⁶, at least one of R¹³³ to R¹³⁸, and at least one of R¹⁶⁰ to R¹⁶⁵ each represent a cyano group, fluorine, chlorine, a nitro group, a substituted or unsubstituted alkyl halide group having 1 to 6 carbon atoms, or a substituted or unsubstituted alkoxy group having 1 to 6 carbon atoms.

12. The optical device according to claim 6,
wherein the first organic compound is represented by any one of Structural Formulae (101) and (102).

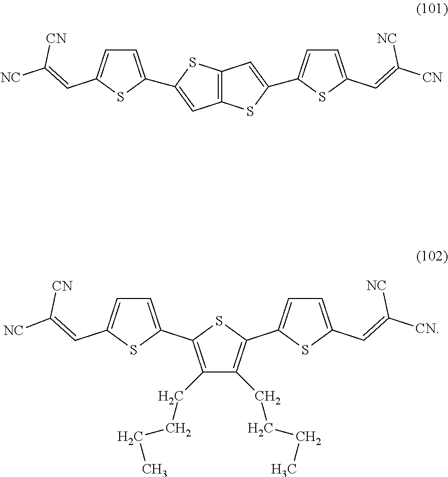 [SMILES: N#CC(C#N)=Cc1ccc(-c2cc3sc(-c4ccc(C=C(C#N)C#N)s4)cc3s2)s1 ; CCCCc1c(-c2ccc(C=C(C#N)C#N)s2)sc(-c2ccc(C=C(C#N)C#N)s2)c1CCCC]

13. The optical device according to claim 6,
wherein the carrier-transport layer contains an electron-transport material,
wherein the optical device further comprises a hole-transport layer,
wherein the hole-transport layer is positioned between the first electrode and the active layer,
wherein the hole-transport layer contains a hole-transport material, and
wherein thickness of the hole-transport layer is greater than or equal to 10 nm and less than or equal to 300 nm.

14. (canceled)

15. The optical device according to claim 6,
wherein the carrier-transport layer contains a hole-transport material,
wherein the optical device further comprises an electron-transport layer,
wherein the electron-transport layer is positioned between the first electrode and the active layer,
wherein the electron-transport layer contains an electron-transport material, and
wherein thickness of the electron-transport layer is greater than or equal to 10 nm and less than or equal to 300 nm.

16. (canceled)

17. The optical device according to claim 6,
wherein the active layer comprises a first layer and a second layer,
wherein the first layer comprises a region in contact with the second layer,
wherein the first layer contains the first organic compound, and
wherein the second layer contains the second organic compound.

18-22. (canceled)

23. The optical device according to claim 8,
wherein the D¹ is represented by any one of General Formula (g1-1-1) to General Formula (g1-1-4),
wherein the Ar¹ and the Ar² each independently represent a substituted or unsubstituted thiophene-diyl group, a substituted or unsubstituted furan-diyl group, a substituted or unsubstituted phenylene group, or a substituted or unsubstituted naphthalene-diyl group,
wherein the A¹ and the A² are each independently represented by General Formula (g1-2), and 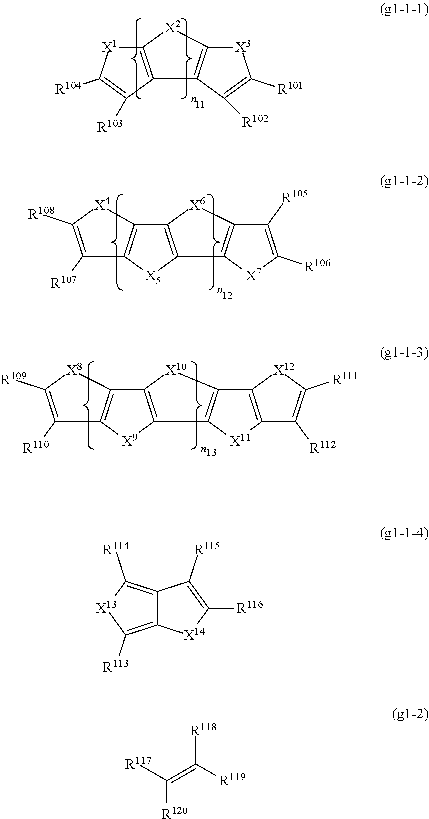
wherein, in General Formula (g1-1-1) to General Formula (g1-1-4) and General Formula (g1-2), one of R¹⁰¹ and R¹⁰² is bonded to one of Ar¹ and Ar²; one of R¹⁰³ and R¹⁰⁴ is bonded to the other of Ar¹ and Ar²; one of R¹⁰⁵ and R¹⁰⁶ is bonded to one of Ar¹ and Ar²; one of R¹⁰⁷ and R¹⁰⁸ is bonded to the other of Ar¹ and Ar²; one of R¹⁰⁹ and R¹¹⁰ is bonded to one of Ar¹ and Ar²; one of R¹¹¹ and R¹¹² is bonded to the other of Ar¹ and Ar²; one of any two of R¹¹³ to R¹¹⁶ is bonded to Ar¹ and the other is bonded to Ar²; the rest of R¹⁰¹ to R¹¹⁶ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹¹⁷ to R¹¹⁹ each independently represent hydrogen, deuterium, a cyano group, fluorine, chlorine, a nitro group, a substituted or unsubstituted alkyl halide group having 1 to 6 carbon atoms, or a substituted or unsubstituted alkoxy group having 1 to 6 carbon atoms; at least one of R¹¹⁷ to R¹¹⁹ represents a cyano group, fluorine, chlorine, a nitro group, a substituted or unsubstituted alkyl halide group having 1 to 6 carbon atoms, or a substituted or unsubstituted alkoxy group having 1 to 6 carbon atoms; R¹²⁰ is bonded to one or both of Ar¹ and Ar²; X¹ to X¹⁴ each independently represent oxygen or sulfur; n₁₁ represents an integer of 0 to 10; and n₁₂ and n₁₃ each independently represent an integer of 0 to 4.

24. The optical device according to claim 8,
wherein the first organic compound is represented by any one of General Formula (G1-1) to General Formula (G1-3), and 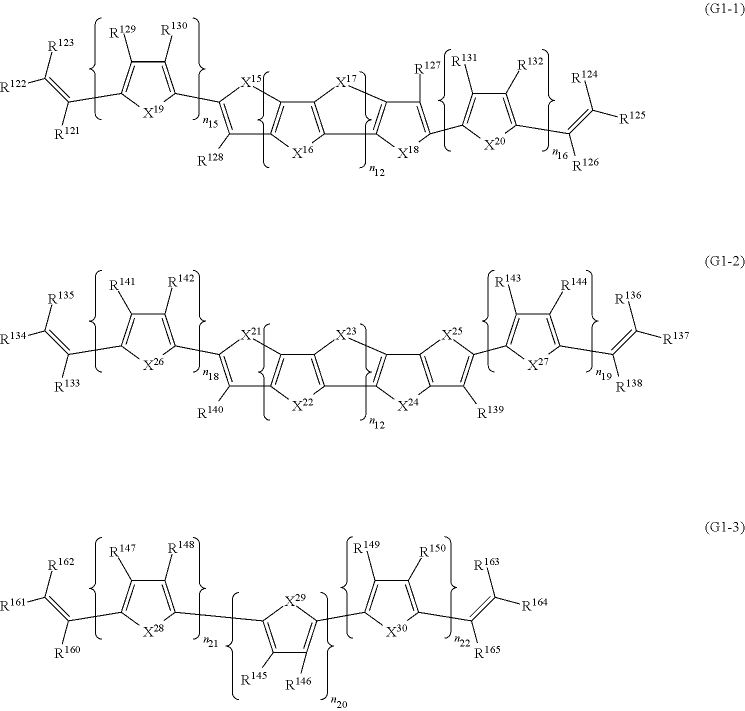
wherein, in General Formula (G1-1) to General Formula (G1-3), X¹⁵ to X³⁰ each independently represent oxygen or sulfur; n₁₄ and n₁₇ each independently represent an integer of 0 to 4; n₁₅, n₁₆, n₁₈, and n₁₉ to n₂₂ each independently represent an integer of 0 to 3; at least one of n₂₀ to n₂₂ represents an integer of 1 to 3; R¹²⁷ to R¹³² and R¹³⁹ to R¹⁵⁰ each independently represent hydrogen, deuterium, a straight-chain alkyl group having 1 to 6 carbon atoms, a cycloalkyl group having 3 to 10 carbon atoms, a straight-chain alkoxy group having 1 to 6 carbon atoms, a substituted or unsubstituted aryl group having 6 to 30 carbon atoms, a substituted or unsubstituted heteroaryl group having 2 to 30 carbon atoms, a straight-chain alkyl halide group having 1 to 6 carbon atoms, or halogen; R¹²¹ to R¹²⁶, R¹³³ to R¹³⁸, and R¹⁶⁰ to R¹⁶⁵ each independently represent hydrogen, deuterium, a cyano group, fluorine, chlorine, a substituted or unsubstituted alkyl halide group having 1 to 6 carbon atoms, or a substituted or unsubstituted alkoxy group having 1 to 6 carbon atoms; at least one of R¹²¹ to R¹²⁶, at least one of R¹³³ to R¹³⁸, and at least one of R¹⁶⁰ to R¹⁶⁵ each represent a cyano group, fluorine, chlorine, a nitro group, a substituted or unsubstituted alkyl halide group having 1 to 6 carbon atoms, or a substituted or unsubstituted alkoxy group having 1 to 6 carbon atoms.

25. The optical device according to claim 8,
wherein the first organic compound is represented by any one of Structural Formulae (101) and (102),

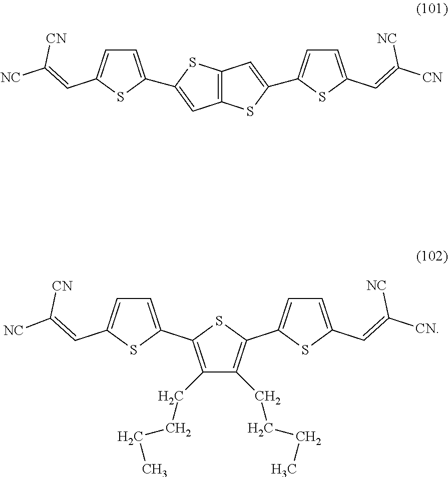 [SMILES: N#CC(C#N)=Cc1ccc(-c2cc3sc(-c4ccc(C=C(C#N)C#N)s4)cc3s2)s1 ; CCCCc1c(-c2ccc(C=C(C#N)C#N)s2)sc(-c2ccc(C=C(C#N)C#N)s2)c1CCCC]

26. The optical device according to claim 8,
wherein the carrier-transport layer contains an electron-transport material,
wherein the optical device further comprises a hole-transport layer,
wherein the hole-transport layer is positioned between the first electrode and the active layer,
wherein the hole-transport layer contains a hole-transport material, and
wherein thickness of the hole-transport layer is greater than or equal to 10 nm and less than or equal to 300 nm.

27. The optical device according to claim 8,
wherein the carrier-transport layer contains a hole-transport material,
wherein the optical device further comprises an electron-transport layer,
wherein the electron-transport layer is positioned between the first electrode and the active layer,
wherein the electron-transport layer contains an electron-transport material, and
wherein thickness of the electron-transport layer is greater than or equal to 10 nm and less than or equal to 300 nm.

28. The optical device according to claim 8,
wherein the active layer comprises a first layer and a second layer,
wherein the first layer comprises a region in contact with the second layer,
wherein the first layer contains the first organic compound, and
wherein the second layer contains the second organic compound.
